(19) United States
(12) Patent Application Publication
(10) Pub. No.: US 2026/0020198 A1
(43) Pub. Date: Jan. 15, 2026

(54) Compressed Air Ride-Through System for Immediate, Short-Term Cooling, Especially Adapted for Data Centers

(71) Applicant: Seth Rizzo, Canastota, NY (US)

(72) Inventor: Seth Rizzo, Canastota, NY (US)

(21) Appl. No.: 19/265,816

(22) Filed: Jul. 10, 2025

Related U.S. Application Data
(60) Provisional application No. 63/669,372, filed on Jul. 10, 2024.
(60) Provisional application No. 63/700,737, filed on Sep. 29, 2024.

(51) Int. Cl. H05K 7/20

(52) U.S. Cl. CPC H05K 7/20836; H05K 7/20272; H05K 7/20609; H05K 7/20745

(57) ABSTRACT

In its broadest respect, the invention relates to a system and method for releasing compressed air from a tank to provide immediate, short-term movement of a cooling fluid and/or provide immediate, short-term cooling, especially adapted for data centers to maintain information technology equipment within an acceptable temperature range during a utility failure or other non-standard operating condition.

### CROSS-REFERENCE TO RELATED APPLICATIONS

The inventor, Seth Rizzo, has previously filed two provisional applications which are associated with this non-provisional patent application. This application claims the benefit of these provisional applications:
a. Provisional Application Serial No.: 63/669,372, entitled “Compressed Air Ride-Through System for Immediate, Short-Term Cooling, Especially Adapted for Data Centers”, Application Filing Date: Jul. 10, 2024.
b. Provisional Application Serial No.: 63/700,737, entitled “Compressed Air Ride-Through System for Immediate, Short-Term Cooling, Especially Adapted for Data Centers”, Application Filing Date: Sep. 29, 2024.

### GLOSSARY

Data center: As used herein, the phrase “data center” refers to a room, a closet, a facility, a container, an area, a building, or a group of buildings which primarily houses information technology equipment (ITE), such as computers, servers, storage systems, networking equipment, telecommunication equipment, IT infrastructure, air-cooled ITE, and liquid-cooled ITE. Examples of such data centers include, but are not limited to, managed data centers, enterprise data centers, colocation data centers, hyperscale data centers, cloud data centers, edge/micro data centers, containerized/modular data centers, server rooms, IT closets, and “meet-me” rooms.

Rack: As used herein, the term “rack” refers to a support structure or housing on which or in which ITE is mounted. A rack typically supports or houses a plurality of pieces of ITE. As used herein, the term “rack” is synonymous and interchangeable with the term “cabinet”.

Cabinet: As used herein, the term “cabinet” refers to a support structure or housing on which or in which ITE is mounted. A cabinet typically supports or houses a plurality of pieces of ITE. As used herein, the term “cabinet” is synonymous and interchangeable with the term “rack”.

Air-cooled ITE: As used herein, the phrase “air-cooled ITE” refers to information technology equipment (ITE) which is cooled solely by air at the rack-level (i.e. only air crosses the boundary of the rack). ITE, which is cooled by a liquid or refrigerant that circulates only within the confines of the rack and then ultimately rejects all of its heat from the liquid or refrigerant to air that crosses the boundary of the rack, is still considered to be air-cooled ITE. For example, a server which utilizes a heat pipe or a small refrigerant loop internally to transfer heat from a chip to an air-cooled heat sink within the cabinet is still considered be air-cooled ITE since only air (no liquid nor refrigerant) would cross the boundary of the cabinet to pick up the heat from this server.

Liquid-cooled ITE: As used herein, the phrase “liquid-cooled ITE” refers to information technology equipment (ITE) which is cooled in part or cooled wholly by a liquid cooling fluid at the rack level (i.e. a liquid cooling fluid crosses the boundary of the rack). The cooling fluid which crosses the boundary of the rack of liquid-cooled ITE includes liquids which remain a liquid throughout its entire cooling cycle/loop and the liquid phase of a refrigerant cycle/loop. Liquid-cooled ITE may require cooling from both a liquid cooling fluid and from ambient air in order to operate properly.

Technology cooling system piping or technology cooling system loop or TCS piping or TCS loop: As used herein, the phrases “technology cooling system piping” or “technology cooling system loop” or “TCS piping” or “TCS loop” refer to a hydraulic network or loop of piping, hosing, or tubing which cross the boundary of a rack containing liquid-cooled ITE in order to extract/absorb heat from the liquid-cooled ITE. The cooling fluid which passes through technology cooling system piping, a technology cooling system loop, TCS piping, or a TCS loop includes liquids which remain a liquid throughout their entire cooling cycle/loop and refrigerants for which the liquid phase of the refrigerant cross the boundary of a rack containing liquid-cooled ITE. A TCS loop is considered a specific type of principal cooling equipment fluid loop, principal cooling equipment liquid loop, principal cooling fluid loop, or principal cooling liquid loop.

Air-cooled sidecar arrangement: As used herein, the phrase “air-cooled sidecar arrangement” refers to a pair of cabinets in which one cabinet houses one or more pieces of liquid-cooled ITE (i.e. a liquid crosses the boundary of the cabinet), and this cabinet housing the liquid-cooled ITE rejects all or part of its heat through the liquid/refrigerant loop to an adjacent cabinet, and the adjacent cabinet rejects this heat to the ambient air in the data center. This air-cooled sidecar arrangement is offered by some equipment manufacturers as a low-initial-cost way to be able to integrate a liquid-cooled ITE rack into an existing data center which only has air-cooling available.

PSIA: As used herein, the term “PSIA” refers to pounds of force per square inch absolute, which is a unit of pressure referenced to the absolute zero pressure. For example, 14.7 PSIA refers to a pressure which is 14.7 pounds of force per square inch above absolute zero pressure (14.7 PSIA is a typical atmospheric pressure at sea level). By contrast, 200 PSIA inside a compressed air tank would indicate that the air pressure inside the compressed air tank is 200 pounds of force per square inch above absolute zero pressure.

PSIG: As used herein, the term “PSIG” refers to pounds of force per square inch gauge, which is a unit of pressure referenced to the local atmospheric pressure. For example, 0 PSIG inside a compressed air tank would indicate that the air pressure inside the compressed air tank is 0 pounds of force per square inch above the local atmospheric pressure. By contrast, 200 PSIG inside a compressed air tank would indicate that the air pressure inside the compressed air tank is 200 pounds of force per square inch above the local atmospheric pressure (if the local atmospheric pressure is 14.7 PSIA, then a pressure of 200 PSIG would equal 214.7 PSIA).

ACFM: As used herein, the term “ACFM” refers to actual cubic feet per minute, which is a unit of volumetric flowrate at the actual density of the fluid. For example, a flowrate of 25 ACFM of ambient air through a duct would indicate that 25 cubic feet of ambient moves through the duct every minute.

SCFM: As used herein, the term “SCFM” refers to standard cubic feet per minute, which is a unit of mass flowrate expressed as a volumetric flowrate standardized/normalized to standard temperature and pressure conditions of 14.696 PSIA and 68° F. For example, a 25 SCFM flowrate of air which is at 14.696 PSIA and 68° F. is equal to 25 ACFM. However, a 25 SCFM flowrate of air which is at 114.696 PSIA and 68° F. is equal to 3.2 ACFM (the air at 100 PSIA is compressed and thus for the same mass flowrate, it has a much smaller volumetric flowrate than it would have at standard temperature and pressure conditions).

Non-standard operating condition: As used herein, the phrase “non-standard operating condition” refers to a temporary condition or state during which the principal cooling equipment is interrupted, is affected, fails to maintain the ITE within an acceptable temperature range, or is at an increased risk of doing so. Examples of such non-standard operating conditions include, but are not limited to, a loss of normal utility power, a loss of at least one source of normal utility power, an emergency condition, a transfer to generator/emergency/standby power, a generator/emergency/standby power system startup, a re-transfer back to normal utility power, a manual activation of the compressed air ride-through system, a principal cooling equipment failure, a failure of a component of a piece of principal cooling equipment, a shutdown of a piece of principal cooling equipment, a cooling emergency, an ITE high temperature condition, an ITE failure, a high temperature condition in a cold aisle, a high temperature condition at the inlet to a piece of ITE, a loss of cooling fluid flow, a high temperature cooling fluid condition, a maintenance event, and a loss of communication with a piece of principal cooling equipment.

Indication of a non-standard operating condition: As used herein, the phrase “indication of a non-standard operating condition” refers to a change of state or signal which is indicative of an occurrence of a non-standard operating condition. The compressed air ride-through system activates in response to at least one indication of a non-standard operating condition, thus opening an automatic releasing valve to release the compressed air stored in a compressed air tank to a pneumatically-powered fluid mover. Note that in some cases, the compressed air ride-through system may activate in response to an occurrence of a non-standard operating condition directly (such as with the use of a powered-closed, fail-open automatic releasing valve fed with normal utility power, which will open upon a loss of normal utility power). In other cases, the compressed air ride-through system activates in response to an indication of non-standard operating condition (such as the automatic releasing valve opening in response to a cold aisle high temperature alarm). Therefore, as used herein, the phrase “indication of a non-standard operating condition” encompasses both the indication of a non-standard operating condition and the occurrence of non-standard operating condition itself, since the compressed air ride-through system may activate in response to both in different cases. Examples of such indications of non-standard operating conditions include, but are not limited to, a loss of normal utility power, a loss of at least one source of normal utility power, a principal cooling equipment alarm/signal, generator/emergency/standby power system alarm/signal, a transfer switch alarm/signal, a cooling fluid alarm/signal, a cold aisle alarm/signal, a differential pressure alarm/signal, a leak alarm/signal, temperature sensor alarm/signal, ITE alarm/signal, ITE failure alarm/signal, ITE high temperature alarm/signal, a user-configurable alarm/signal, a building management system alarm/signal, a power management system alarm/signal, a state change of an electrical switch, a state change of a relay, an opening of a circuit, a closing of a circuit, an opening of a relay, a closing of a relay, a manual activation signal, and a maintenance event alarm/signal.

Automatic releasing valve: As used herein, the phrase “automatic releasing valve” refers to a valve which is configured to open automatically (i.e. without human intervention) in response to an indication of a non-standard operating condition in order to release the compressed air stored in a compressed air tank through a compressed air conduit to a pneumatically-powered fluid mover. An automatic releasing valve may also incorporate a means of being manually opened in addition to the automatic-opening functionality. An automatic releasing valve may open automatically directly in response to an indication of a non-standard operating condition (such as a powered-closed, fail-open automatic releasing valve fed with normal utility power, which will open upon a loss of normal utility power) or it may open automatically indirectly in response to a signal, alarm, relay, normally-open circuit, normally-closed circuit, control circuit, controller, control panel, pilot/supervisory pressure, or similar which changes state in response to an indication of a non-standard operating condition. Examples of such automatic releasing valves include, but are not limited to, a powered-closed fail-open (i.e. spring-opened or capacitor-opened) motorized valve, a slow-opening powered-closed fail-open (i.e. spring-opened or capacitor-opened) solenoid valve, a pneumatically operated valve, a pilot-operated valve, a deluge-type valve, and a cylinder valve.

Activation of the compressed air ride-through system or compressed air ride-through system activation or activation of the backup system or backup system activation: As used herein, the phrases “activation of the compressed air ride-through system” or “compressed air ride-through system activation” or “activation of the backup system” or “backup system activation” refer to the automatic opening of at least one automatic releasing valve in response to an indication of a non-standard operating condition. As used herein, the phrases “activation of the compressed air ride-through system” or “compressed air ride-through system activation” or “activation of the backup system” or “backup system activation” are synonymous and interchangeable with the phrase “automatic opening of at least one automatic releasing valve”.

Backup system: As used herein, the phrase “backup system” refers to an embodiment of the invention described herein. As used herein, the phrase “backup system” is synonymous and interchangeable with the phrases “compressed air ride-through system”, “the invention”, and “the invention described herein”.

Compressed air ride-through system: As used herein, the phrase “compressed air ride-through system” refers to an embodiment of the invention described herein. As used herein, the phrase “compressed air ride-through system” is synonymous and interchangeable with the phrases “backup system”, the invention”, and “the invention described herein”.

Ride-through or ride through: As used herein, the phrases “ride-through” or “ride through” refer to maintaining the ITE in a data center within an acceptable temperature range (i.e. below a failure temperature) during a temporary non-standard operating condition in which the principal cooling equipment is interrupted, affected, or fails to maintain the ITE within an acceptable temperature range, such as a utility failure or an interruption to the operation of part or all of the principal cooling equipment. For example, when used as an adjective in the sentence “Raising the cold aisle temperature setpoint reduces the available ride-through time.”, the phrase “ride-through” in this context indicates that by raising the cold aisle temperature setpoint, the ITE would stay within an acceptable temperature range for a shorter period of time during a temporary non-standard operating condition in which the principal cooling equipment was interrupted or affected, or put another way, by raising the cold aisle temperature setpoint, the ITE would reach a failure temperature faster during a temporary non-standard operating condition in which the principal cooling equipment was interrupted or affected. In another example, when used as a noun in the sentence “Implementation of the backup system will help ensure a successful ride-through.”, the phrase “ride-through” in this context refers to the event or achievement of maintaining the ITE in a data center at acceptable temperature levels (i.e. below a failure temperature) during a temporary non-standard operating condition in which the principal cooling equipment is interrupted or affected. In another example, when used as a verb without the hyphen in the sentence, “The process of inventing and patenting a compressed air system which allows data centers to ride through a utility failure turns out to be an excellent mid-life crisis project.”, the phrase “ride through” in this context indicates that the compressed air system performs an action which maintains the ITE in a data center at acceptable temperature levels (i.e. below a failure temperature) during a temporary non-standard operating condition in which the principal cooling equipment is interrupted or affected.

Principal cooling equipment or principal cooling system: As used herein, the phrases “principal cooling equipment” or “principal cooling system” refer to the cooling equipment and cooling systems serving a data center which are intended to operate at least under standard/normal operating conditions, including redundant or standby pieces of cooling equipment. Furthermore, the phrases “principal cooling equipment” or “principal cooling system” do not exclude cooling equipment and cooling systems which are intended to operate during both standard/normal and non-standard/abnormal operating conditions. Note that the compressed air ride-through system described herein is not considered a principal cooling system since it is not intended to operate automatically under standard/normal operating conditions (note that the compressed air ride-through system may be activated manually during standard/normal operating conditions for periodic testing or maintenance purposes). However, some pieces of principal cooling equipment may be configured to be pneumatically overridden by the compressed air ride-through system (see “Pneumatically-overridden principal cooling equipment or pneumatically-overridden piece of principal cooling equipment”). Examples of such principal cooling equipment and principal cooling systems include, but are not limited to, computer room air conditioners (CRAC's), computer room air handlers (CRAH's), in-row coolers, cooling distribution units (CDU's), supply fans, exhaust fans, return fans, outdoor air fans, rear-door heat exchangers, rack air removal units, water-cooled chillers, air-cooled chillers, evaporative coolers, outdoor air handlers, cooling towers, packaged and split refrigerant-based systems (DX systems), pumps, compressors, chilled water systems, glycol chilled water systems, condenser water systems, glycol condenser water systems, technology cooling water systems, technology cooling systems, facility water systems, facility cooling systems, dielectric fluid systems, deionized water systems, mineral oil systems, domestic water systems, and cooling system controls. Similarly, a cooling fluid loop or hydraulic network of piping, hosing, or tubing (referred to in this paragraph as piping) served by principal cooling equipment is termed a “principal cooling equipment fluid loop”, a “principal cooling equipment liquid loop”, a “principal cooling fluid loop”, or a “principal cooling liquid loop”. Examples of such principal cooling equipment fluid loops, principal cooling equipment liquid loops, principal cooling fluid loops, and principal cooling liquid loops include, but are not limited to, chilled water piping loops, glycol chilled water piping loops, condenser water piping loops, glycol condenser water piping loops, technology cooling water piping loops, technology cooling system piping loops, facility water piping loops, facility cooling system piping loops, dielectric fluid piping loops, deionized water piping loops, mineral oil piping loops, and domestic water piping loops.

Compressed air tank: As used herein, the phrase “compressed air tank” refers to any vessel or reservoir of any shape capable of receiving compressed air, holding/storing compressed air at a pressure of at least 25 PSIG, and releasing compressed air. Examples of such compressed air tanks include, but are not limited to, horizontal or vertical compressed air receiver tanks, compressed air cylinders, singlewall or doublewall piping pressurized with compressed air, doublewall compressed air tanks, and spherical compressed air vessels. Such compressed air tanks may be constructed of materials which include, but are not limited to, steel, aluminum, carbon fiber, fiber-reinforced polymer, or a combination thereof.

Ambient air: As used herein, the phrase “ambient air” refers to any air inside the data center which is at near-atmospheric pressure (in contrast to compressed air, which is initially at a pressure which is higher than atmospheric pressure). Examples of such ambient air include, but are not limited to, supply air, return air, exhaust air, outdoor air which has been drawn into or blown into the data center, mixed air, the air in a cold aisle, the air in a hot aisle, the air under a raised floor, the air in a return plenum, and the air surrounding an air amplifier.

Cooling fluid: As used herein, the phrase “cooling fluid” refers to any gas, liquid, or phase-change refrigerant which is used for cooling ITE directly or indirectly, and/or used for absorbing heat from ITE directly or indirectly. Although the compressed air which is released from the compressed air tank becomes cold, absorbs some heat from the cooling fluid(s) that it moves in some embodiments, and mixes with the cooling fluid(s) that it moves in some embodiments, the compressed air does not fall under the definition of a cooling fluid as used herein (this allows for a clearer distinction between the compressed air and the cooling fluid(s) that the compressed air moves). Examples of such cooling fluids include, but are not limited to, ambient air, water, condenser water, glycol chilled water, glycol condenser water, facility water, technology cooling water, technology cooling liquid, technology cooling fluid, refrigerant, dielectric fluid, deionized water, domestic water, thermal storage liquid, mineral oil, primary cooling fluid, primary cooling liquid, secondary cooling fluid, secondary cooling liquid, and thermal storage liquid.

Move a cooling fluid or moving a cooling fluid: As used herein, the phrases “move a cooling fluid” or “moving a cooling fluid” refer to the act of causing or assisting a cooling fluid to flow macroscopically. Examples of such movement of a cooling fluid include, but are not limited to, inducing, entraining, blowing, sucking, drawing, dragging, transferring momentum, pumping, circulating, recirculating, flowing, creating a pressure differential, removing a hindrance to flow, manipulating a valve or damper to allow flow, and reducing or increasing the density of a fluid in order for a flow to occur due to buoyancy.

Pneumatically-powered fluid mover: As used herein, the phrase “pneumatically-powered fluid mover” refers to a device which comprises a compressed air inlet and a compressed air outlet and which utilizes compressed air as the energy source to move a cooling fluid at a mass flowrate which is at least three times larger than the mass flowrate of the compressed air entering the pneumatically-powered fluid mover (a value of three is used because at values less than three, the size and/or pressure of the compressed air tank and compressed air conduits would likely become cost-prohibitive for commercially-feasible embodiments). In other words, a pneumatically-powered fluid mover not only causes a cooling fluid to move, but the mass flowrate of this cooling fluid movement is of a magnitude which is at least three times larger than the mass flowrate of compressed air entering the pneumatically-powered fluid mover. For example, when the cooling fluid is ambient air and the pneumatically-powered fluid mover is an air amplifier, the mass flowrate of the entrained/induced ambient air may be anywhere from three times to fifty times (or higher) the mass flowrate of the compressed air entering the air amplifier. In another example, when the cooling fluid is water and the pneumatically-powered fluid mover is an air-operated diaphragm pump, a water flowrate of 185 gallons per minute (i.e. 1,541 pound-mass of water per minute) can be achieved with a compressed air flowrate of 95 SCFM (i.e. 7.1 pound-mass of air per minute), therefore the mass flowrate of the water is 217 times larger than the mass flowrate of compressed air entering the air-operated diaphragm pump. Examples of such pneumatically-powered fluid movers include, but are not limited to, air amplifiers, pneumatically-driven fans, reaction-type fans, pneumatically-driven pumps, airlift pumps, air-operated diaphragm pumps, pneumatic valves which are manipulated to allow a cooling fluid to flow, pneumatically-driven submersible pumps, pneumatically-driven refrigerant compressors, and pneumatically-overridden principal cooling equipment.

Air amplifier: As used herein, the phrase “air amplifier” refers to a specific type of pneumatically-powered fluid mover which is configured to create high-velocity jets or streams of compressed air which entrain or induce a flow of ambient air into the flow path of the compressed air while simultaneously mixing the compressed air with the entrained/induced ambient air. This entraining/inducing action, combined with the drop in stagnation temperature due to expansion of the compressed air as it is released from the tank, results in a total discharge mass flowrate from the air amplifier which is larger and colder than the mass flowrate of ambient air entering the air amplifier. The amplification effect which is insinuated in the phrase “air amplifier” refers to the fact that the total discharge mass flowrate from an air amplifier is larger than the mass flowrate of just the compressed air entering the air amplifier, thus the compressed air mass flowrate is “amplified” by entraining/inducing ambient air into the flow path of the compressed air. Examples of such air amplifiers include, but are not limited to, Coanda-type air amplifiers, venturi blowers, air-operated in-line conveyors, air knives, air ejectors, and entraining air nozzles.

Amplification Ratio: As used herein, the phrase “amplification ratio” refers to the total mass flowrate of air in SCFM which is discharged from an air amplifier, pneumatically-driven fan, reaction-type fan, or pneumatically-overridden principal cooling fan for each 1 SCFM of compressed air entering the air amplifier, pneumatically-driven fan, reaction-type fan, or pneumatically-overridden principal cooling fan. For example, for an air amplifier with a nominal amplification ratio of 27 and an entering compressed air mass flow of 4 SCFM, the air amplifier can discharge a mass flowrate of 108 SCFM (which is 4 SCFM×27). In this example, the air amplifier entrains/induces a mass flowrate 104 SCFM of ambient air (which is 108 SCFM-4 SCFM) which mixes with the compressed air mass flowrate of 4 SCFM to result in a discharge mass flowrate of 108 SCFM.

Reaction-type fan: As used herein, the phrase “reaction-type fan” refers to a specific type of pneumatically-powered fluid mover in which compressed air is delivered directly to fan blades, where the compressed air outlet port/nozzle is arranged on the trailing edge of the fan blades to produce thrust to spin the reaction-type fan (i.e. the fan blades spin in reaction to the discharge of compressed air from the port/nozzle on the trailing edge of the fan blades). The compressed air which is released from the ports/nozzles on the fan blades is discharged into the airstream so that it mixes with the ambient air drawn into the fan inlet, resulting in a discharge mass flowrate which consists of the ambient air entering the fan inlet plus the compressed air which is released from the fan blade discharge ports/nozzles.

Pneumatic motor: As used herein, the phrase “pneumatic motor” refers to a motor or engine which is driven by compressed air and comprises a compressed air inlet, a compressed air outlet, and a rotating shaft. Examples of such pneumatic motors include, but are not limited to, vane-type air motors, piston-type air motors, gear-type air motors, reaction-type turbines, impulse-type turbines, microturbines, Di Pietro motors, Pelton wheels, and turboexpanders.

Pneumatically-overridden principal cooling equipment or pneumatically-overridden piece of principal cooling equipment: As used herein, the phrases “pneumatically-overridden principal cooling equipment” or “pneumatically-overridden piece of principal cooling equipment” refer to a specific type of pneumatically-powered fluid mover in which a principal piece of cooling equipment or a component of a principal piece of cooling equipment which is powered with electricity under normal/standard conditions, and includes a mechanism for being powered or overridden by compressed air under a non-standard operating condition, such as when no electricity is available to non-battery-backed equipment immediately after a utility failure before the onsite generators start up. Examples of such pneumatically-overridden principal cooling equipment or pneumatically-overridden pieces of principal cooling equipment include, but are not limited to, a normally-electric-driven fan or pump with belt sheaves and a belt tensioner connected to a pneumatic motor with a belt sheave, a normally-electric-driven fan or pump with a dual-shafted electric motor and a clutching mechanism and a pneumatic motor connected to the opposite end of the shaft, a piece of principal cooling equipment which incorporates a pneumatically-powered fluid mover into the assembly of the piece of principal cooling equipment, a piece of principal cooling equipment which incorporates an air amplifier into the assembly of the piece of principal cooling equipment, a piece of principal cooling equipment which incorporates a pneumatic motor to spin the normally-electric-driven internal components, and a piece of principal cooling equipment which incorporates fan blades which are arranged similarly the fan blades in reaction-type fans where the fan blades incorporate a compressed air discharge port/nozzle on the trailing edge of the fan blades. Note that a pneumatically-overridden piece of principal cooling equipment may also be referred to as a “pneumatically-overridden principal cooling pump”, a “pneumatically-overridden principal cooling fan”, or a “pneumatically-overridden principal cooling compressor”.

Compressed air conduit: As used herein, the phrase “compressed air conduit” refers to a pipe, hose, or tube for conveying/delivering compressed air, wherein the pipe, hose, or tube is rigid or flexible, and wherein the pipe, hose, or tube is singlewall or doublewall. Examples of such compressed air conduits include, but are not limited to, steel piping, copper piping, aluminum piping, metallic piping, polymer piping, steel tubing, copper tubing, aluminum tubing, metallic tubing, polymer tubing, pneumatic hoses of any construction, polymer-lined metallic piping, polymer-lined metallic tubing, polymer-lined hoses, compressed air header lines, and compressed air branch lines.

Cooling fluid conduit: As used herein, the phrase “cooling fluid conduit” refers to a pipe, hose, or tube for conveying/delivering a cooling fluid, wherein the pipe, hose, or tube is rigid or flexible, and wherein the pipe, hose, or tube is singlewall or doublewall. Examples of such cooling fluid conduits include, but are not limited to, steel piping, copper piping, aluminum piping, metallic piping, polymer piping, steel tubing, copper tubing, aluminum tubing, metallic tubing, polymer tubing, hoses of any construction, polymer-lined metallic piping, polymer-lined metallic tubing, polymer-lined hoses, cooling fluid header lines, cooling fluid branch lines, primary cooling fluid loop piping, secondary cooling fluid loop piping, ductwork, and plenums.

Maintaining ITE within an acceptable temperature range or maintaining ITE at acceptable temperature levels: As used herein, the phrases “maintaining ITE within an acceptable temperature range” or “maintaining ITE at acceptable temperature levels” refer to the act of indirectly maintaining the internal component temperatures within a piece of ITE within a user-defined, ITE-manufacturer-defined, or standards-agency-defined range of temperatures by maintaining the cooling fluid(s) which serves the ITE within a user-defined, ITE-manufacturer-defined, or standards-agency-defined range of temperatures and by maintaining adequate flow/movement of the cooling fluid(s) which serves the ITE. In all cases, the internal component temperatures within a piece of ITE are dictated by a combination of externally-controllable and externally-uncontrollable factors, such as the entering cooling fluid temperature (externally-controllable), the cooling fluid flowrate (externally-controllable), the degree of local recirculation of the cooling fluid (partially-externally-controllable), the ITE heat output power (externally-uncontrollable), the internal heat transfer coefficients (externally-uncontrollable), the internal flow path arrangement within the ITE (externally-uncontrollable), and any internal ITE cooling/heat transfer mechanisms such as internal fans, internal heat pipes, internal CDU's, internal fluid loops, internal cooling algorithms, etc (externally-uncontrollable). Therefore, the phrases “maintaining ITE within an acceptable temperature range” or “maintaining ITE at acceptable temperature levels” also refer to the act of indirectly maintaining the internal component temperatures within a piece of ITE within a user-defined, ITE-manufacturer-defined, or standards-agency-defined range of temperatures by maintaining an adequate combination of externally-controllable factors related to the cooling fluid(s), such as the entering cooling fluid temperature, the cooling fluid flowrate, and the degree of local recirculation of the cooling fluid. In some cases, a user may define an “acceptable temperature range” or “acceptable temperature level” as simply an entering cooling fluid temperature which is below a user-defined “failure” temperature. In some other cases, a user may define an “acceptable temperature range” or “acceptable temperature level” as a combination of externally-controllable factors related to the cooling fluid(s) which does not result in a user-defined ITE failure. See the discussion of how different users may define an ITE failure in the “Background of the Invention” section of this document for further information.

Primary cooling fluid or primary cooling liquid: As used herein, in configurations of the backup system where one cooling fluid exchanges heat with another cooling fluid and both cooling fluids remain hydraulically separated from each other (i.e. they do not mix with each other), the phrase “primary cooling fluid” or “primary cooling liquid” refers to the cooling fluid which is in fluid communication with principal cooling equipment and/or in fluid communication with the liquid-cooled ITE or liquid-cooled ITE racks.

Secondary cooling fluid or secondary cooling liquid: As used herein, in configurations of the backup system where one cooling fluid exchanges heat with another cooling fluid and both cooling fluids remain hydraulically separated from each other (i.e. they do not mix with each other), the phrase “secondary cooling fluid” or “secondary cooling liquid” refers to the cooling fluid which is not in fluid communication with principal cooling equipment and/or is not in fluid communication with the liquid-cooled ITE nor the liquid-cooled ITE racks (i.e. the secondary cooling fluid is the cooling fluid which is further “removed” from the principal cooling equipment and/or from the liquid-cooled ITE).

In parallel or in-parallel: As used herein, the phrases “in parallel” or “in-parallel” refer to two or more devices which are arranged hydraulically such that their fluid inlets share a common source upstream, their fluid outlets share a common destination downstream, or both. As used herein, the phrases “in parallel” or “in-parallel” do not refer to any geometric orientation of devices. Furthermore, the phrases “in parallel” or “in-parallel” do not exclude the use of dissimilar types of devices being arranged in this manner.

In series or in-series: As used herein, the phrases “in series” or “in-series” refer to two or more devices which are arranged hydraulically such that a fluid leaving the fluid outlet of one device is directed to the fluid inlet of a second device. As used herein, the phrases “in series” or “in-series” do not refer to any geometric orientation of devices. Furthermore, the phrases “in series” or “in-series” do not exclude the use of dissimilar types of devices being arranged in this manner.

At least one: As used herein, the phrase “at least one” of a feature or element refers to one or a plurality of that feature or element. Furthermore, the phrase “at least one” does not exclude different types of a particular feature or element from being implemented elsewhere in the backup system. For example, “at least one air amplifier” encompasses a single air amplifier as well as a plurality of air amplifiers, and it does not exclude the use of other types of pneumatically-powered fluid movers from being used in the backup system. As used herein, the phrase “at least one” is synonymous and interchangeable with the terms “a” or “an”.

A or an: As used herein, the terms “a” or “an” of a feature or element refer to one or a plurality of that feature or element. Furthermore, the terms “a” or “an” do not exclude different types of a particular feature or element from being implemented elsewhere in the backup system. For example, “an air amplifier” encompasses a single air amplifier as well as a plurality of air amplifiers, and it does not exclude the use of other types of pneumatically-powered fluid movers from being used in the backup system. As used herein, the terms “a” or “an” are synonymous and interchangeable with the phrase “at least one”.

### BRIEF DESCRIPTION OF DRAWINGS

Non-limiting and non-exhaustive embodiments of the compressed air ride-through system are described with reference to the following figures, wherein like reference numerals refer to like parts throughout the various views unless otherwise specified.

FIG. 1 depicts some of the basic components of an embodiment of the compressed air ride-through system to serve air-cooled ITE, including a compressed air tank, a portable or permanent air compressor, an indication of a non-standard operating condition, an automatic releasing valve, compressed air conduits, and air amplifiers. FIG. 1 also depicts some pathways for room pressure relief/equalization.

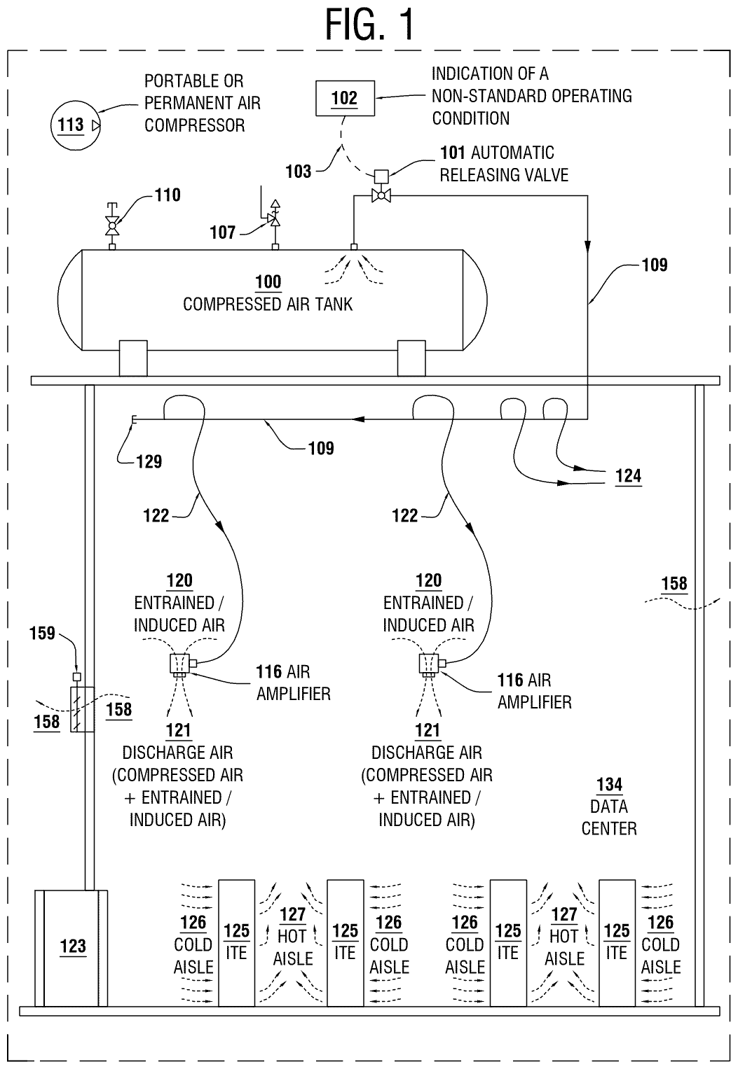

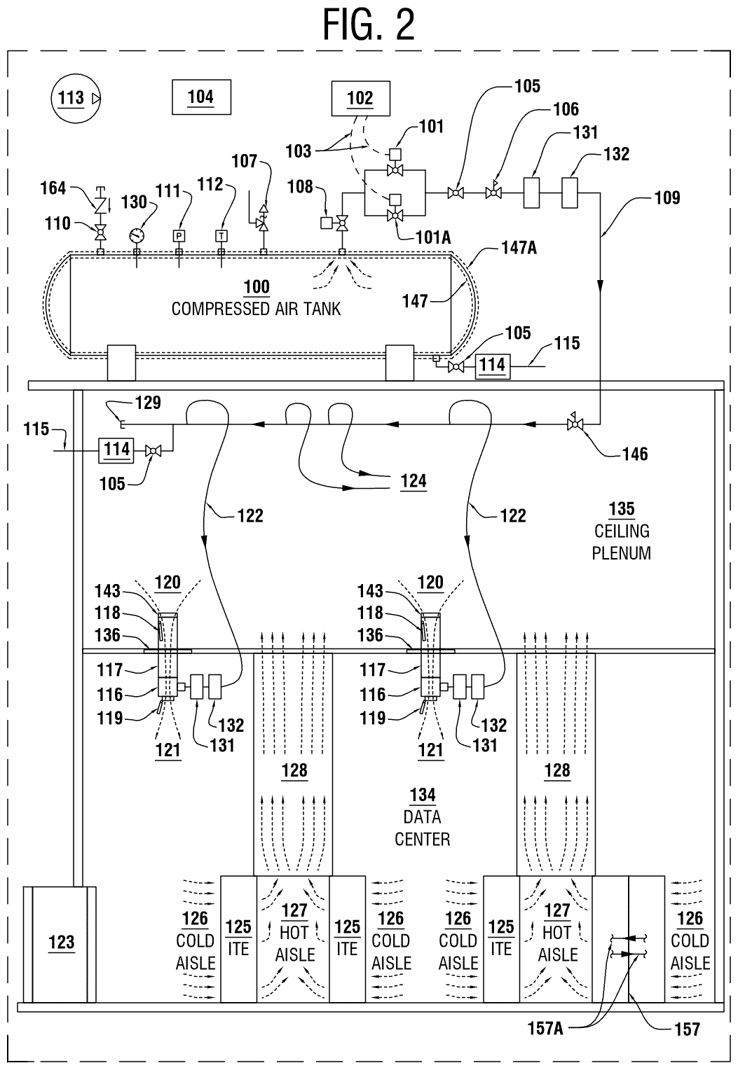

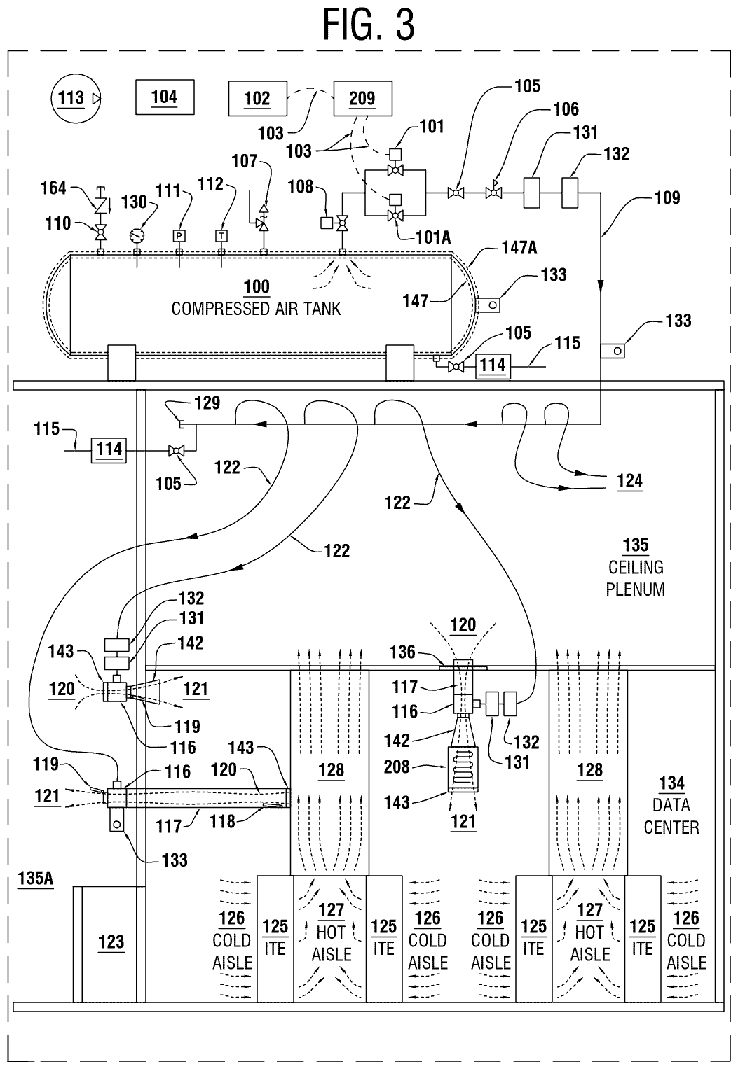

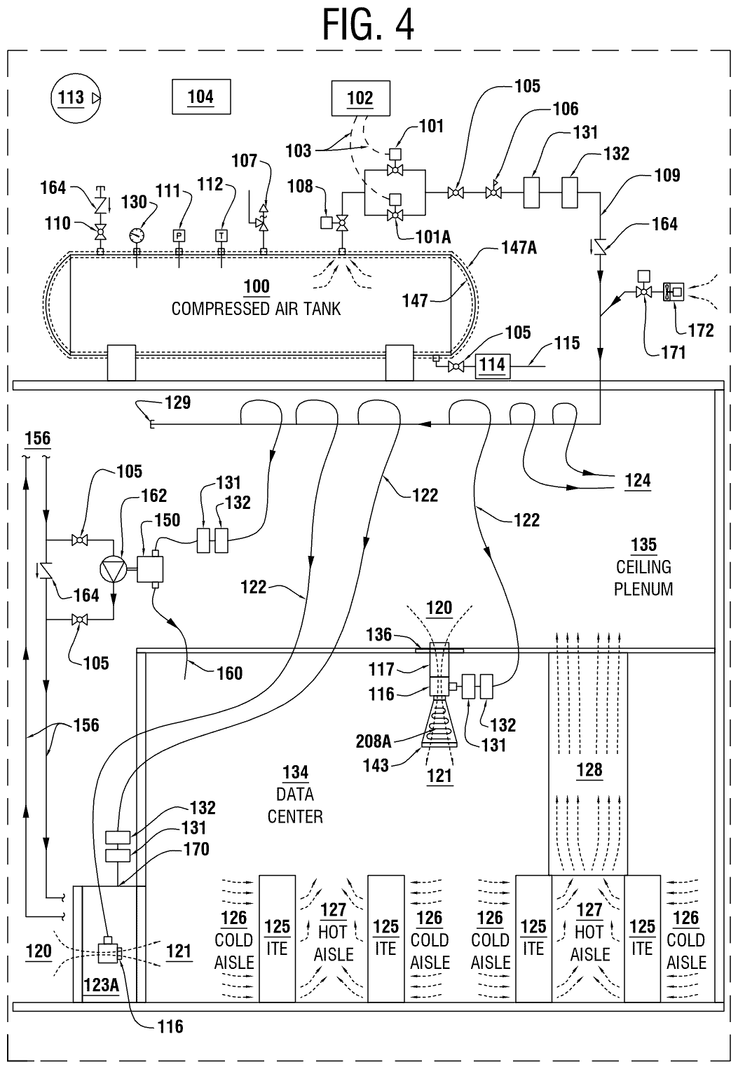

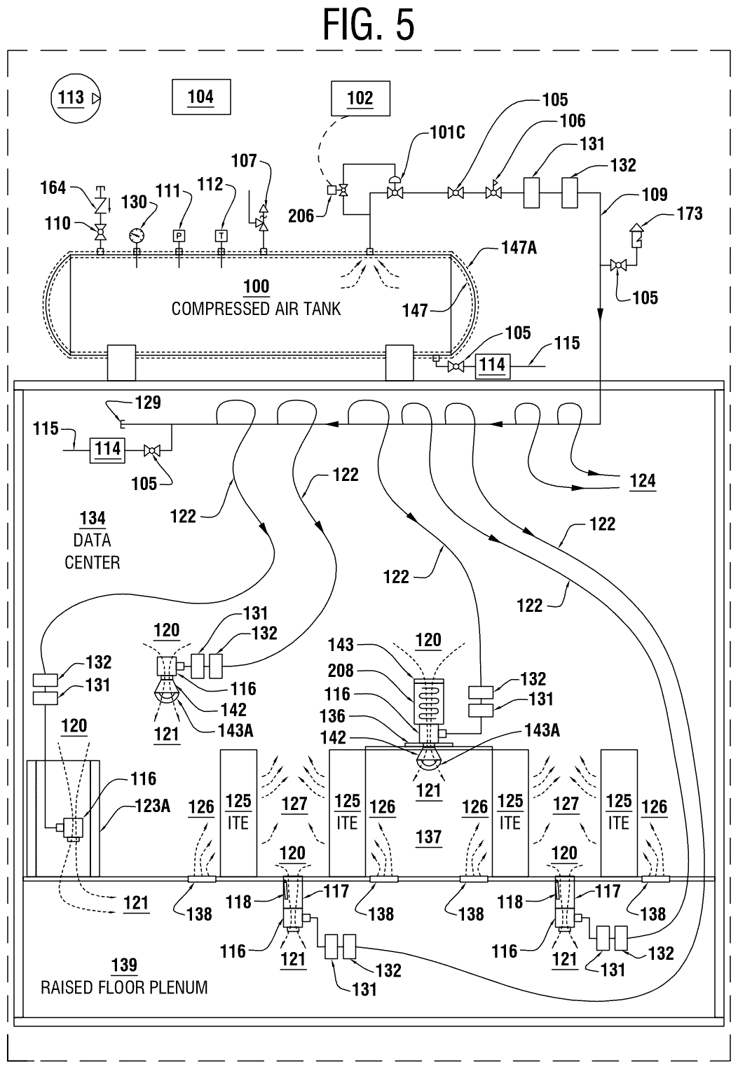

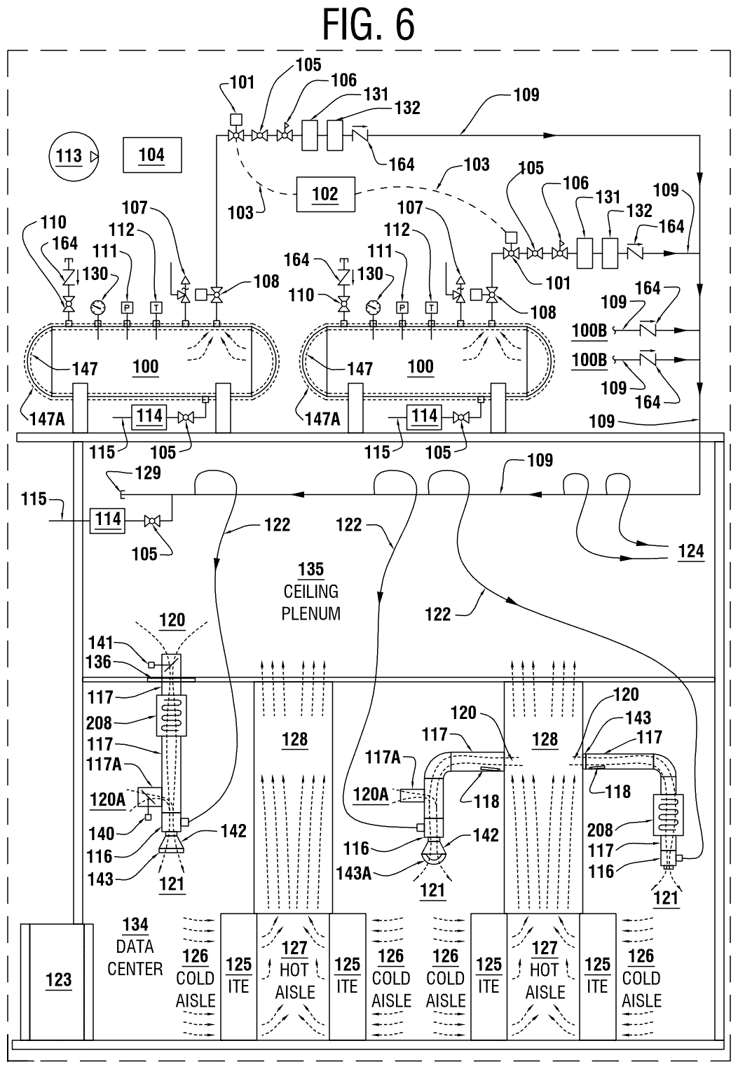

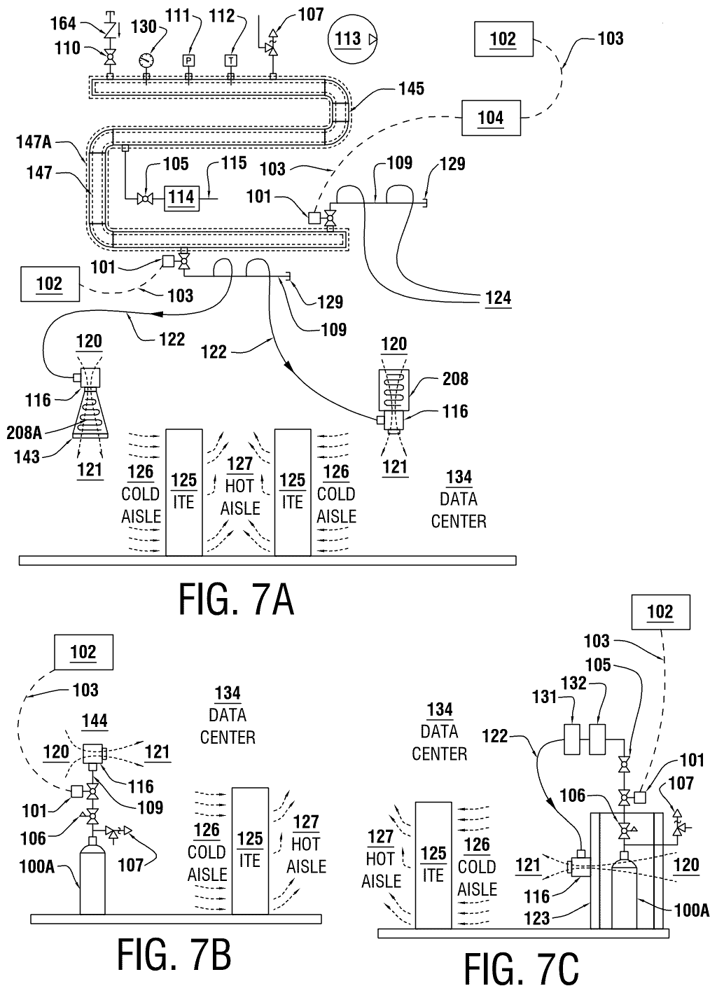

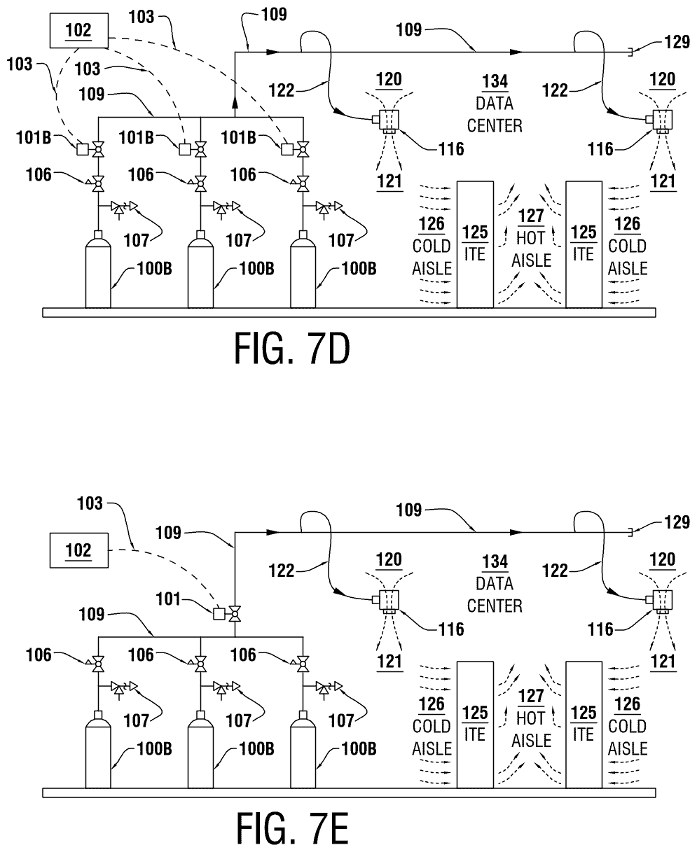

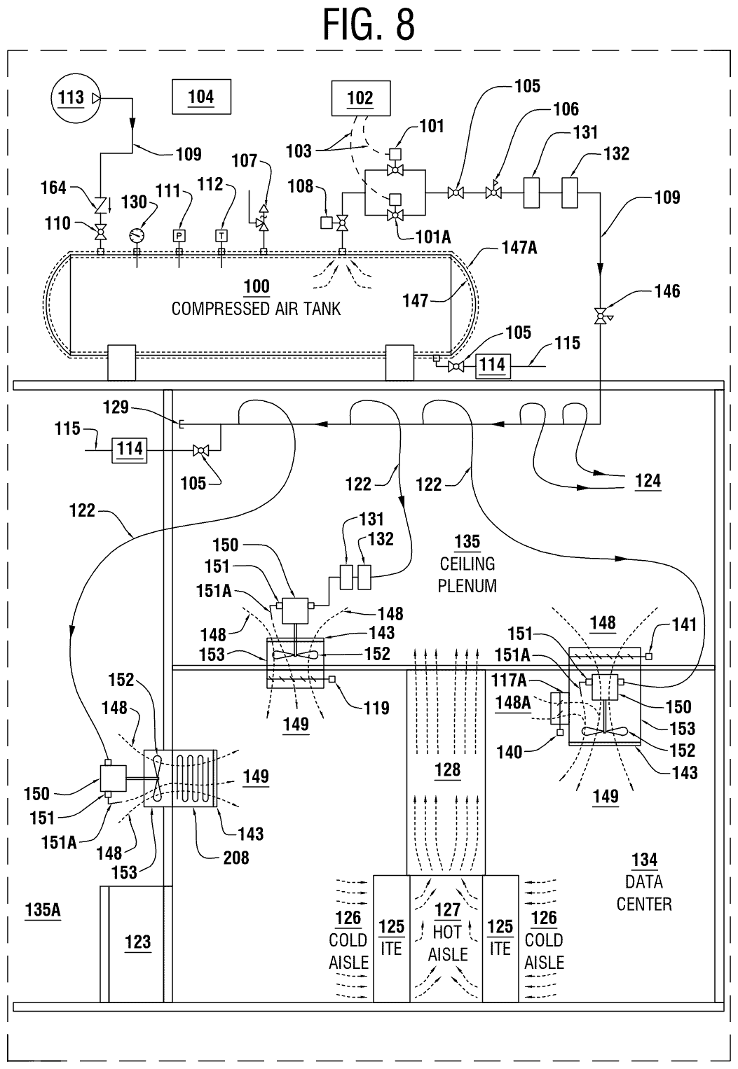

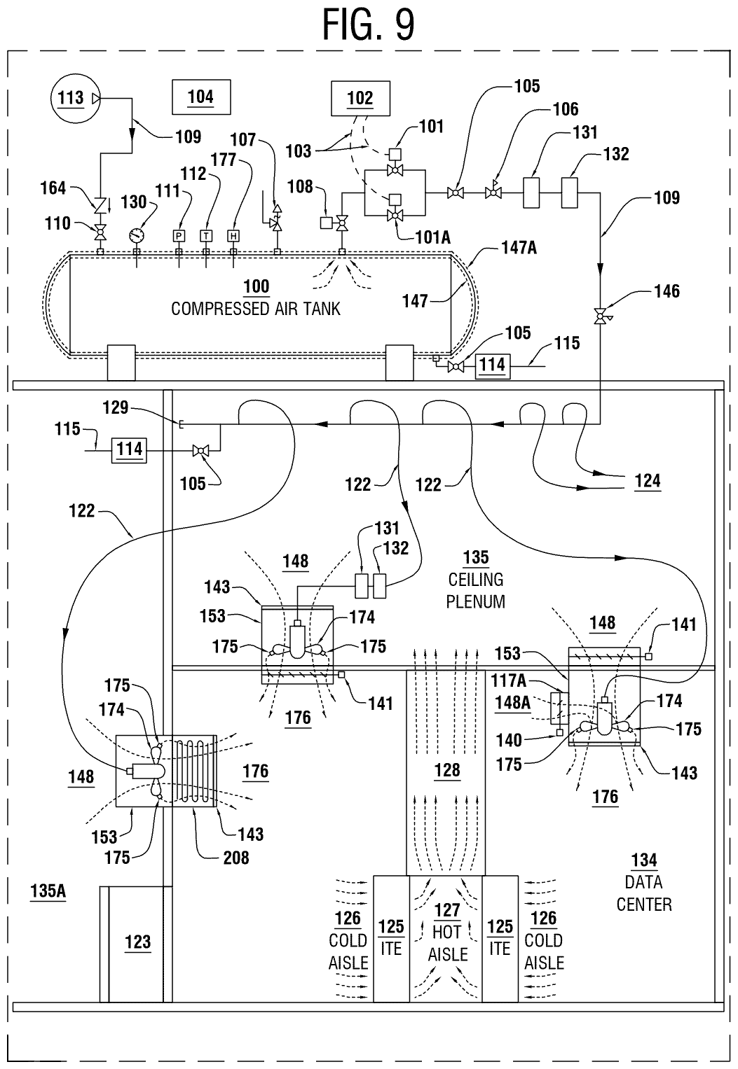

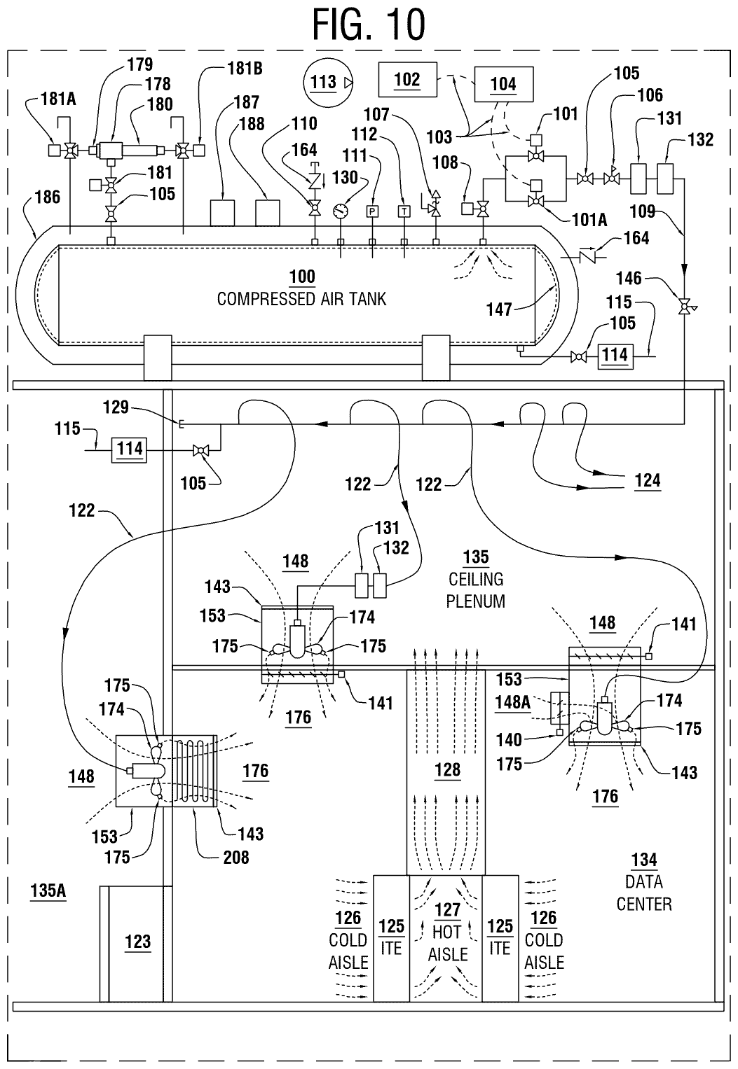

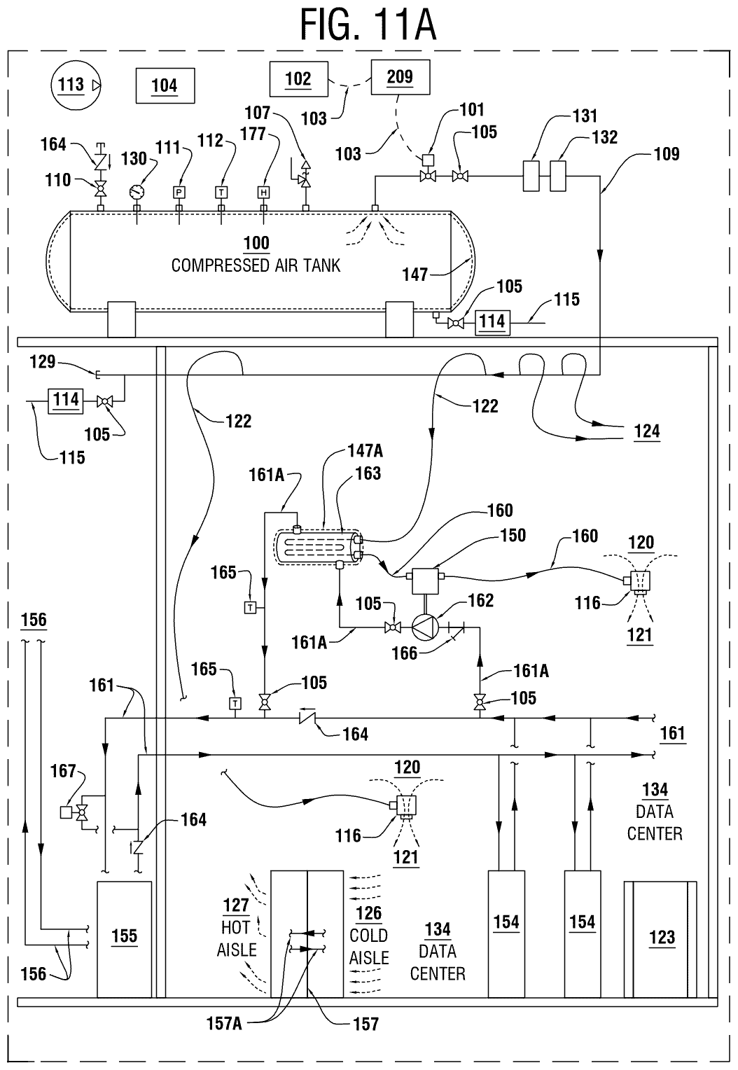

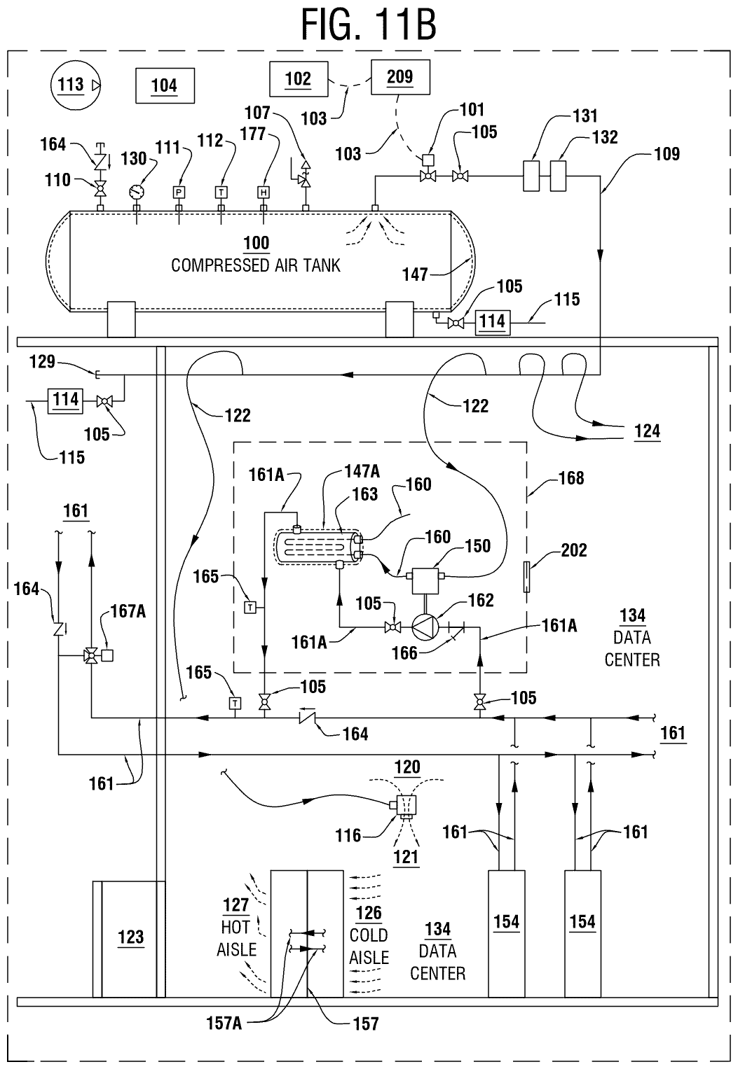

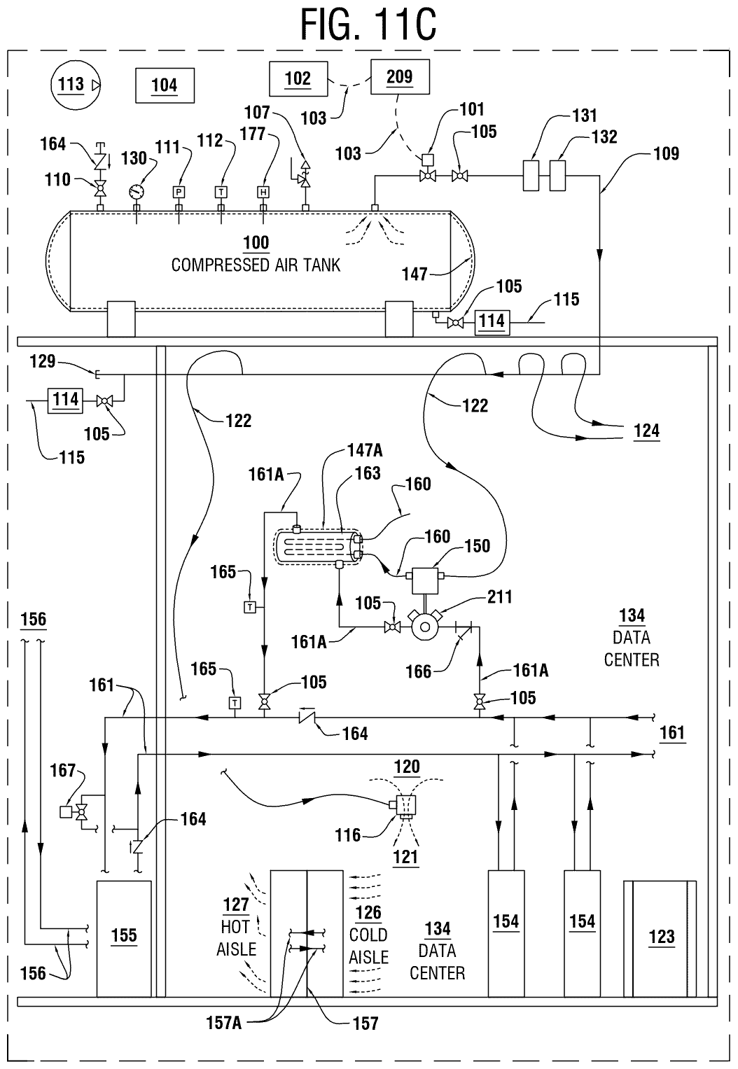

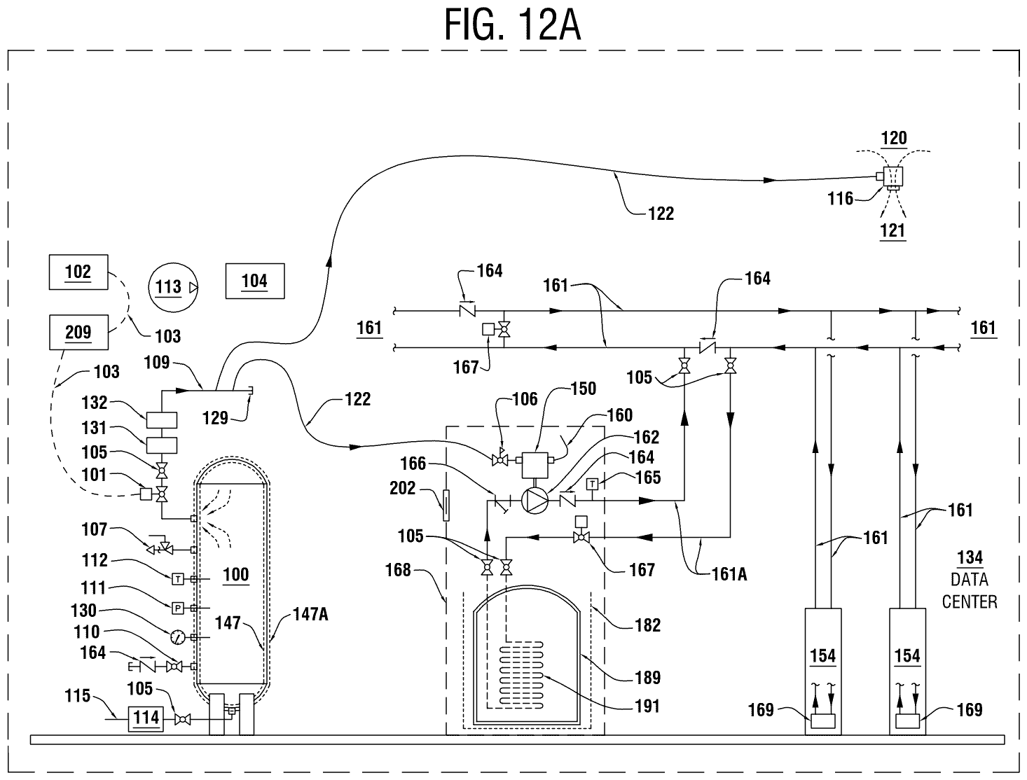

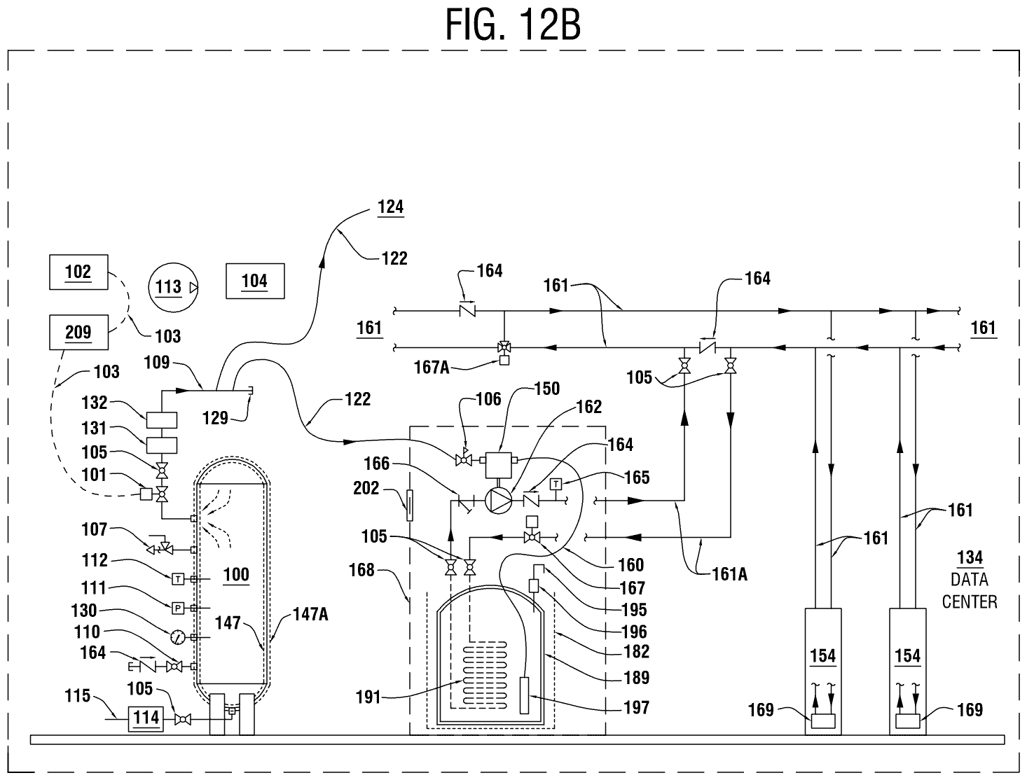

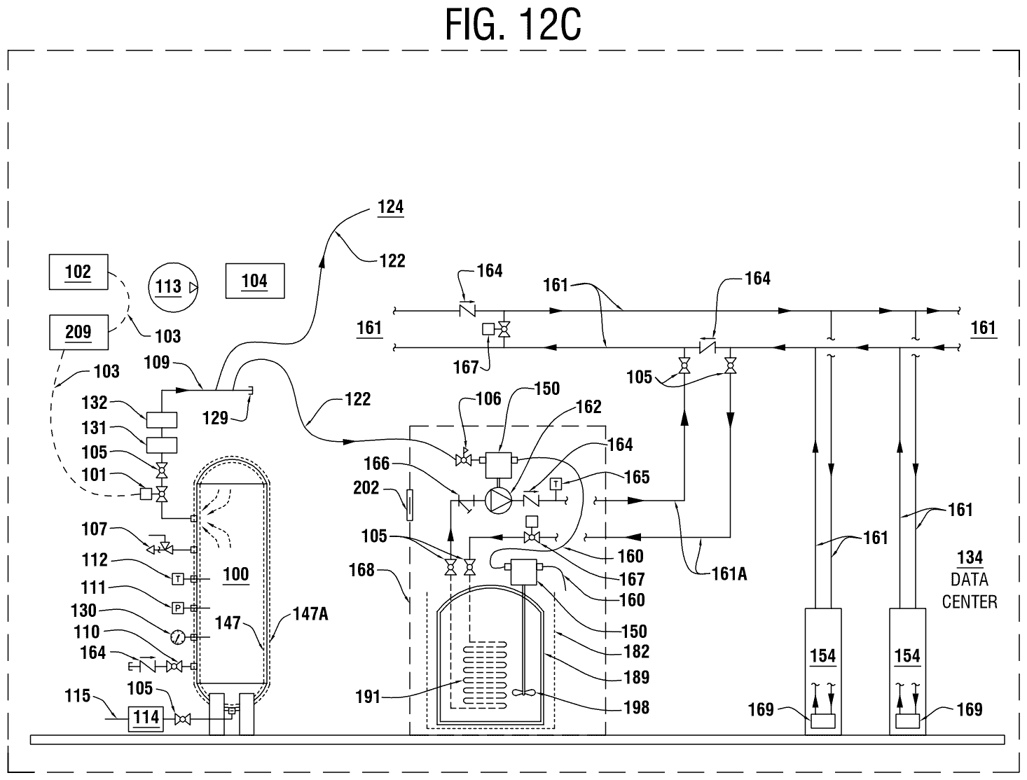

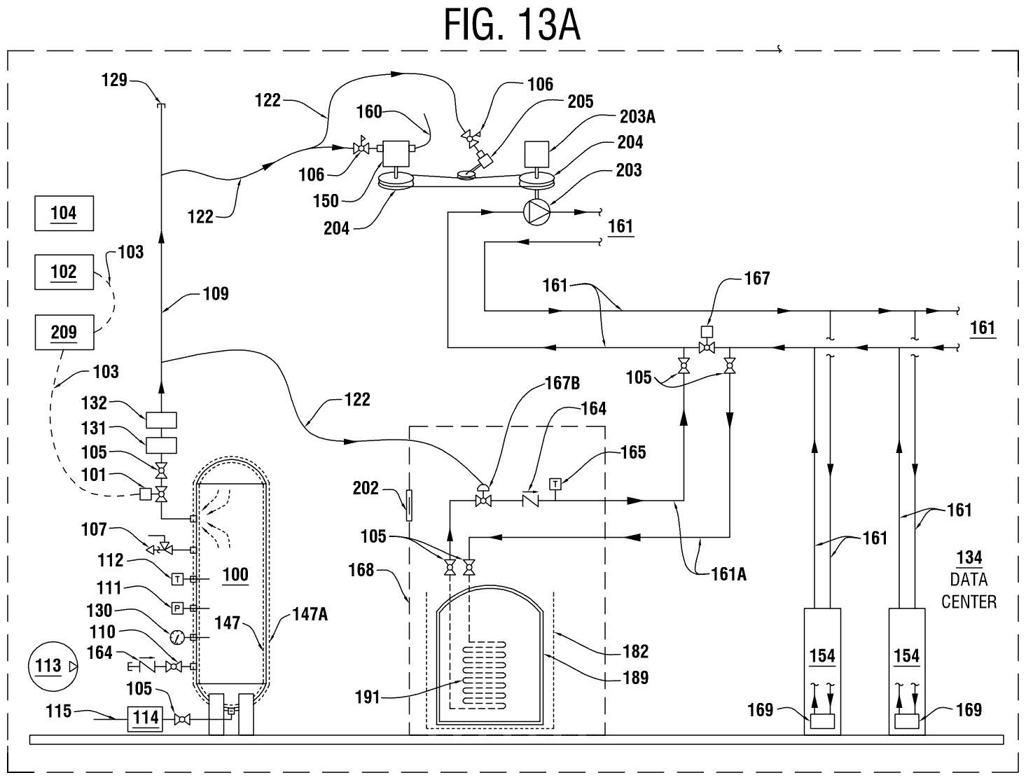

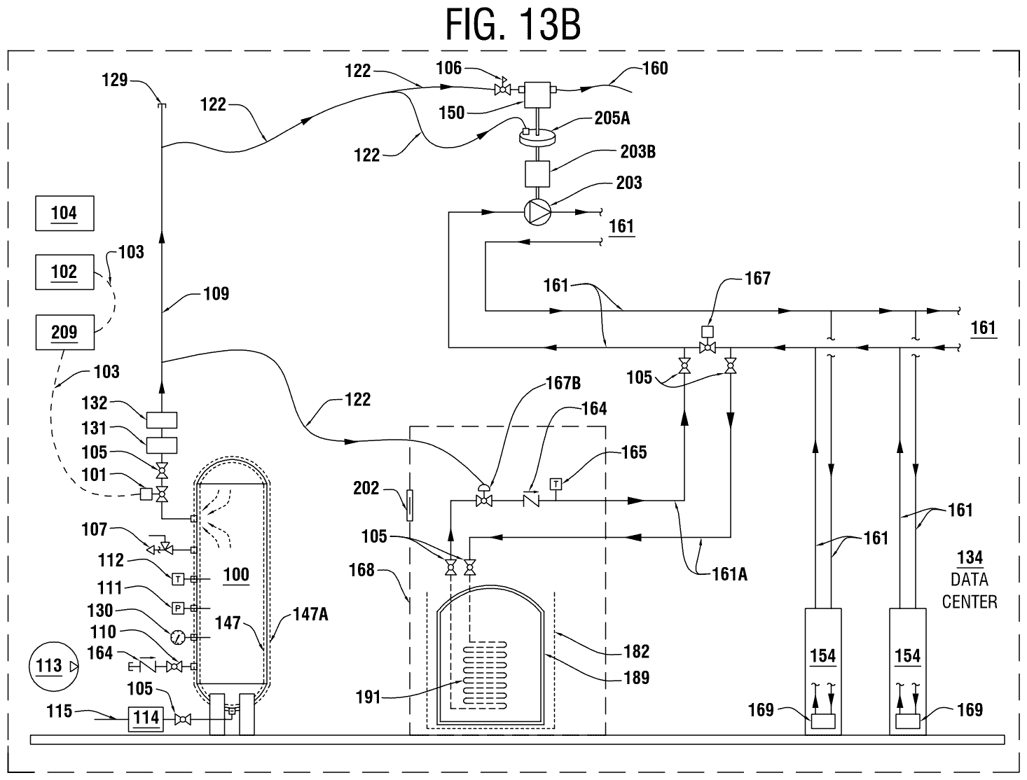

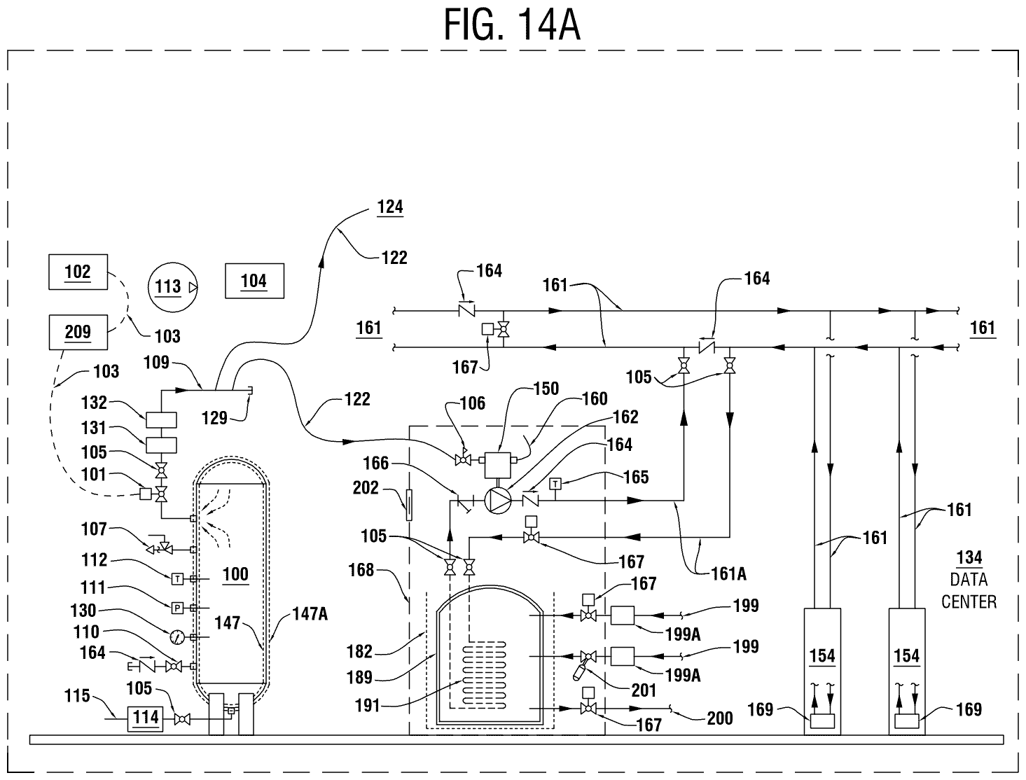

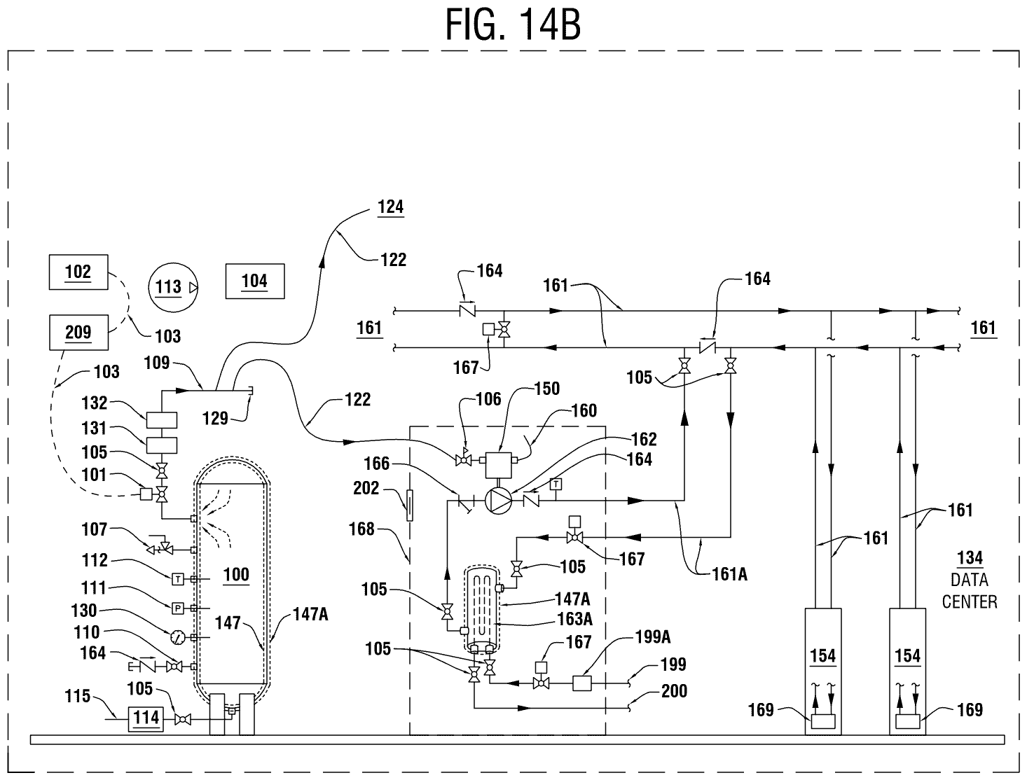

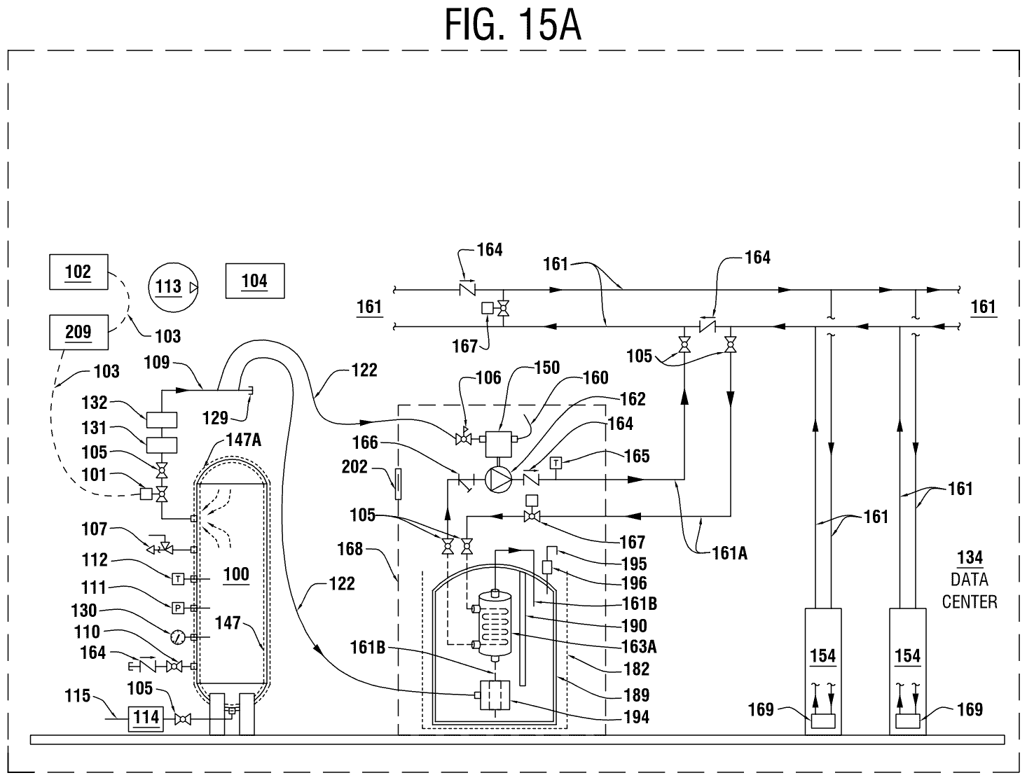

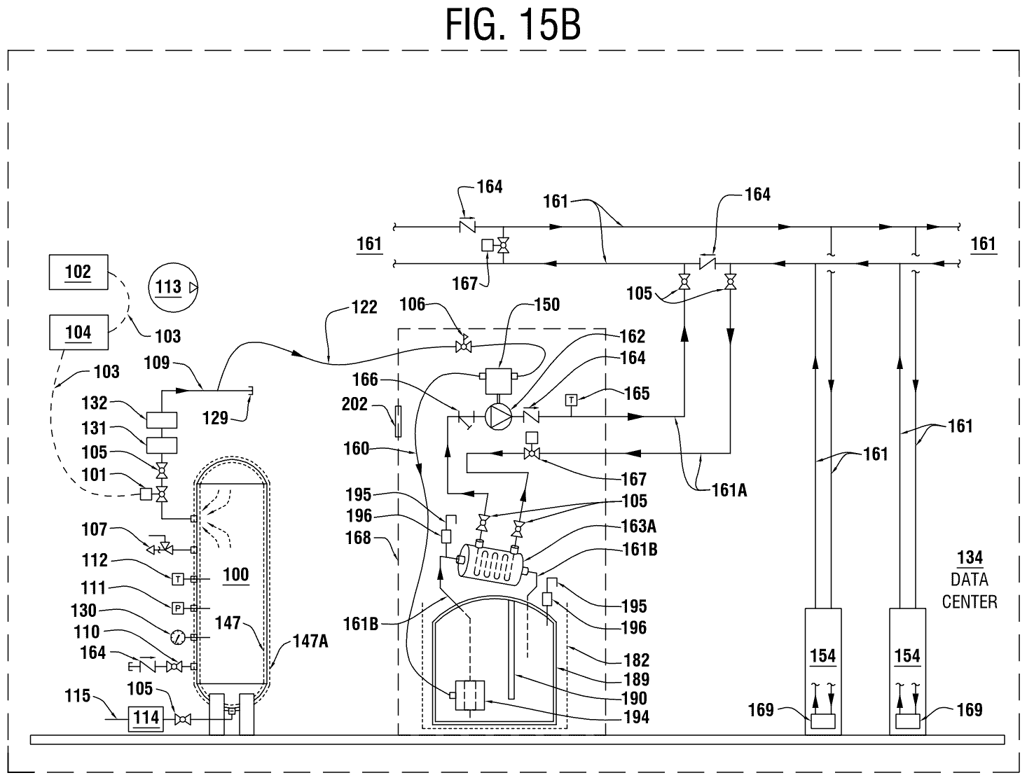

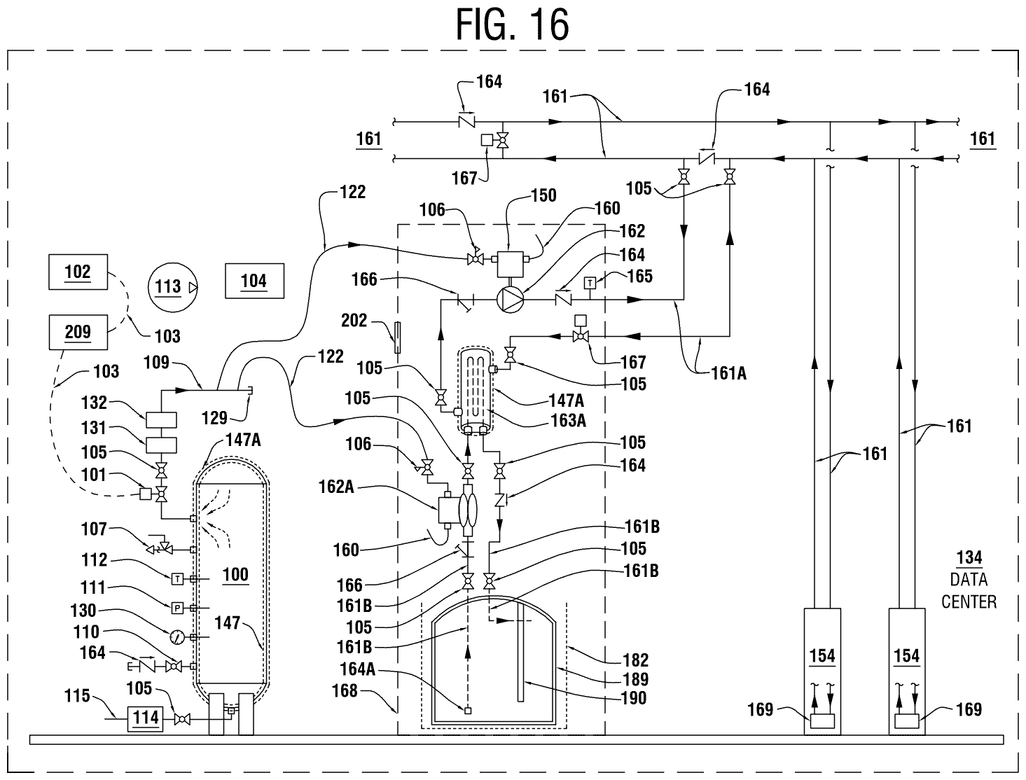

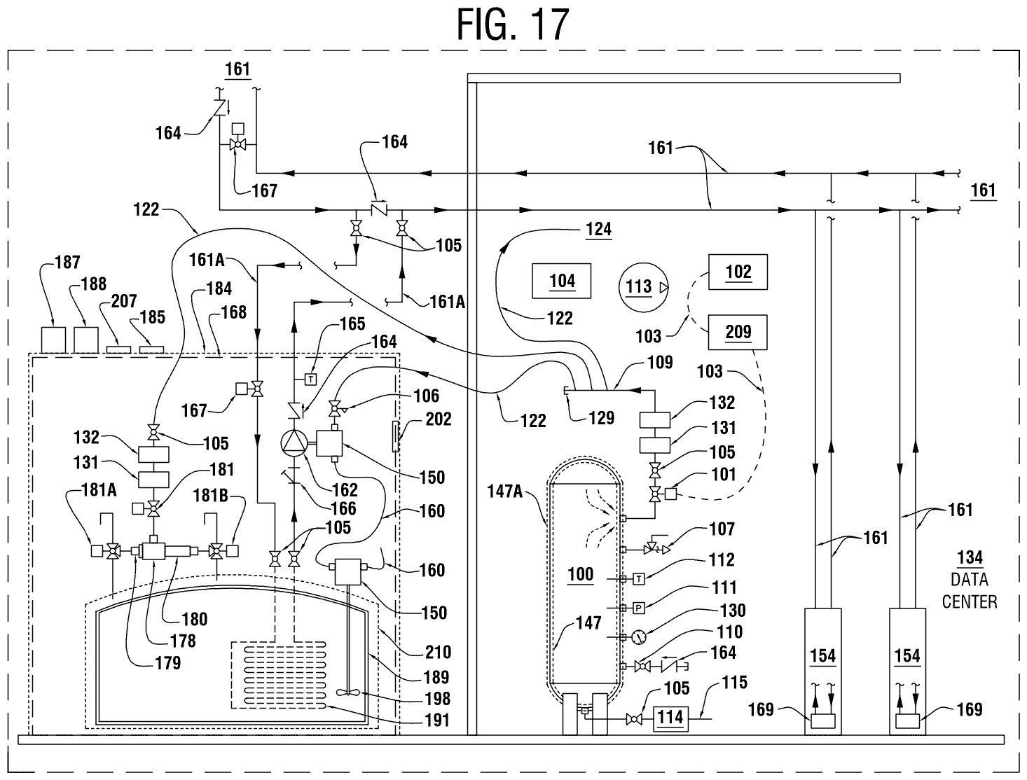

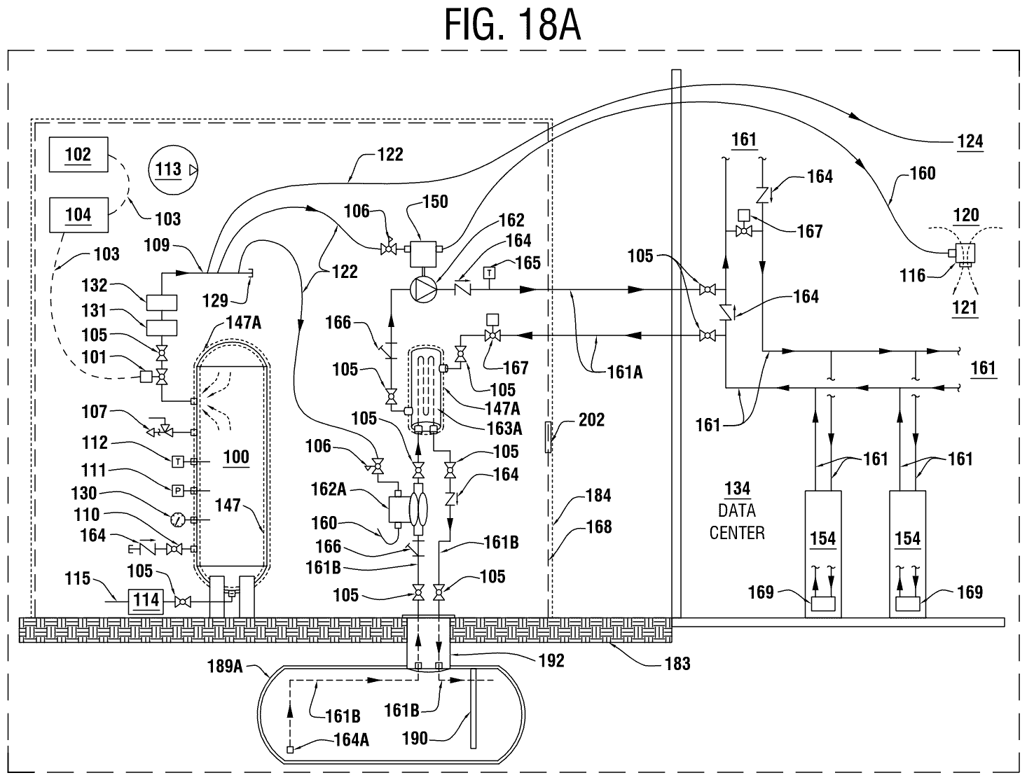

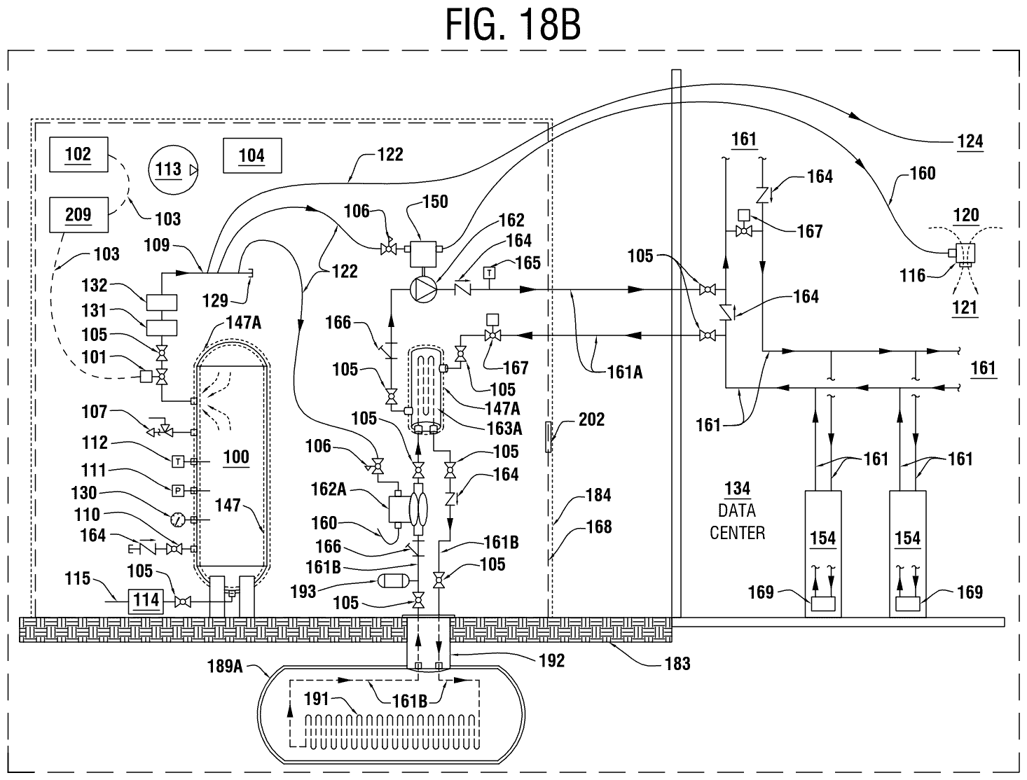

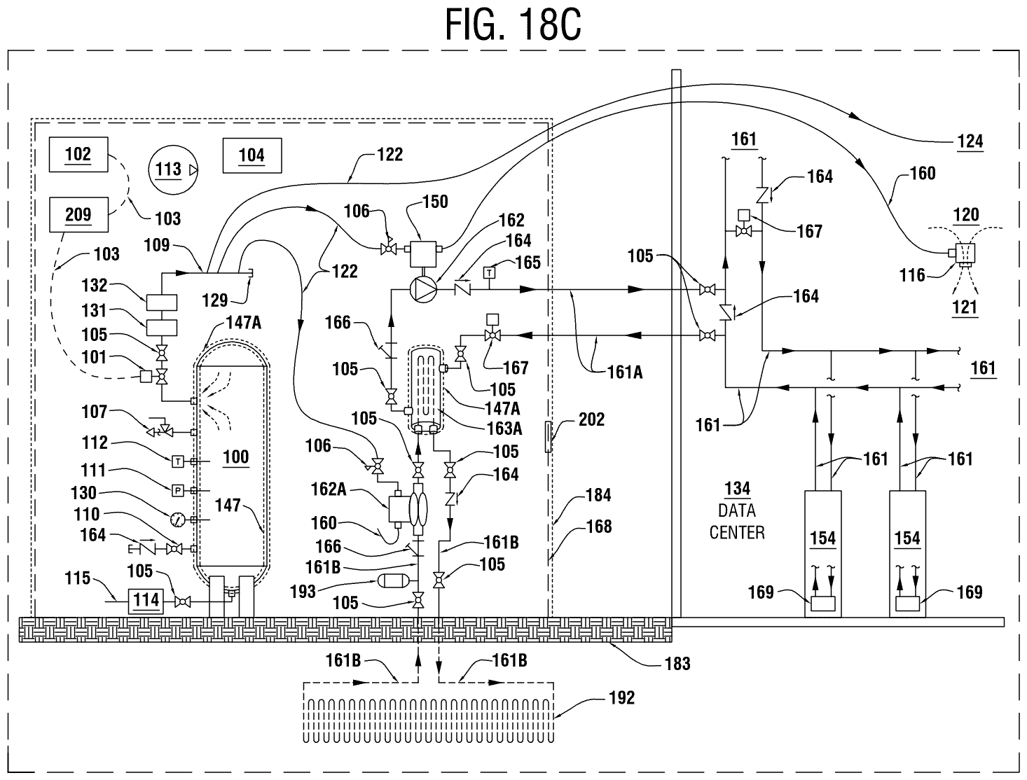

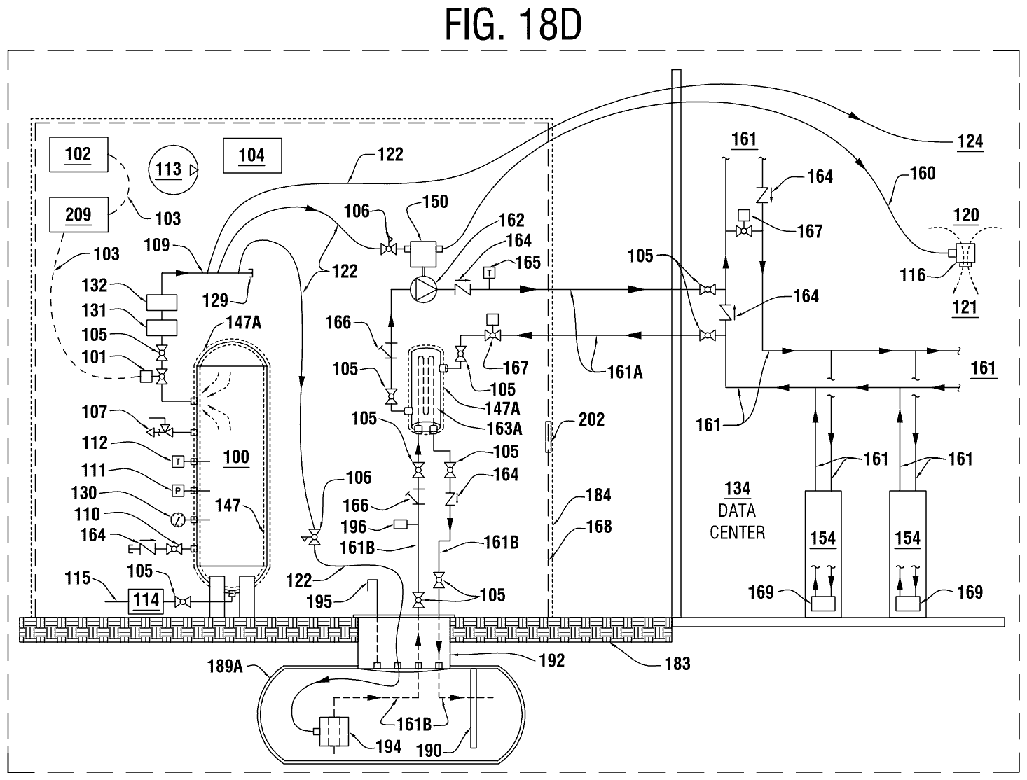

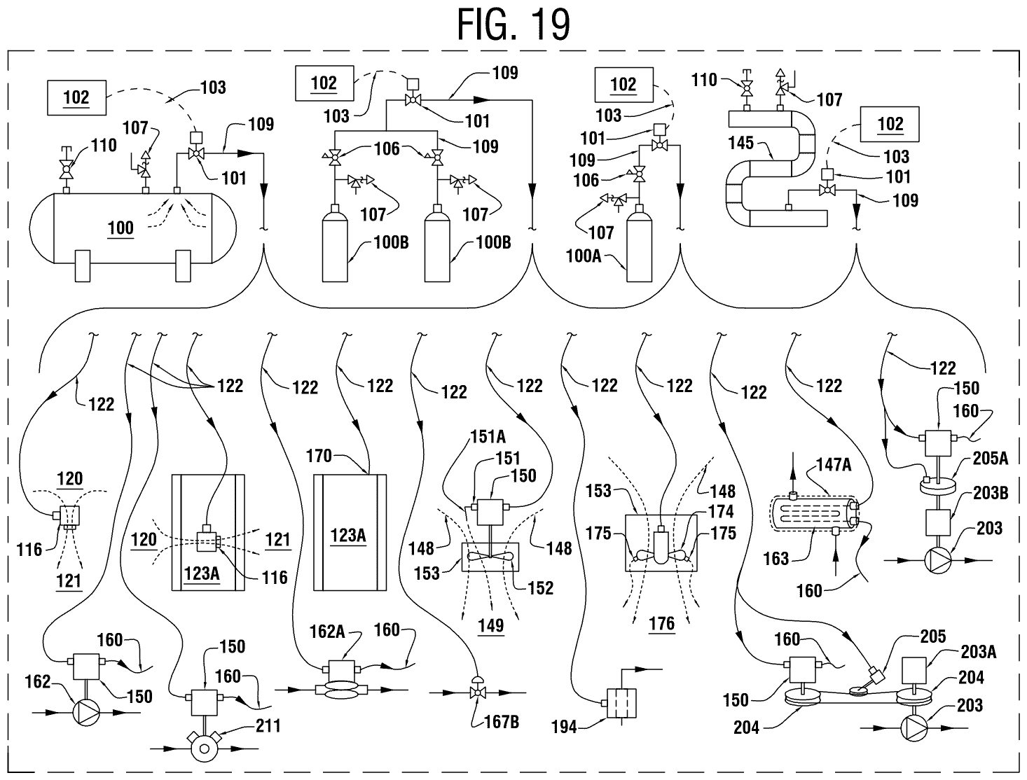

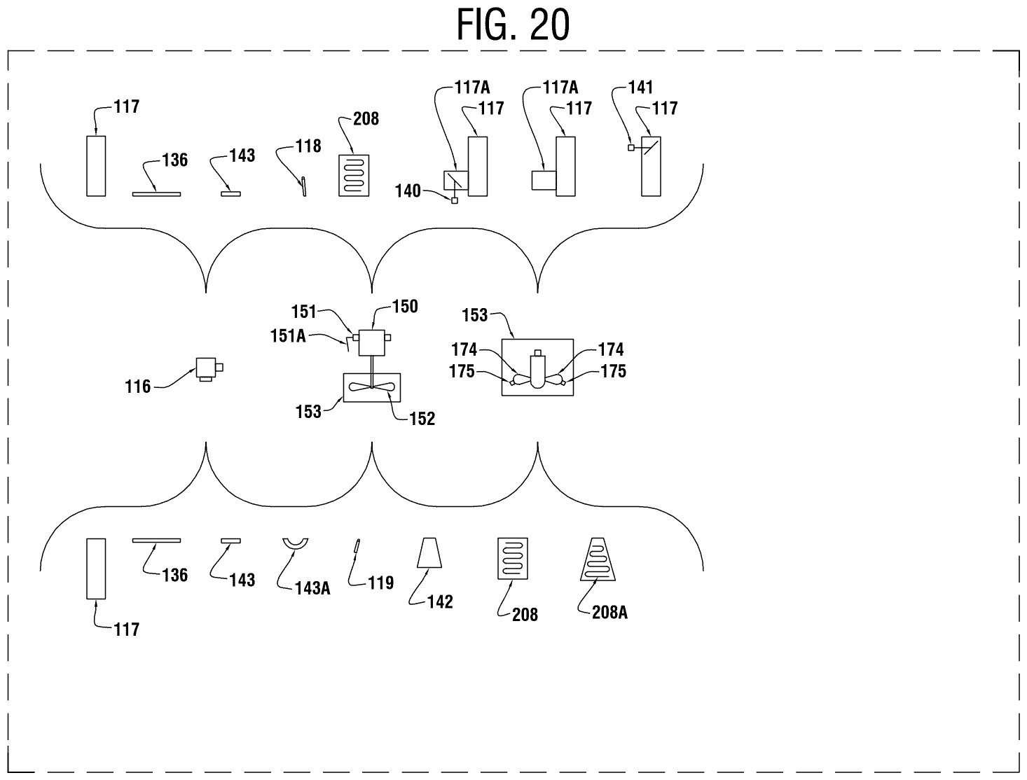

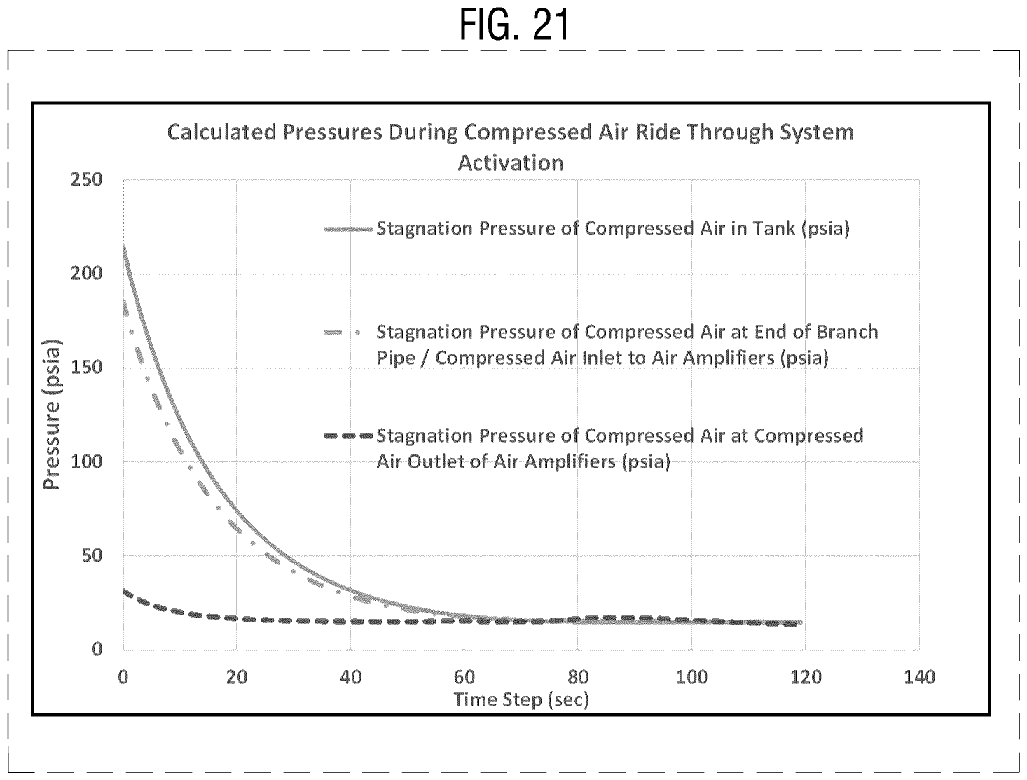

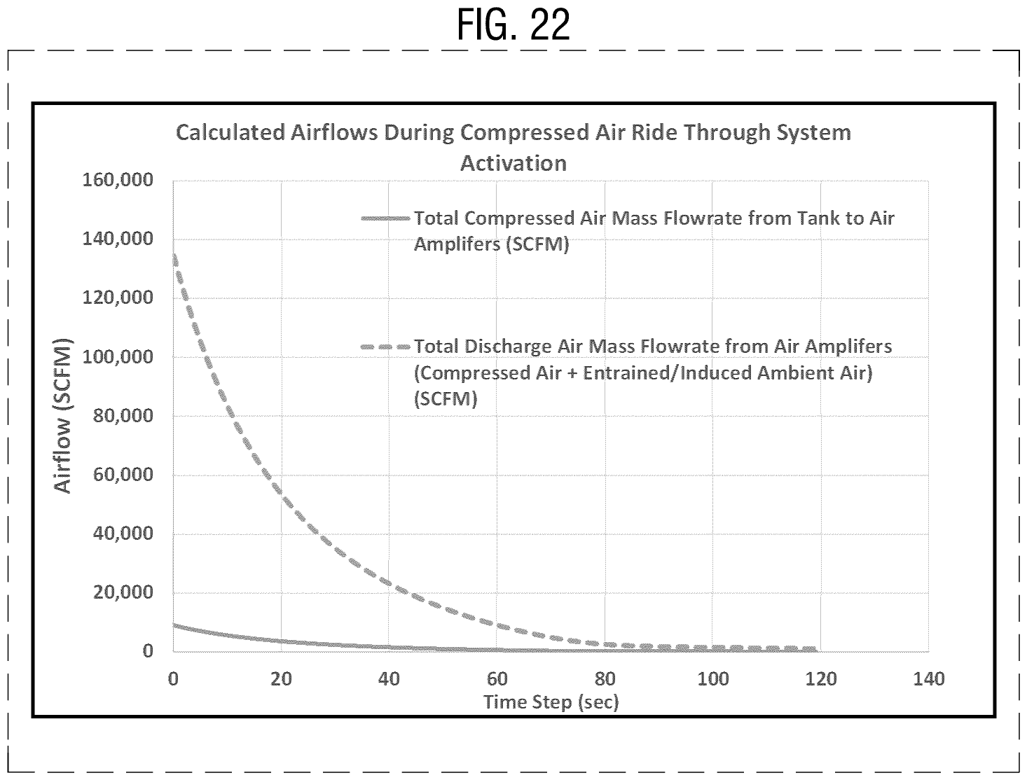

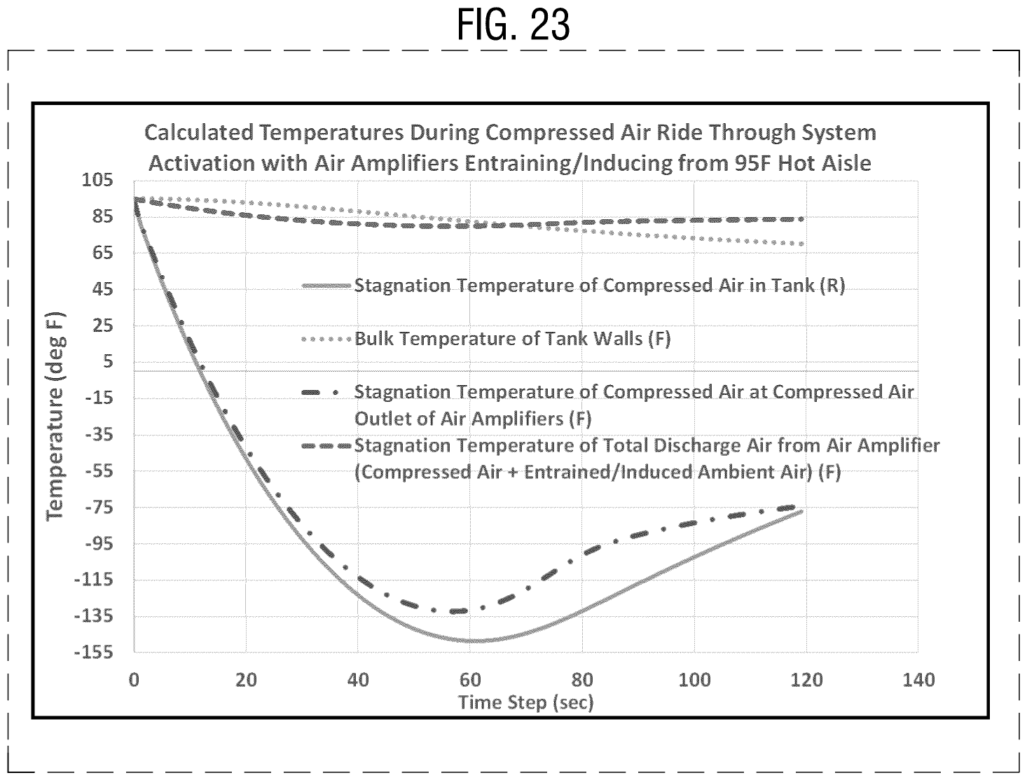

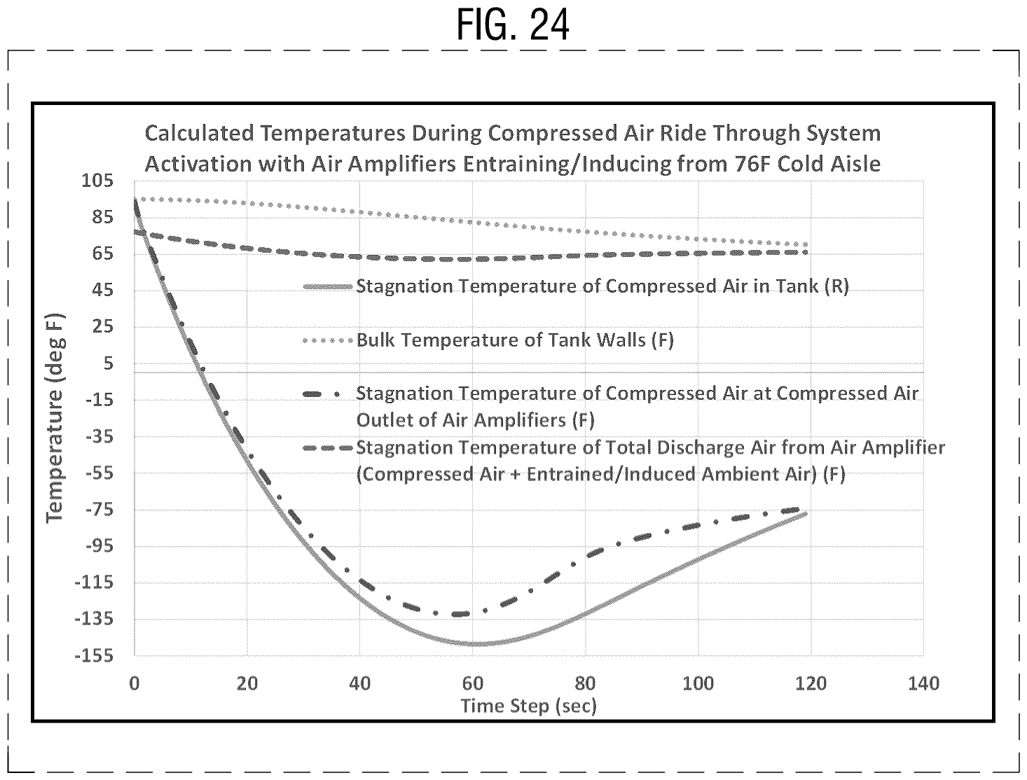

FIG. 2 depicts some of the basic components of the compressed air ride-through system to serve air-cooled ITE, as well as various options/accessories, along with additional configurations/embodiments for:
a. An air amplifier arranged to entrain/induce ambient air from above a ceiling and direct the discharge air into a flooded room/cold aisle;
b. Redundant automatic releasing valves;
c. A fire-alarm-interlocked automatic valve; and
d. An air-cooled sidecar arrangement.

FIG. 3 depicts some of the basic components of the compressed air ride-through system to serve air-cooled ITE, as well as various options/accessories, along with additional configurations/embodiments for:
a. A relay in between an indication of a non-standard operating condition and an automatic releasing valve;
b. An air amplifier arranged to entrain/induce ambient air from a space outside of the data center (such as a CRAH/CRAC gallery) and direct the discharge air into a flooded room/cold aisle;
c. A tapered or untapered duct, nozzle, cone, pipe, or fitting on the discharge of an air amplifier;
d. An air amplifier arranged to entrain/induce ambient air from a hot aisle containment assembly and direct the discharge air into a space outside of the data center (such as a CRAH/CRAC gallery);
e. An air amplifier arranged to entrain/induce ambient air from a ceiling plenum and direct the discharge air into a flooded room/cold aisle; and
f. A passive airside thermal storage heat exchanger on the discharge of an air amplifier.
g. An electrical grounding bar on the compressed air tank, on the compressed air conduit header, and on an air amplifier.

FIG. 4 depicts some of the basic components of the compressed air ride-through system to serve air-cooled ITE, as well as various options/accessories, along with additional configurations/embodiments for:
a. A direct connection of the compressed air to a piece of principal cooling equipment in order to pneumatically-override the principal cooling equipment;
b. An air amplifier installed on, in, or in the vicinity of a piece of principal cooling equipment;
c. An air amplifier arranged to entrain/induce ambient air from a ceiling plenum and direct the discharge air into a flooded room/cold aisle;
d. A passive airside thermal storage heat exchanger arranged in the form of a tapered opening or cone on the discharge of an air amplifier;
e. A valve and fan assembly for warming up the compressed air conduit and other downstream devices following an activation of the compressed air ride-through system; and
f. A pneumatic motor connected to a pump to provide liquid flow of a liquid in a principal cooling equipment liquid loop (such as chilled water, condenser water, glycol, or other heat rejection loop).

FIG. 5 depicts some of the basic components of the compressed air ride-through system to serve air-cooled ITE, as well as various options/accessories, along with additional configurations/embodiments for:
a. A pilot valve controlling a pneumatic automatic releasing valve;
b. An air whistle for mechanical notification of activation of the compressed air ride-through system;
c. An air amplifier installed on, in, or in the vicinity of the principal cooling equipment, arranged to entrain/induce ambient air from the return air inlet of a piece of principal cooling equipment and direct the discharge air down into a raised floor;
d. An air amplifier arranged to entrain/induce ambient air from the data center and direct the discharge air into a flooded room/cold aisle;
e. A curved or hemispherical filter on the discharge side of an air amplifier;
f. An air amplifier arranged to entrain/induce ambient air from the data center and direct the discharge air into a cold aisle into the contained area of a cold aisle containment assembly;
g. A passive airside thermal storage heat exchanger on the entrained/induced air side of an air amplifier; and
h. An air amplifier arranged to entrain/induce ambient air from the hot aisle and direct the discharge air down into a raised floor; and

FIG. 6 depicts some of the basic components of the compressed air ride-through system to serve air-cooled ITE, as well as various options/accessories, along with additional configurations/embodiments for:
a. A plurality of compressed air tanks headered together;
b. An air amplifier arranged to entrain/induce ambient air from a ceiling plenum and from a flooded room/cold aisle and direct the discharge air into a flooded room/cold aisle, along with isolation/modulating device on both entrained/induced air inlets;
c. An air amplifier arranged to entrain/induce ambient air from a hot aisle containment assembly and from a flooded room/cold aisle and direct the discharge air into a flooded room/cold aisle;
d. An air amplifier arranged to entrain/induce ambient air from a hot aisle containment assembly and direct the discharge air into a flooded room/cold aisle; and
e. A passive airside thermal storage heat exchanger on the ductwork upstream of an air amplifier.

FIG. 7A depicts some of the basic components of the compressed air ride-through system to serve air-cooled ITE, as well as various options/accessories, along with additional configurations/embodiments for:
a. Using air-pressurized piping as the compressed air tank;
b. A controller in between an indication of a non-standard operating condition and an automatic releasing valve;
c. An air amplifier arranged to entrain/induce ambient air from the data center and direct the discharge air into a flooded room/cold aisle;
d. A passive airside thermal storage heat exchanger on the entrained/induced air side of an air amplifier; and
e. A passive airside thermal storage heat exchanger on the discharge side of an air amplifier.

FIG. 7B depicts some of the basic components of the compressed air ride-through system to serve air-cooled ITE, as well as various options/accessories, along with additional configurations/embodiments for:
a. A self-contained assembly with a short compressed air conduit between a compressed air tank and an automatic releasing valve, and a short compressed air conduit between the automatic releasing valve and an air amplifier; and
b. An air amplifier arranged to entrain/induce ambient air from the data center and direct the discharge air into a flooded room/cold aisle.

FIG. 7C depicts some of the basic components of the compressed air ride-through system to serve air-cooled ITE, as well as various options/accessories, along with additional configurations/embodiments for:
a. A compressed air tank installed on, inside of, adjacent to, or in the vicinity of a piece of principal cooling equipment; and
b. An air amplifier installed on, in, or in the vicinity of a piece of principal cooling equipment, arranged to entrain/induce ambient air from the return air inlet of a piece of principal cooling equipment and direct the discharge air into a flooded room/cold aisle.

FIG. 7D depicts some of the basic components of the compressed air ride-through system to serve air-cooled ITE, as well as various options/accessories, along with additional configurations/embodiments for:
a. A plurality of compressed air tanks headered together through a compressed air conduit, with an automatic releasing valve downstream of each compressed air tank; and
b. An air amplifier arranged to entrain/induce ambient air from the data center and direct the discharge air into a flooded room/cold aisle.

FIG. 7E depicts some of the basic components of the compressed air ride-through system to serve air-cooled ITE, as well as various options/accessories, along with additional configurations/embodiments for:
a. A plurality of compressed air tanks headered together through a compressed air conduit, with a single automatic releasing valve downstream of all compressed air tanks; and
b. An air amplifier arranged to entrain/induce ambient air from the data center and direct the discharge air into a flooded room/cold aisle.

FIG. 8 depicts some of the basic components of the compressed air ride-through system to serve air-cooled ITE, as well as various options/accessories, along with additional configurations/embodiments for:
a. A compressed air conduit connecting a compressor to a compressed air tank;
b. A pneumatic motor connected to a fan arranged to entrain/induce ambient air from a space outside of the data center (such as a CRAH/CRAC gallery) and direct the discharge air into a flooded room/cold aisle;
c. A pneumatic motor connected to a fan arranged to entrain/induce ambient air from a ceiling plenum and direct the discharge air into a flooded room/cold aisle, with the pneumatic motor and fan located in the ceiling plenum;
d. A pneumatic motor connected to a fan arranged to entrain/induce ambient air from a ceiling plenum and direct the discharge air into a flooded room/cold aisle, with the pneumatic motor and fan located below the ceiling plenum, along with isolation/modulating device on both entrained/induced air inlets; and
e. A passive airside thermal storage heat exchanger on the discharge of a fan which is driven by a pneumatic motor.

FIG. 9 depicts some of the basic components of the compressed air ride-through system to serve air-cooled ITE, as well as various options/accessories, along with additional configurations/embodiments for:
a. A compressed air conduit connecting a compressor to a compressed air tank;
b. A reaction-type fan arranged to entrain/induce ambient air from a space outside of the data center (such as a CRAH/CRAC gallery) and direct the discharge air into a flooded room/cold aisle;
c. A reaction-type fan arranged to entrain/induce ambient air from a ceiling plenum and direct the discharge air into a flooded room/cold aisle, with the reaction-type fan located in the ceiling plenum;
d. A reaction-type fan arranged to entrain/induce ambient air from a ceiling plenum and direct the discharge air into a flooded room/cold aisle, with the reaction-type fan located below the ceiling plenum, along with isolation/modulating device on both entrained/induced air inlets; and
e. A passive airside thermal storage heat exchanger on the discharge of a reaction-type fan.

FIG. 10 depicts some of the basic components of the compressed air ride-through system to serve air-cooled ITE, as well as various options/accessories, along with additional configurations/embodiments for:
a. A vortex tube for cooling and/or heating an outer shell or insulating jacket around a compressed air tank, along with associated control valves and a check valve;
b. A traditional electric-powered heater/heat tracing for heating a compressed air tank;
c. A traditional electric-powered coolers for cooling a compressed air tank;
d. A reaction-type fan arranged to entrain/induce ambient air from a space outside of the data center (such as a CRAH/CRAC gallery) and direct the discharge air into a flooded room/cold aisle;
e. A reaction-type fan arranged to entrain/induce ambient air from a ceiling plenum and direct the discharge air into a flooded room/cold aisle, with the reaction-type fan located in the ceiling plenum;
f. A reaction-type fan arranged to entrain/induce ambient air from a ceiling plenum and direct the discharge air into a flooded room/cold aisle, with the reaction-type fan located below the ceiling plenum, along with isolation/modulating device on both entrained/induced air inlets; and
g. A passive airside thermal storage heat exchanger on the discharge of a reaction-type fan.

FIG. 11A depicts some of the basic components of the compressed air ride-through system to serve air-cooled ITE and liquid-cooled ITE, as well as various options/accessories, along with additional configurations/embodiments for:
a. A relay in between an indication of a non-standard operating condition and an automatic releasing valve;
b. A pneumatic motor connected to a pump and a compressed-air-to-cooling-fluid heat exchanger, both of which are connected to a primary loop which is connected to a TCS loop served by a cooling distribution unit with associated valving, wherein the compressed air leaving the compressed air outlet of the compressed-air-to-cooling-fluid heat exchanger is directed through a secondary compressed air conduit to the inlet of the pneumatic motor;
c. An air amplifier arranged to entrain/induce ambient air from the data center and direct the discharge air into a flooded room/cold aisle;
d. An air amplifier arranged to entrain/induce ambient air from the data center and direct the discharge air into a flooded room/cold aisle, wherein the compressed air leaving a pneumatic motor is directed through a secondary compressed air conduit to the inlet of the air amplifier;
e. A centralized cooling distribution unit; and
f. An air-cooled sidecar arrangement.

FIG. 11B depicts some of the basic components of the compressed air ride-through system to serve air-cooled ITE and liquid-cooled ITE, as well as various options/accessories, along with additional configurations/embodiments for:
a. A relay in between an indication of a non-standard operating condition and an automatic releasing valve;
b. A pneumatic motor connected to a pump and a compressed-air-to-cooling-fluid heat exchanger, both of which are connected to a primary loop which is connected to a TCS loop with associated valving, wherein the compressed air leaving the compressed air outlet of the pneumatic motor is directed through a secondary compressed air conduit to the inlet of the compressed-air-to-cooling-fluid heat exchanger;
c. An air amplifier arranged to entrain/induce ambient air from the data center and direct the discharge air into a flooded room/cold aisle; and
d. An air-cooled sidecar arrangement.

FIG. 11C depicts some of the basic components of the compressed air ride-through system to serve air-cooled ITE and liquid-cooled ITE, as well as various options/accessories, along with additional configurations/embodiments for:
a. A relay in between an indication of a non-standard operating condition and an automatic releasing valve;
b. A pneumatic motor connected to a compressor and a compressed-air-to-cooling-fluid heat exchanger, both of which are connected to a primary loop which is connected to a TCS loop with associated valving, wherein the compressed air leaving the compressed air outlet of the pneumatic motor is directed through a secondary compressed air conduit to the inlet of the compressed-air-to-cooling-fluid heat exchanger;
c. An air amplifier arranged to entrain/induce ambient air from the data center and direct the discharge air into a flooded room/cold aisle;
d. A centralized cooling distribution unit; and
e. An air-cooled sidecar arrangement.

FIG. 12A depicts some of the basic components of the compressed air ride-through system to serve air-cooled ITE and liquid-cooled ITE, as well as various options/accessories, along with additional configurations/embodiments for:
a. A primary-only arrangement for movement and cooling of a liquid/refrigerant cooling fluid in a TCS loop with associated valving, including:
   i. A pneumatic motor connected to a pump connected to a primary loop; and
   ii. An immersed coil/heat exchanger connected to a primary loop, wherein the immersed coil/heat exchanger is inside of a thermal storage tank which houses a thermal storage media;
b. An enclosure which houses a thermal storage tank and other components;
c. An air amplifier arranged to entrain/induce ambient air from the data center and direct the discharge air into a flooded room/cold aisle; and
d. A rack-level cooling distribution unit.

FIG. 12B depicts some of the basic components of the compressed air ride-through system to serve liquid-cooled ITE, as well as various options/accessories, along with additional configurations/embodiments for:
a. A primary-only arrangement for movement and cooling of a liquid/refrigerant cooling fluid in a TCS loop with associated valving, including:
   i. A pneumatic motor connected to a pump connected to a primary loop;
   ii. An immersed coil/heat exchanger connected to a primary loop, wherein the immersed coil/heat exchanger is inside of a thermal storage tank which houses a thermal storage media; and
   iii. A submerged compressed air direct injector inside of a thermal storage tank, wherein the compressed air leaving the compressed air outlet of the pneumatic motor is directed through a secondary compressed air conduit to the inlet of the submerged compressed air direct injector;
b. An enclosure which houses a thermal storage tank and other components; and
c. A rack-level cooling distribution unit.

FIG. 12C depicts some of the basic components of the compressed air ride-through system to serve liquid-cooled ITE, as well as various options/accessories, along with additional configurations/embodiments for:
a. A primary-only arrangement for movement and cooling of a liquid/refrigerant cooling fluid in a TCS loop with associated valving, including:
   i. A pneumatic motor connected to a pump connected to a primary loop;
   ii. An immersed coil/heat exchanger connected to a primary loop, wherein the immersed coil/heat exchanger is inside of a thermal storage tank which houses a thermal storage media; and
   iii. A pneumatic motor connected to a mechanical-type agitator inside of a thermal storage tank, wherein the compressed air leaving the compressed air outlet of the pneumatic motor serving the pump is directed through a secondary compressed air conduit to the inlet of the pneumatic motor serving the mechanical-type agitator;
b. An enclosure which houses a thermal storage tank and other components; and
c. A rack-level cooling distribution unit.

FIG. 13A depicts some of the basic components of the compressed air ride-through system to serve liquid-cooled ITE, as well as various options/accessories, along with additional configurations/embodiments for:
a. A primary-only arrangement for movement and cooling of a liquid/refrigerant cooling fluid in a TCS loop with associated valving, including:
   i. A pneumatically-overridden pump connected to a primary loop, wherein a pneumatic motor with belts, sheaves/pulleys, and a belt tensioner are arranged to pneumatically-override an electric motor serving a normally-electric-driven pump; and
   ii. An immersed coil/heat exchanger connected to a primary loop, wherein the immersed coil/heat exchanger is inside of a thermal storage tank which houses a thermal storage media;
b. An enclosure which houses a thermal storage tank and other components; and
c. A rack-level cooling distribution unit.

FIG. 13B depicts some of the basic components of the compressed air ride-through system to serve liquid-cooled ITE, as well as various options/accessories, along with additional configurations/embodiments for:
a. A primary-only arrangement for movement and cooling of a liquid/refrigerant cooling fluid in a TCS loop with associated valving, including:
   i. A pneumatically-overridden pump connected to a primary loop, wherein a pneumatic motor and a pneumatic clutch are arranged to pneumatically-override a dual-shafted electric motor serving a normally-electric-driven pump; and
   ii. An immersed coil/heat exchanger connected to a primary loop, wherein the immersed coil/heat exchanger is inside of a thermal storage tank which houses a thermal storage media;
b. An enclosure which houses a thermal storage tank and other components; and
c. A rack-level cooling distribution unit.

FIG. 14A depicts some of the basic components of the compressed air ride-through system to serve liquid-cooled ITE, as well as various options/accessories, along with additional configurations/embodiments for:
a. A primary-only arrangement for movement and cooling of a liquid/refrigerant cooling fluid in a TCS loop with associated valving, including:
   i. A pneumatic motor connected to a pump connected to a primary loop;
   ii. An immersed coil/heat exchanger connected to a primary loop, wherein the immersed coil/heat exchanger is inside of a thermal storage tank;
   iii. A domestic water connection to a thermal storage tank, wherein the domestic water acts as the thermal storage media inside the thermal storage tank;
   iv. A domestic water control valve;
   v. A domestic water float-operated valve;
   vi. A domestic water drain connection; and
   vii. A domestic water backflow preventer/reduced pressure zone assembly;
b. An enclosure which houses a thermal storage tank and other components; and
c. A rack-level cooling distribution unit.

FIG. 14B depicts some of the basic components of the compressed air ride-through system to serve liquid-cooled ITE, as well as various options/accessories, along with additional configurations/embodiments for:
a. A primary-secondary arrangement for movement and cooling of a liquid/refrigerant cooling fluid in a TCS loop with associated valving, including:
   i. A pneumatic motor connected to a pump connected to a primary loop;
   ii. A primary-to-secondary heat exchanger connected to a primary loop and a secondary loop;
   iii. A domestic water connection to a primary-to-secondary heat exchanger, wherein the domestic water acts as a secondary cooling liquid in the primary-to-secondary heat exchanger heat exchanger;
   iv. A domestic water control valve;
   v. A domestic water drain connection; and
   vi. A domestic water backflow preventer/reduced pressure zone assembly;
b. An enclosure which houses a primary-to-secondary heat exchanger and other components; and
c. A rack-level cooling distribution unit.

FIG. 15A depicts some of the basic components of the compressed air ride-through system to serve liquid-cooled ITE, as well as various options/accessories, along with additional configurations/embodiments for:
a. A primary-secondary arrangement for movement and cooling of a liquid/refrigerant cooling fluid in a TCS loop with associated valving, including:
   i. A pneumatic motor connected to a pump connected to a primary loop;
   ii. A primary-to-secondary heat exchanger connected to a primary loop (hot fluid side) and a secondary loop (cold fluid side), wherein the primary-to-secondary heat exchanger is submerged in a thermal storage tank;
   iii. An airlift pump submerged in a thermal storage tank, wherein the airlift pump is connected to an open-type secondary loop and the airlift pump moves a thermal storage liquid from the thermal storage tank, through the cold fluid side of a primary-to-secondary heat exchanger, and back to the thermal storage tank;
b. A baffle inside a thermal storage tank;
c. An automatic air vent on a thermal storage tank;
d. An enclosure which houses a primary-to-secondary heat exchanger and other components; and
e. A rack-level cooling distribution unit.

FIG. 15B depicts some of the basic components of the compressed air ride-through system to serve liquid-cooled ITE, as well as various options/accessories, along with additional configurations/embodiments for:
a. A primary-secondary arrangement for movement and cooling of a liquid/refrigerant cooling fluid in a TCS loop with associated valving, including:
   i. A pneumatic motor connected to a pump connected to a primary loop;
   ii. A primary-to-secondary heat exchanger connected to a primary loop (hot fluid side) and a secondary loop (cold fluid side), wherein the primary-to-secondary heat exchanger is external to a thermal storage tank; and
   iii. An airlift pump submerged in a thermal storage tank, wherein the airlift pump is connected to an open-type secondary loop and the airlift pump moves a thermal storage liquid from the thermal storage tank, through the cold fluid side of a primary-to-secondary heat exchanger, and back to the thermal storage tank;
b. A baffle inside a thermal storage tank;
c. An automatic air vent on a thermal storage tank;
d. An automatic air vent on a secondary loop, upstream of a primary-to-secondary heat exchanger;
e. An enclosure which houses a primary-to-secondary heat exchanger and other components; and
f. A rack-level cooling distribution unit.

FIG. 16 depicts some of the basic components of the compressed air ride-through system to serve liquid-cooled ITE, as well as various options/accessories, along with additional configurations/embodiments for:
a. A primary-secondary arrangement for movement and cooling of a liquid/refrigerant cooling fluid in a TCS loop with associated valving, including:
   i. A pneumatic motor connected to a pump connected to a primary loop;
   ii. A primary-to-secondary heat exchanger connected to a primary loop (hot fluid side) and a secondary loop (cold fluid side), wherein the primary-to-secondary heat exchanger is external to a thermal storage tank; and
   iii. An air-operated diaphragm pump connected to an open-type secondary loop, wherein the air-operated diaphragm pump moves a thermal storage liquid from the thermal storage tank, through the cold fluid side of a primary-to-secondary heat exchanger, and back to the thermal storage tank;
b. A foot valve inside of a thermal storage tank on the suction line of a secondary loop;
c. A baffle inside a thermal storage tank;
d. An enclosure which houses a primary-to-secondary heat exchanger, a thermal storage tank, and other components; and
e. A rack-level cooling distribution unit.

FIG. 17 depicts some of the basic components of the compressed air ride-through system to serve liquid-cooled ITE, as well as various options/accessories, along with additional configurations/embodiments for:
a. A primary-only arrangement for movement and cooling of a liquid/refrigerant cooling fluid in a TCS loop with associated valving, including:
   i. A pneumatic motor connected to a pump connected to a primary loop;
   ii. An immersed coil/heat exchanger connected to a primary loop, wherein the immersed coil/heat exchanger is inside of a thermal storage tank which houses a thermal storage media; and
   iii. A pneumatic motor connected to a mechanical-type agitator inside of a thermal storage tank, wherein the compressed air leaving the compressed air outlet of the pneumatic motor serving the pump is directed through a secondary compressed air conduit to the inlet of the pneumatic motor serving the mechanical-type agitator;
b. An enclosure with insulation which houses a thermal storage tank and other components;
c. A traditional electric-powered heater/heat tracing for heating an enclosure which houses a thermal storage tank and other components;
d. A traditional electric-powered cooler (such as an air-cooled DX cooler) for cooling an enclosure which houses a thermal storage tank and other components;
e. A solar panel to power a heating or cooling device serving an enclosure and/or power other devices in the compressed air ride-through system;
f. A sky-facing radiative-cooling panel for cooling an enclosure which houses a thermal storage tank and other components;
g. A vortex tube for cooling and/or heating an outer shell or insulating jacket around a thermal storage tank, along with associated control valves; and
h. A rack-level cooling distribution unit.

FIG. 18A depicts some of the basic components of the compressed air ride-through system to serve air-cooled ITE and liquid-cooled ITE, as well as various options/accessories, along with additional configurations/embodiments for:
a. A primary-secondary arrangement for movement and cooling of a liquid/refrigerant cooling fluid in a TCS loop with associated valving, including:
   i. A pneumatic motor connected to a pump connected to a primary loop;
   ii. A primary-to-secondary heat exchanger connected to a primary loop (hot fluid side) and a secondary loop (cold fluid side), wherein the primary-to-secondary heat exchanger is external to an underground thermal storage tank; and
   iii. An air-operated diaphragm pump connected to an open-type secondary loop, wherein the air-operated diaphragm pump moves a thermal storage liquid from an underground thermal storage tank, through the cold fluid side of a primary-to-secondary heat exchanger, and back to the underground thermal storage tank;
b. A controller in between an indication of a non-standard operating condition and an automatic releasing valve;
c. An air amplifier arranged to entrain/induce ambient air from the data center and direct the discharge air into a flooded room/cold aisle;
d. A foot valve inside of an underground thermal storage tank on the suction line of a secondary loop;
e. A baffle inside an underground thermal storage tank;
f. An enclosure which houses a compressed air tank, a primary-to-secondary heat exchanger, and other components; and
g. A rack-level cooling distribution unit.

FIG. 18B depicts some of the basic components of the compressed air ride-through system to serve air-cooled ITE and liquid-cooled ITE, as well as various options/accessories, along with additional configurations/embodiments for:
a. A primary-secondary arrangement for movement and cooling of a liquid/refrigerant cooling fluid in a TCS loop with associated valving, including:
   i. A pneumatic motor connected to a pump connected to a primary loop;
   ii. A primary-to-secondary heat exchanger connected to a primary loop (hot fluid side) and a secondary loop (cold fluid side), wherein the primary-to-secondary heat exchanger is external to an underground thermal storage tank;
   iii. An immersed coil/heat exchanger connected to a closed-type secondary loop, wherein the immersed coil/heat exchanger is inside of an underground thermal storage tank which houses a thermal storage media;
   iv. An air-operated diaphragm pump connected to a closed-type secondary loop, wherein the air-operated diaphragm pump moves a secondary cooling liquid through an immersed coil/heat exchanger, through the cold fluid side of a primary-to-secondary heat exchanger, and back to the immersed coil/heat exchanger;
b. An air amplifier arranged to entrain/induce ambient air from the data center and direct the discharge air into a flooded room/cold aisle;
c. An expansion tank connected to a closed-type secondary loop;
d. An enclosure which houses a compressed air tank, a primary-to-secondary heat exchanger, and other components; and
e. A rack-level cooling distribution unit.

FIG. 18C depicts some of the basic components of the compressed air ride-through system to serve air-cooled ITE and liquid-cooled ITE, as well as various options/accessories, along with additional configurations/embodiments for:
a. A primary-secondary arrangement for movement and cooling of a liquid/refrigerant cooling fluid in a TCS loop with associated valving, including:
   i. A pneumatic motor connected to a pump connected to a primary loop;
   ii. A primary-to-secondary heat exchanger connected to a primary loop (hot fluid side) and a secondary loop (cold fluid side);
   iii. A direct-burial coil/pipe connected to a closed-type secondary loop, wherein the direct-burial coil/pipe buried underground;
   iv. An air-operated diaphragm pump connected to a closed-type secondary loop, wherein the air-operated diaphragm pump moves a secondary cooling liquid through a direct-burial coil/pipe, through the cold fluid side of a primary-to-secondary heat exchanger, and back to the direct-burial coil/pipe;
b. An air amplifier arranged to entrain/induce ambient air from the data center and direct the discharge air into a flooded room/cold aisle;
c. An expansion tank connected to a closed-type secondary loop;
d. An enclosure which houses a compressed air tank, a primary-to-secondary heat exchanger, and other components; and
e. A rack-level cooling distribution unit.

FIG. 18D depicts some of the basic components of the compressed air ride-through system to serve air-cooled ITE and liquid-cooled ITE, as well as various options/accessories, along with additional configurations/embodiments for:
a. A primary-secondary arrangement for movement and cooling of a liquid/refrigerant cooling fluid in a TCS loop with associated valving, including:
   i. A pneumatic motor connected to a pump connected to a primary loop;
   ii. A primary-to-secondary heat exchanger connected to a primary loop (hot fluid side) and a secondary loop (cold fluid side), wherein the primary-to-secondary heat exchanger is external to an underground thermal storage tank; and
   iii. An air-operated diaphragm pump connected to an open-type secondary loop, wherein the air-operated diaphragm pump moves a thermal storage liquid from an underground thermal storage tank, through the cold fluid side of a primary-to-secondary heat exchanger, and back to the underground thermal storage tank;
b. An air amplifier arranged to entrain/induce ambient air from the data center and direct the discharge air into a flooded room/cold aisle;
c. A baffle inside an underground thermal storage tank;
d. An air vent on a thermal storage tank;
e. An automatic air vent on a secondary loop, upstream of a primary-to-secondary heat exchanger;
f. An enclosure which houses a compressed air tank, a primary-to-secondary heat exchanger, and other components; and
g. A rack-level cooling distribution unit.

FIG. 19 depicts some of the various configurations/embodiments of a compressed air tank, along with some of the various pneumatically-powered fluid movers and other components which may be connected to the various configurations/embodiments of a compressed air tank via a compressed air conduit. Specifically, the following is depicted:
a. Compressed air tank configurations/embodiments:
   i. A compressed air tank;
   ii. A plurality of cylinder-type compressed air tanks headered together;
   iii. A singular cylinder-type compressed air tank; and
   iv. An air-pressurized piping type of compressed air tank;
b. Pneumatically-powered fluid mover configurations/embodiments:
   i. An air amplifier;
   ii. A pneumatic motor connected to a pump;
   iii. A pneumatic motor connected to a compressor;
   iv. An air amplifier installed on, in, or in the vicinity of a piece of principal cooling equipment, arranged to entrain/induce ambient air from the return air inlet of a piece of principal cooling equipment and direct the discharge air to the supply air outlet of a piece of principal cooling equipment;
   v. An air-operated diaphragm pump;
   vi. A direct connection of the compressed air to a piece of principal cooling equipment in order to pneumatically-override the principal cooling equipment;
   vii. A pneumatic control valve;
   viii. A pneumatic motor connected to a fan;
   ix. An airlift pump;
   x. A reaction-type fan;
   xi. A pneumatically-overridden pump, wherein a pneumatic motor with belts, sheaves/pulleys, and a belt tensioner are arranged to pneumatically-override an electric motor serving a normally-electric-driven pump; and
   xii. A pneumatically-overridden pump, wherein a pneumatic motor and a pneumatic clutch are arranged to pneumatically-override a dual-shafted electric motor serving a normally-electric-driven pump; and
c. A compressed-air-to-cooling-fluid heat exchanger.

FIG. 20 depicts some of the various configurations/embodiments of a pneumatically-powered fluid mover which moves ambient air, along with some of the various components and accessories which may be connected upstream or downstream of the various configurations/embodiments of a pneumatically-powered fluid mover which moves ambient air. Specifically, the following is depicted:
a. Pneumatically-powered fluid mover configurations/embodiments which move ambient air:
   i. An air amplifier;
   ii. A pneumatic motor connected to a fan; and
   iii. A reaction-type fan.
b. Components and accessories which may be connected upstream (i.e. on the entrained/induced air inlet side) of the various pneumatically-powered fluid mover configurations/embodiments which move ambient air:
   i. A hose or duct;
   ii. A mounting plate/bracket;
   iii. A filter;
   iv. A damper/isolating device;
   v. A passive airside thermal storage heat exchanger;
   vi. An isolating/modulating device on a second entrained/induced air inlet, teed into a hose or duct;
   vii. A second entrained/induced air inlet, teed into a hose or duct; and
   viii. An isolating/modulating device on a single entrained/induced air inlet at the end of a hose or duct.
c. Components and accessories which may be connected downstream (i.e. on the discharge air side) of the various pneumatically-powered fluid mover configurations/embodiments which move ambient air:
   i. A hose or duct;
   ii. A mounting plate/bracket;
   iii. A filter;
   iv. A curved or hemispherical filter;
   v. A damper/isolating device;
   vi. A tapered or untapered duct, nozzle, cone, pipe, or fitting;
   vii. A passive airside thermal storage heat exchanger; and
   viii. A passive airside thermal storage heat exchanger in the form of a tapered opening or cone.

FIG. 21 is a graph of the calculated/predicted performance of a specific embodiment of the compressed air ride-through system. The graph shows the calculated/predicted stagnation pressure of the compressed air in the compressed air tank, at the end of each branch pipe/compressed air inlet to the air amplifiers, and at the compressed air outlet of the air amplifiers over the course of an activation of the compressed air ride-through system. Some of the inputs used for these calculations are as follows:
a. Thermodynamic assumptions and effects incorporated into the calculations:
   i. Combination of ideal gas theory with compressibility and real gas effects based on values from the National Institute of Standards and Technology;
   ii. Sonic flow limiting (i.e. compressible flow choking and unchoking);
   iii. Lumped analysis of tank walls and pipe walls for Biot numbers less than 0.1;
   iv. Natural convection coefficient calculated dynamically for tank inner wall surface;
   v. Natural convection coefficient calculated dynamically for tank outer wall surface;
   vi. Forced convection coefficient calculated dynamically for inner wall surface of header pipe, sub-header pipes, and branch pipes;
   vii. Natural convection coefficient calculated dynamically for outer wall surface of header pipe, sub-header pipes, and branch pipes;
   viii. Fourth-order Runge Kutta approximation of generalized compressible flow with friction, heat transfer, area change, and perpendicular mass addition/subtraction calculated along each discretized length of each header pipe, sub-header pipe, and branch pipe;
b. Altitude=0 feet above sea level;
c. Temperature of air around the compressed air tank=95° F.;
d. Temperature of air around the compressed air conduits=80° F.;
e. One compressed air tank with the following parameters:
   i. Cylindrical shape with semi-ellipsoidal end caps;
   ii. Horizontal orientation;
   iii. Diameter=5 feet;
   iv. Location=Outdoors (thus, the initial temperature of the compressed air inside the tank is equal to the outdoor air temperature around the tank, which equals 95° F.);
   v. Length of just the cylindrical section=12.167 feet;
   vi. Length of each end cap=1.417 feet;
   vii. Tank wall thickness=0.1875 inches;
   viii. Approximate tank volume=2,011 gallons;
   ix. Tank wall material=Mild steel with no lining;
   x. Initial gauge pressure of compressed air in compressed air tank=200 PSIG;
   xi. Initial mass of compressed air inside compressed air tank=281.7 pound-mass;
f. Automatic releasing valve on the header pipe opens at time step=0 seconds
g. One main header pipe: Carbon steel, 4 inch nominal, schedule 40, 75 feet long, no additional minor loss resistance;
h. Four sub-header pipes: Carbon steel, 3 inch nominal, schedule 40, 60 feet long each, K-value of 5.0 for minor loss resistance;
i. Thirty-two branch pipes (eight branches per sub-header): HDPE piping, 0.75 inch nominal, 20 feet long each, K-value of 10.0 for minor loss resistance;
j. Adiabatic wall temperature recovery factor=0.6;
k. Thirty-two air amplifiers (one air amplifier per branch pipe) with the following parameters:
   i. Approximate equivalent orifice area=0.000584 square feet;
   ii. Compressed air flowrate entering air amplifier at upstream compressed air pressure of 100 PSIG=180 SCFM or 0.226 pound-mass per second;
   iii. Discharge air flowrate leaving air amplifier at upstream compressed air pressure of 100 PSIG=2,700 SCFM or 3.39 pound-mass per second;
   iv. Entrainment ratio=15 SCFM of discharge air per SCFM of compressed air;
   v. Entrained/induced air flowrate entering air amplifier at upstream compressed air pressure of 100 PSIG=2,520 SCFM or 3.164 pound-mass per second;
   vi. Entrained/induced air inlet location and temperature:
      1. Hot aisle at 95° F. for FIG. 23; and
      2. Cold aisle at 76° F. for FIG. 24;

FIG. 22 is a graph of the calculated/predicted performance of the same specific embodiment of the compressed air ride-through system described above for FIG. 21. The graph shows the calculated/predicted airflows (expressed as SCFM mass flowrates) for the total compressed airflow from the compressed air tank to the air amplifiers and the total discharge airflow from the air amplifiers (which is the compressed air plus the entrained/induced ambient air) over the course of an activation of the compressed air ride-through system. The inputs used for these calculations are the same as described above for FIG. 21.

FIG. 23 is a graph of the calculated/predicted performance of the same specific embodiment of the compressed air ride-through system described above for FIG. 21. The graph shows the calculated/predicted temperature for the stagnation temperature of the compressed air inside the compressed air tank, the bulk temperature of the compressed air tank walls, the stagnation temperature of the compressed air at the compressed air outlet of the air amplifiers, and the stagnation temperature of the discharge air from the air amplifiers (which is a mix of the compressed air plus the entrained/induced ambient air) over the course of an activation of the compressed air ride-through system. The inputs used for these calculations are the same as described above for FIG. 21. For FIG. 23, the source and temperature of the entrained/induced air is a hot aisle at 95° F.

FIG. 24 is a graph of the calculated/predicted performance of the same specific embodiment of the compressed air ride-through system described above for FIG. 21. The graph shows the calculated/predicted temperature for the stagnation temperature of the compressed air inside the compressed air tank, the bulk temperature of the compressed air tank walls, the stagnation temperature of the compressed air at the compressed air outlet of the air amplifiers, and the stagnation temperature of the discharge air from the air amplifiers (which is a mix of the compressed air plus the entrained/induced ambient air) over the course of an activation of the compressed air ride-through system. The inputs used for these calculations are the same as described above for FIG. 21. For FIG. 24, the source and temperature of the entrained/induced air is a cold aisle/flooded room at 76° F.

Corresponding reference characters indicate corresponding components throughout the several views of the drawings. Skilled artisans will appreciate that elements in the figures are illustrated for simplicity and clarity and have not necessarily been drawn to scale. For example, the dimensions and scale of some of the elements in the figures may be exaggerated relative to other elements to help to improve understanding of various embodiments. Also, common but well-understood elements that are useful or necessary in a commercially-feasible embodiment are often not depicted in order to facilitate a less obstructed view of these various embodiments.

On some figures, several components, systems, and configurations/embodiments are shown on the same figure, but may not necessarily all be used in the same embodiment. Similarly, components, systems, and configurations/embodiments from different figures may be used in the same embodiment. The final choice of combination of options and configurations/embodiments for each particular project, deployment, or embodiment will be case-by-case to suit the specific needs of each project and the desires of the parties involved.

### BACKGROUND OF THE INVENTION

The information technology equipment (ITE) within data centers, server rooms, ITE closets, and the like (henceforth referred to as data centers) consumes massive amounts of electrical energy and creates huge amounts of heat. In addition, the associated power equipment (transformers, power distribution units, uninterruptible power supplies, etc.) and associated principal cooling equipment (computer room air conditioners/handlers, chillers, pumps, heat exchangers, fans, cooling towers, condensers, etc.) which support the ITE consume large amounts of energy as well.

The ITE within a data center is typically considered critical, and unexpected shutdowns of the ITE due to overheating or an interruption of power, even if for only a fraction of a second, are almost never tolerable, thus the ITE is typically served by an uninterruptible power supply (UPS).

UPSs provide a means of maintaining steady power to the ITE at all times, even during a utility failure when the normal power from the utility/grid experiences an interruption (such as a black out, brown out, voltage dip, momentary blip, etc.). Typical UPS systems utilize batteries or flywheels to provide a relatively short-term source of electrical energy to maintain this steady power to the ITE for a duration of typically around five to thirty minutes. For an extended outage of the normal power source, a longer-duration backup power source is required, and thus usually generators are typically used in combination with the UPS system and automatic transfer switches (ATSs).

For typical data centers, although the ITE will typically not experience any power interruption due to the presence of UPSs, generators, and ATSs, the principal cooling systems are often only provided with backup power from the generator, not a UPS. In such a configuration, during a utility failure, the principal cooling equipment will experience an interruption of power and temporarily shut down. Following a utility failure, once the generators have started, the ATSs serving the principal cooling equipment will switch to the generator source, and the principal cooling equipment will then restart. In such a configuration without any principal cooling equipment on UPS, even if all the principal cooling equipment were to start immediately, all pumps and fans were to ramp up to full speed immediately, and all principal cooling equipment were to reach full cooling capacity output immediately, the data center would still have undergone a period without cooling (i.e. the period of time it takes for the generators to start and provide backup power).

Therefore, during a utility failure, the ITE will continue running, and will continue to produce a massive amount of heat in the data center, while the principal cooling equipment (if not on UPS) will often experience an interruption of its power source, thus cooling and airflow will be interrupted during this period. With the full ITE heat load being generated with no cooling, no pumps, and no external airflow (external airflow meaning airflow from the principal cooling equipment, separate from the internal ITE fans), this inherently causes the air temperatures (and liquid/refrigerant temperatures for liquid-cooled ITE) in the data center to immediately begin to rise. If the temperature rise exceeds the American Society of Heating, Refrigerating, and Air-Conditioning Engineers (ASHRAE) TC9.9 recommended or allowable limits, the ITE limits, or some other user-defined criteria, this may be considered a failure.

After the principal cooling equipment fans have ramped down (or “free-wheeled” to a stop) following a utility failure, the lack of external airflow exacerbates the temperature rise, since the hot discharge air from the ITE is no longer being aided by external fans, and thus is more likely to recirculate back to the ITE inlets, often recirculating within the cabinet itself or around the cabinet. The internal fans within ITE do not have enough external static pressure to push the air through the return pathway, through the principal cooling equipment filters and coils, and through the supply pathway, especially when there are hundreds or thousands of ITE fans all running in parallel. The leakage in cabinet-level blanking (or the lack of cabinet-level blanking) and leakage/gaps around cabinets allows for a lower-resistance pathway for the hot discharge air to reach the ITE inlets. The presence of rear perforated doors and rear-mounted coils further exacerbates this effect, as they add resistance to the discharge air from the ITE, which will tend to cause more air to internally recirculate within a cabinet than if no doors were present. Furthermore, when a cabinet experiences internal recirculation, the cycle time for each parcel of air is very fast compared to the normal cycle time when the principal cooling equipment is running. The air may pick up the heat from ITE once every few minutes under normal operation as it moves through the ITE, through the return pathway, through the principal cooling equipment, through the supply pathway, and back to the ITE. However, when cabinet recirculation is occurring, the air picks up the same amount of heat every few seconds, since it is only traveling from the discharge of the ITE right back to the inlet of the ITE (whether within the cabinet or immediately around the cabinet). This effect is further complicated by the internal ITE fan control method, which generally speeds up the internal ITE fans at higher inlet temperatures. This higher airflow will reduce the delta-T across the ITE but will move more airflow which may lessen or worsen the ITE inlet temperatures when recirculating, depending on several variables. All of this means that a lack of external airflow during a utility failure will tend to accelerate the temperature rise experienced by the ITE, further shortening the available ride-through time before a failure. This is true regardless of whether or not cooling is available. For example, a chilled water buffer tank will provide an immediately-available source of chilled water/glycol (provided the chilled water pumps are on UPS), but this chilled water/glycol offers no immediate benefit while the CRAH fans are off, since the hot discharge air from the ITE cannot reject its heat to the chilled water/glycol in the CRAH coils unless the CRAH fans are running to push that air through the ITE and back to the CRAH coils (chilled water buffer tanks offer other benefits, such as increasing system volume to increase cycle time, thus reducing the risk of chiller short-cycling and providing a reservoir of chilled water at the supply chilled water setpoint for a period while the chillers ramp back up to full capacity).

Note that in addition to the initial interruption of power to the principal cooling equipment during a utility failure, there will usually be a second interruption of power to the principal cooling equipment much later when transferring back from generator power to normal utility power. This is because the ATSs upstream of principal cooling equipment are usually arranged as “open-delayed,” which intentionally disconnects power from both the generators and the normal power source prior to connecting to the normal power source. This is done to allow a short period for mechanical and motor loads to dissipate their electrical “flux” to minimize the inrush on the normal power source. The ITE inlet temperatures may be at a similar risk during this second interruption, although this re-transfer back to normal power is often conducted under supervision of the operators, keeping the period of power interruption shorter.

A utility power failure is not the only scenario under which the principal cooling equipment can be interrupted; there are many other temporary non-standard operating conditions during which the principal cooling equipment may fail to maintain acceptable temperature levels at the ITE, or may be at an increased risk of doing so.

Depending on a multitude of factors, the ambient air temperatures in the data center may rise far enough and fast enough during a relatively short non-standard operating condition to exceed the “failure” temperature. Note that the “failure” temperature can be defined in several different ways, depending on several factors, and is often site-specific. A non-exhaustive list of some common ways to define a “failure” for air-cooled ITE and liquid-cooled ITE due to elevated temperature is shown below (note that the term cooling fluid used below, as defined in the Glossary, refers to the air, liquid, or refrigerant crossing the boundary of the ITE rack to provide cooling to the ITE):
a. The inlet cooling fluid temperature of one (1) or more pieces of ITE exceeding the ASHRAE allowable temperature limit for the chosen/design allowable envelope, as defined in ASHRAE TC9.9.
b. The rate of cooling fluid temperature rise at the inlet of one (1) or more pieces of ITE exceeding the ASHRAE allowable rate of temperature rise limit for the chosen/design allowable envelope, as defined in ASHRAE TC9.9.
c. The inlet cooling fluid temperature of one (1) or more pieces of ITE exceeding the ITE manufacturer's maximum inlet temperature limit.
d. One (1) or more pieces of ITE experiencing a high-temperature warning.
e. One (1) or more pieces of ITE experiencing a high-temperature shut down.
f. One (1) or more pieces of ITE experiencing any sort of malfunction due to high temperature.
g. One (1) or more pieces of ITE experiencing any sort of warning, shut down, or malfunction due to a high rate of temperature rise at the ITE inlet or within the ITE itself.
h. A breach of the service level agreements (SLAs) in place which often dictate the maximum cold aisle or maximum ITE inlet cooling fluid temperatures that are allowed both during normal operation and during temporary high temperature “excursions,” often with defined maximum durations which the high temperature “excursions” are not allowed to exceed without penalty.

For high-altitude sites, the failure definitions listed above may be appropriately adjusted/de-rated. For example, the ASHRAE allowable temperature limits are reduced at altitudes above a certain level, and thus an interested party may choose to use the calculated de-rated ASHRAE allowable value as the failure point for a high-altitude site or may choose to use the sea-level value.

Following a utility failure, once the generators have started and are providing backup power, the principal cooling equipment then undergoes a restart sequence to re-establish cooling, airflow, and liquid/refrigerant flow in the data center. The restart times and ramp-up speeds of principal cooling equipment vary widely, and different cooling components may restart faster or slower than others. For example, even with a “rapid restart” sequence specifically designed for data centers, air-cooled and water-cooled chillers may initialize their restart sequence shortly after the generators have started, but may take several minutes to re-establish full cooling capacity output. For the fans serving the data center itself, the fan restart time can be as quick as only a few seconds after backup power is received (which is still usually at least ten (10) seconds after the utility failure, given the generator startup time), or in some cases up to one (1) minute after, depending on the “reboot” time, fan ramp-up time, staggered restart delay settings, delays due to controls checks, etc. For pumps and compressors serving liquid-cooled ITE, restarting immediately after the generators have started, may still not be fast enough to prevent overheating of the liquid-cooled ITE. Liquid-cooled ITE generally requires any interruptions to the liquid/refrigerant flow to be less than a few seconds, which is shorter than the time it takes for generators to start up. This means that the presence of liquid-cooled ITE alone may necessitate some means of energy storage to maintain flow while both the utility power and generator power are unavailable (at some facilities, the pumps/compressors serving liquid-cooled ITE are served by UPS power for this purpose).

In some cases, the restart of principal cooling equipment is intentionally delayed/staggered to minimize the inrush/load step when the generators start. The electrical infrastructure and generators would typically need to be more robust and costly to avoid the necessity of staggered restart times of principal cooling equipment, such as more displacement in the generator engine (alternatively, the use of variable speed fans, pumps, and compressors offers the benefit of soft-starting, which helps mitigate the inrush/load step). For example, in a data center with twelve CRAC units, the internal settings on the CRACs may be configured such that CRAC-1 starts one (1) second after regaining power following a power failure, CRAC-2 may be configured to start two (2) seconds after, CRAC-3 may be three (3) seconds after, and so on. Such a configuration will further delay the re-establishment of full cooling capacity and airflow. Note that this is more typical of existing data centers where the principal cooling equipment does not have a means of soft-starting, but this practice is still conducted in some newer data centers as well.

The determination of whether or not a particular data center can inherently ride through a utility failure or other non-standard operating condition without putting any principal cooling equipment on UPS is often determined through a computational fluid dynamics (CFD) analysis, usually of the transient simulation type (as opposed to a steady-state simulation). Other methods may include real-world testing using temporary load banks as a proxy for actual ITE, or simply using published data regarding time-to-failure vs cabinet power density. In many other cases, this analysis simply is not performed, and the interested parties either assume that a) the ITE inlet temperatures will not exceed the ASHRAE or ITE limits during a utility failure or other non-standard operating condition based on experience; b) the ITE will tolerate a short excursion of inlet temperatures above the ASHRAE or ITE limits; or c) in the case of some co-location facilities, write service level agreements (SLAs) which allow for temporary excursions of ITE inlet temps above the ASHRAE or ITE limits.

There are a multitude of factors which influence whether or not a particular data center can successfully ride through a utility failure or other non-standard operating condition. In most data centers, a failure to ride through a non-standard operating condition may be defined as even a single piece of ITE experiencing an elevated inlet temperature above the ASHRAE allowable limit, or above the ITE limit, or a single piece of ITE experiencing a high temperature warning or shutdown. The following is a non-exhaustive list of such factors which may influence a data center's ability to ride through a utility failure or other non-standard operating condition:
a. Size of the room, which influences the thermal mass of the air in the cold aisles or in the case of a flooded room, the thermal mass of the air in the room itself, minus the volume of the hot aisles, hot aisle containment, and ceiling plenum.
b. The air cycle time, which is the time it takes for one (1) parcel of air to nominally make one (1) full trip through airside pathway(s), i.e. leave the ITE, travel through the return pathway, reach the principal cooling equipment, travel through the supply pathway, and reach the ITE again.
c. Volume of piping systems, and cycle time of piping systems, both for traditional cooling piping (chilled water, condenser water, or glycol condenser water) and liquid-cooled “technology” piping.
d. Fan ramp down (“free-wheeling”) and ramp up times.
e. Heat rejection and compressor restart times.
f. Principal cooling equipment controller reboot times.
g. The internal settings on principal cooling equipment.
h. The warning and shutdown temperature limits of the ITE.
i. The maximum temperature rate-of-change limits of the ITE.
j. The ability for the ITE to tolerate short-term excursions of elevated inlet temperatures (i.e. how long does the inlet temperature need to remain above the ITE's maximum inlet temperature limit before it generates a warning or shuts down).
k. The desired or established ASHRAE allowable envelope.
l. The altitude of the site (higher elevations have lower density air, which requires higher airflow rates (i.e. higher volume flowrates) to accomplish the same amount of cooling (i.e. produce the same delta-T) at sea level). The variable-speed internal fans in ITE will also tend to run at higher speeds at high altitude in order to maintain the same internal component temperature setpoints (i.e. maintain the same delta-T effectively). The ASHRAE allowable values also get de-rated above a certain altitude.
m. Start time and paralleling time of generators.
n. Thermal mass, conductivity, emissivity, and local heat transfer coefficients of the appurtenances within the airstream, such as the cabinets/racks, floor slab and ceiling slab, columns, beams, coils, floor grilles, raised floor, walls, containment, cages, etc.
o. Presence and type of containment (hot aisle, cold aisle, roofs, connection to ceiling, partial-height dividers, size of gaps, drop ceilings, underfloor baffles, etc.)
p. Level and quality of airflow management.
q. The presence of plastic sheeting on cages.
r. How close the hottest piece of ITE is to the ASHRAE or ITE temperature limits under normal operation.
s. Whether or not some ITE is already-exceeding the ASHRAE or ITE temperature limits under normal operation.
t. ITE and associated cabinet/rack construction/configuration:
   i. U-slot blanking
   ii. Legs on the cabinet and presence of plinths/skirts.
   iii. Side, bottom, and top blanking around mounting rail.
   iv. Cable penetrations through the top and bottom.
   v. Presence of side panels between adjacent cabinets/racks.
   vi. Presence of front and rear perforated doors.
   vii. Orientation of the ITE inlets and outlets (some ITE has rear or side inlets which normally pull from the hot aisle).
   viii. ITE fan modulation (constant vs variable).
   ix. ITE fan control method and fan control curve (for example, increasing ITE fan speed based on elevated inlet temperatures, which effectively reduces the ACFM/KW)
u. Fail position of dampers and valves.
v. Reliability of the fuel oil system serving the generators (which carries whole host of factors itself).
w. Outdoor air recirculation patterns which may affect the inlet temperatures to the generators, and/or the resistance on the radiators.
x. Principal cooling equipment setpoints, such as supply air temperature setpoints, rack-mounted temperature setpoints, fan control setpoints, differential-temperature setpoints, differential-pressure setpoints, backup setpoints, chilled water supply temperature setpoints, etc.
y. Overall ITE load within the room, and percentage of the full design capacity to which the room is actually loaded.
z. Presence of UPSs or other electrical equipment within the data center which may generate more heat than normal during a utility failure or other non-standard operating condition and may influence airflow patterns.
aa. Layout and configuration of the ITE within the room.
bb. Airflow dynamics within the room, both during steady-state conditions and during a utility failure or other non-standard operating condition.
cc. Principal cooling equipment net sensible cooling curves which dictate, in part, the available capacity of principal cooling equipment at varying return temperatures.
dd. Supervisory control scheme which may or may not be configured to recognize a failure and then take action automatically.
ee. Level of cooling redundancy at the room and heat rejection levels, including the quantity of units running.
ff. Whether or not some or all of the principal cooling equipment controllers/control panels have battery-backup or are served by UPS.
gg. Outdoor conditions at the time of the utility failure or other non-standard operating condition.
hh. The state of the data center, such as whether or not there is work being done temporarily in the data center.

Because of the risk of ITE failure during a utility failure or other non-standard operating condition, data centers have adopted several methodologies to mitigate this risk. The following is a non-exhaustive list of some known strategies in use, along with some commentary on each approach (some of these strategies may be used simultaneously/combined):
a. Maintaining the cold aisles at temperatures colder than necessary (i.e. colder than the ASHRAE A1 recommended limit of 80.6° F. at sea level) for normal 24/7 operation (for example, using a supply air setpoint of 70° F.). This approach is often used not only to provide a larger buffer between the normal setpoint and the temperature at which the ITE would be considered failed for the sake of riding through a non-standard operating condition, but also to address poor airflow management (i.e. if there is ITE which is already experiencing elevated inlet temperatures during normal steady-state operation, then keeping the cold aisle temperatures colder than necessary also helps to reduce local elevated inlet temps caused by recirculation, thus essentially keeping the mixed air temperature below the ASHRAE recommended limit). This approach is inefficient and often limits the number of hours which the principal cooling system can operate on economizer. Case in point, one of the most lucrative methods of saving energy in a data center is often to raise the supply air and/or chilled water setpoints to increase the principal cooling equipment efficiency and increase the number of economizer hours (however, the need for implementing improvements in airflow management and adopting a means of riding through a non-standard operating condition are often prerequisites to doing so). This method also does not provide any airflow or differential pressure across the ITE during a utility failure or other non-standard operating condition.
b. Although not necessarily a strategy, one method used by some existing data centers is to simply do nothing. This approach can be successful (meaning that the data center can inherently ride through a utility failure or other non-standard operating condition without any special strategies) in some cases where the particular combination of factors is so arranged to allow for a successful ride-through. For example, a particular data center may have a relatively low average rack density, a minimum level of containment, a large cold aisle or room volume, relatively low cold aisle temperature setpoints, fast-starting generators, and fast-restarting CRAC/CRAH fans—this combination may inherently result in ITE inlet temperatures which stay below the failure point during a utility failure or other non-standard operating condition. In other words, many existing data centers simply may not need any sort of special system for a successful ride through. However, ITE hardware which resides in a particular data center often gets updated several times throughout the lifespan of a data center and the trends for new ITE tend towards higher density racks, towards adoption and implementation of artificial intelligence (AI) processes (high power density), and towards adoption of liquid-cooled ITE. This means that data centers which may currently be able to ride through a utility failure or other non-standard operating condition successfully, without any special considerations or systems, may lose that ability soon. Such facilities may need to implement some special measures or systems (such as the compressed air ride-through system described herein) to regain the ability to ride through a utility failure or other non-standard operating condition given the adoption/deployment of high-density racks/ITE, ITE running AI processes, and liquid-cooled ITE.
c. In other cases, a particular data center may not be able to ride through a utility failure or other non-standard operating condition without some sort of special system, yet they still adopt the do-nothing approach. This is not uncommon (see below). For the same reasons above (adoption/deployment of high-density racks/ITE, ITE running AI processes, and liquid-cooled ITE), these facilities may also have to implement some special measures or systems (such as the compressed air ride-through system described herein) to gain the ability to ride through a utility failure or other non-standard operating condition. Note that there are several possible reasons why a particular data center may not be able to ride through a utility failure or other non-standard operating condition successfully, yet still adopt a do-nothing approach:
   i. The ITE may not be considered critical in some data centers. In these situations, there may be no significant issue or risk in some ITE failing during a utility failure or other non-standard operating condition. In such cases, there would be no need for special ride-through considerations or systems.
   ii. The ITE may be considered semi-critical, but the ITE may be “mirrored” at another facility (i.e. there may be redundant ITE running the same tasks simultaneously in different places, so a failure at one facility ends up being tolerable).
   iii. The owners, operators, or engineers may assume (rightly or wrongly) that a data center can ride through a utility failure or other non-standard operating condition successfully with no further analysis conducted.
   iv. The owners, operators, or engineers may simply ignore the issue of ride-through, or the issue may end up being effectively ignored. For example, the design engineer may omit the analysis of ride-through capabilities in their scope, and thus may not bring up the issue voluntarily, or may demand more money to conduct an evaluation which the client may not be willing to pay, effectively leaving the issue unresolved.
   v. The analysis to determine whether or not the data center could ride through a utility failure or other non-standard operating condition (such as a transient CFD analysis) may not have been performed.
   vi. The analysis above may have been performed, but it was not accurate or used incorrect assumptions or inputs (such as not adjusting air density for altitude, not including thermal mass effects, not inputting/modeling the dynamic ITE ACFM/kW curves, not inputting/modeling net sensible cooling curves, etc.), or was not granular enough (such as omitting the effects inside a rack/cabinet). This could possibly result in a false conclusion that the data center can successfully ride through a utility failure or other non-standard operating condition. This can also work in the opposite manner too, resulting in a conclusion that a data center cannot ride through a utility failure or other non-standard operating condition without special adjustments/systems, when in reality it can.
d. Powering principal cooling equipment controllers/control panels with UPS power or internal battery-backup or capacitor backup (not powering the principal cooling equipment itself with UPS/batteries/capacitors, but just the governing controllers/control panels). This method helps reduce the time wasted for controllers to restart/reboot during a utility failure or other interruption of power to the principal cooling equipment. For example, if a utility failure occurs and the generators start ten (10) seconds later, a UPS/battery/capacitor-backed CRAH controller (but not the fans) would remain powered during that period and could immediately command the CRAH fans to restart at the ten (10) or eleven (11) second mark (although some controllers still carry significant delays in restarting the governed equipment even when backed by UPS/batteries/capacitors). Without a UPS/battery/capacitor-backed CRAH controller, there will be an additional delay after the ten (10) second mark where the controller itself must reboot/restart and possibly go through self-checks and system checks, and then give the command for the principal cooling equipment to restart, which could be an additional delay of anywhere from a few seconds to one (1) minute, depending on the make, model, firmware, settings, etc. This issue only really afflicts digital controllers, however, there is not much data center principal cooling equipment nowadays without some form of digital controller (but there are some). Although this method does not provide any cooling, airflow, or liquid/refrigerant flow during the utility failure, it at least minimizes the time wasted for controller rebooting/restarting, which may be sufficient by itself for low-density data centers to ride through a utility failure successfully. This method is relatively low-cost, and fairly easy-to-implement, partly because the controllers often operate at 120V, which is often (but not always) the same as the UPS voltage serving the ITE, therefore, transformers or totally separate UPS systems are often not required for this method. However, separate breakers and separate circuits are often required for each device/controller served to maintain redundancy, which can add more wiring costs and panel costs. If using internal batteries or capacitors as backup within the principal cooling equipment or within the control panel, no additional wiring is usually required, but the batteries and capacitors will have to be replaced periodically (in some cases, there may not be an indication that the internal batteries or capacitors have gone bad, been drained, or been otherwise compromised, which could pose a risk). Overall, this method is generally recommended as part of the solution for riding through a utility failure or other non-standard operating condition (however, this method may not be necessary if the compressed air ride-through system described herein is used). However, this method does not provide any airflow or differential pressure across the ITE during a utility failure.
e. Implementing good airflow management practices and containment. The main aim of this strategy is to increase the separation between the supply and return/discharge airstreams to minimize mixing. This method is normally used to allow the cold aisle temperatures to be raised during normal operation for energy efficiency and to minimize internal and external cabinet recirculation. During a utility failure or other non-standard operating condition, having good airflow management, such as U-slot blanking, top/bottom/side blanking around the mounting rails, and hot or cold aisle containment, can help inhibit warm discharge air from the ITE from recirculating back to the ITE inlets. However, without external airflow during a utility failure or other non-standard operating condition, a portion of the discharge air will still likely find its way through the inevitable gaps in the blanking and containment back to the ITE inlets (albeit a smaller amount than if there were poor airflow management and a lack of blanking/containment). But the implementation of good airflow management practices and containment is often followed by an effort to raise the cold aisle temperatures for energy savings (which reduces the difference between the initial/normal cold aisle temperatures and the ASHRAE or ITE limit), so the ride-through benefits of good airflow management and containment may be reduced or even negated by a setpoint-raising effort. Nonetheless, good airflow management and containment are almost always recommended for any data center, as the energy savings benefits and the prevention of elevated ITE inlet temperatures during normal operation should not be sacrificed.
f. Using chilled water buffer tanks. Chilled water buffer tanks will provide an available source of cooling when the chillers are off, but this source of cooling offers no immediate benefit while the CRAH fans are off, since the hot discharge air from the ITE cannot reject its heat to the chilled water in the CRAH coils unless the CRAH fans are running to push that air through the ITE and back to the CRAH coils (chilled water buffer tanks offer other benefits, such as increasing system volume to increase cycle time to reduce the risk of chiller short-cycling, and providing a reservoir of chilled water at the supply chilled water setpoint for a period while the chillers ramp back up to full capacity after the generators have started). Furthermore, in order for the chilled water in the buffer tank to reach the CRAH's to extract the heat during a utility failure, the chilled water pumps would need to be on UPS, which inherently consumes extra energy constantly, 24/7. And even with the chilled water pumps on UPS, the heat from the ITE can only be transferred to the chilled water if the CRAH fans are running, which is only possible if the CRAH fans are on UPS as well (there will be a couple seconds where the CRAH fans will keep spinning during their ramp-down period immediately after losing power). Therefore, using chilled water buffer tanks alone does not provide any cooling or airflow during a utility failure unless both the chilled water pumps and the CRAH fans are both backed by UPS power, which consumes extra energy continuously. Also note that the presence of chilled water buffer tanks also means that some cooling will be lost/wasted through the shell of the tanks when the air temperature around the chilled water buffer tanks is higher than the chilled water supply temperature (although the insulation slows down this heat transfer, it does not fully stop it). A small amount of free-cooling will be achieved in the same manner when the air temperature around the chilled water buffer tanks is below the chilled water supply temperature, but a portion of this may end up being offset by the energy consumption of heat tracing and/or injection cycles.
g. For water-cooled DX principal cooling equipment, condenser water buffer tanks may be used similar to chilled water buffer tanks above, except one level removed (the condenser water rejects heat from the refrigerant loop, and the refrigerant evaporator coil is what removes the heat from the air in the data center). However, the use of condenser water buffer tanks for water-cooled DX principal cooling equipment often is more so for a municipal domestic water shortage/interruption, rather than to ride through a utility failure—in fact, the tank may be arranged only for make-up to cooling towers as opposed to connected directly to the condenser water system.
h. Powering some principal cooling equipment fully with UPS power. Although this is not common currently for data centers with only air-cooled ITE (but will likely become more common), it is a solution used by some data centers where they have determined that they cannot successfully ride through a utility failure or other non-standard operating condition without keeping at least some principal cooling equipment running via UPS batteries or a flywheel/rotary UPS. The principal cooling equipment fans in the CRACs/CRAHs, the chilled water pumps, condenser water pumps, glycol pumps, liquid-cooling loop pumps, etc. are usually what would be put on UPS in such a case (compressors, chillers, cooling tower fans, condensers, etc. are usually omitted), along with controllers, motorized valves, etc. As previously mentioned, the adoption of AI and liquid-cooled ITE means that more and more data centers will have to entertain putting some principal cooling equipment on UPS. Although this is a viable solution, it carries many issues. The compressed air ride-through system is aimed, in large part, at providing a better solution for maintaining ITE within an acceptable temperature range during a utility failure or other non-standard operating condition than attempting to put the principal cooling equipment on UPS. Some of the issues with putting principal cooling equipment on UPS power are noted below (note that many of these items are true regardless of whether a dedicated UPS is used or if the UPS serving the ITE is just enlarged to handle the principal cooling equipment, and many are true for both online and offline UPS configurations as well):
   i. High initial cost.
   ii. High lifetime cost due to maintenance, replacement of components (such as batteries), energy consumption, heat generated, and associated cooling costs.
   iii. Often requires additional principal cooling equipment to neutralize the heat generated by the UPS module or the flywheel UPS and keep the UPS systems within an optimum temperature range. This additional principal cooling equipment also consumes energy.
   iv. For code compliance, many battery systems require exhaust fans, make-up air fans, fire rated walls, fire alarm devices, spill control, eyewash stations, fire protection systems, and gas monitoring systems.
   v. For several battery types, such as vented lead-acid and valve-regulated lead acid batteries, if an issue occurs with the ventilation or exhaust systems (or if the ventilation or exhaust systems were designed incorrectly), there is a risk of hydrogen accumulation in the battery room, which can become flammable/explosive if the hydrogen concentration in the room exceeds the lower flammability limit or lower explosive limit.
   vi. For several battery types, such as lithium-ion batteries, there is a risk of thermal runaway, which can result in the batteries rupturing, catching fire, or even exploding.
   vii. UPS systems are almost exclusively installed indoors or inside enclosures, thus taking up significant space/real estate (often in dedicated rooms).
   viii. UPS systems often consume a constant amount of energy due to the inefficiencies of the UPS modules, inverters, rectifiers, surge suppressors, transformers in some cases, and other electrical components integral to UPS systems.
   ix. Almost-constant energy consumption to keep the batteries charged, keep a flywheel spinning, and/or keep the flywheel magnetically-levitated.
   x. Low lifespan of batteries.
   xi. Reliance on special/exotic chemicals.
   xii. Maintenance costs are typically high.
   xiii. The UPS equipment often becomes less efficient under low-load conditions as well.
   xiv. Complication, both internally and externally, in terms of the electrical infrastructure/components necessary for the UPS system and the principal cooling equipment served by the UPS system to work properly, reliably, and safely.
   xv. Multiple UPS systems may be required to satisfy redundancy requirements.
   xvi. Depending on the job specifics, powering the principal cooling equipment with UPS power may require additional automatic transfer switches (ATSs) or static transfer switches (STSs) upstream of, or built into, the principal cooling equipment (beyond the switches necessary for simply switching between normal and generator power).
i. Writing language into service level agreements (SLAs) which allow for brief periods of high temperature “excursions”. In the case of co-location facilities (“co-lo's”), the facility owner will rent/lease data center space to customers who populate the space with their ITE. The facility owners and customers will usually sign an SLA which describes the temperature and humidity conditions which they will maintain in the cold aisle (or at the ITE inlets). These SLAs often also include language describing high temperature excursions, which are temporary rises in temperature beyond the acceptable normal cold aisle temperature range listed in the SLA. The ASHRAE recommended limits are normally used for normal operation and the ASHRAE allowable limits are sometimes used for the “excursion” language. In some cases, the language may simply state that the cold aisle temperatures are allowed to rise above the ASHRAE allowable limit (often without any adjustment for altitude) for a maximum of a few minutes per month or per year. With such language, there is no maximum temperature defined, and assuming the customer agrees to this language, the temperatures could rise quite high during a utility failure or other non-standard operating condition (possibly above the ITE failure limit, depending on how the customer defines a failure) without any basis for claims/penalties against the facility owner, provided that the temperatures are brought back down to the normal range within the specified time limit. The use of such language tends to benefit the facility owner and may de-incentivize the implementation of a means of limiting the maximum ITE inlet temperatures during a utility failure or other non-standard operating condition. A savvy customer may wish to revise the language to define a maximum ITE inlet temperature (not a cold aisle temperature) during an excursion. Note that defining a maximum cold aisle temperature (as opposed to an ITE inlet temp) during an excursion may not reflect the actual conditions at the ITE inlets, especially if there is recirculation in or around the cabinet (the mitigation of recirculation in or around the cabinet may be partly within the control of the customer, depending on their airflow management standards/practices).

### SUMMARY OF THE INVENTION

The compressed air ride-through system is designed to maintain the ITE (125, 154, 157) in a data center at acceptable temperature levels during a non-standard operating condition, such as a normal utility power failure or other short-term interruption to the principal cooling systems, for thirty minutes or less. The compressed air ride-through system accomplishes this by opening an automatic releasing valve (101, 101A, 101B, 101C) in response to an indication of a non-standard operating condition, which releases compressed air from a compressed air tank (100, 100A, 100B, 145) through a compressed air conduit (109, 122, 124) a pneumatically-powered fluid mover (116, 123A, 150, 152, 162, 162A, 174, 194, 203, 205A, 205B, 211). The pneumatically-powered fluid mover (116, 123A, 150, 152, 162, 162A, 174, 194, 203, 205A, 205B, 211) utilizes the released compressed air to move a cooling fluid. The cooling fluid then absorbs/extracts heat from the ITE (125, 154, 157). In many embodiments, the drop in stagnation temperature of the compressed air (due to the expansion of the compressed air as it is released from the tank) is also utilized to help cool the cooling fluid.

In the case of a normal utility power failure, the principal cooling equipment serving the data center will usually lose power immediately and shut down, while the ITE (125, 157, 154) will continue to run and produce heat since the ITE is backed up with UPS power (i.e. batteries). The principal cooling equipment will usually not reboot/restart and re-establish full cooling capacity until a short period after the onsite backup generators start up. The compressed air ride-through system is intended to bridge the gap in cooling during such an interruption to the principal cooling systems and other non-standard operating conditions.

For airside applications to serve air-cooled ITE, the released compressed air is directed to a airside-type of pneumatically-powered fluid mover, such as an air amplifier (116), a pneumatically-powered fan (152), a reaction-type fan (174), or a pneumatically-overridden principal cooling equipment fan (123A) to provide an immediate source of airflow. These devices amplify or multiply the total mass flowrate of compressed air entering the device by entraining/inducing ambient air, such that the discharge air mass flowrate from these devices is several times larger than the compressed air mass flowrate entering the device. The discharge air mass flowrate from these devices also becomes colder than the entrained/induced ambient air temperature due to mixing with the cold compressed air.

One of the primary advantages of the compressed air ride-through system is that its implementation can avoid or prevent the need for the principal cooling equipment in a data center to be powered by UPS power.

The compressed air tank (100, 100A, 100B, 145) acts as a reservoir for compressed air. Once pressurized with compressed air by a portable or permanent compressor (113), the compressed air ride-through system will sit dormant (or sit in “standby”) until it is needed to activate (i.e. until the automatic releasing valve responds to an indication of a non-standard operating condition).

The compressed air in the compressed air tank (100, 100A, 100B, 145) will be warm initially after it has been pressurized due to the heat of compression. The compressed air inside the tank will then naturally cool down and settle to the air temperature surrounding the compressed air tank (100, 100A, 100B, 145). Once the pressure of the compressed air in the tank has reached its target/design pressure and the temperature of the compressed air in the tank has settled back to its target/design temperature, the compressed air ride-through system will have re-achieved its target/design cooling capacity and thus will be ready for the next activation.

The pressurized compressed air tank (100, 100A, 100B, 145) is a form of energy storage.

In most embodiments, the compressed air ride-through system will be operated at relatively low compressed air pressures in the range of residential-type compressors (approximately 200 PSIG or less) for safety and insurance purposes, so it will be less susceptible to leaks than large-scale compressed-air-storage systems which operate at much higher pressures. This also allows a much wider array of components and pneumatically-powered fluid movers to be used without having to rely on pressure regulating valves, which may inhibit the operation of or introduce risk into the backup system. Despite this, much higher compressed air pressures may be used in some embodiments, such as if a compressed air cylinder is used as the compressed air tank.

Provided that the compressed air tank (100, 100A, 100B, 145) and connected components have been installed in an airtight manner with no leaks, the compressed air ride-through system will use very little energy, if any, while dormant in most embodiments. The energy consumption may include items such as:
a. “As-needed” energy consumption of compressed air ride-through system (i.e. this energy is only consumed once after each activation of the compressed air ride-through system, which will be infrequent):
   i. Re-pressurizing the compressed air tank (100, 100A, 100B, 145).
   ii. If thermal storage components are included in the embodiment, such as a passive airside thermal storage heat exchanger (208, 208A) or a thermal storage tank (189), then depending on the location of these components, some energy may be used by the principal cooling equipment to re-cool the fixed mass of heat exchange material or the thermal storage media/liquid present in these components after an activation of the compressed air ride-through system. This energy use to re-cool the thermal storage components is only required following an activation, and once re-cooled, the thermal storage components will not require any further energy consumption until the next activation of the compressed air ride-through system.
   iii. If included in the embodiment, the energy consumption of a re-warming fan (172).
b. Energy consumption while the compressed air ride-through system is dormant or in standby:
   i. Infrequent opening of automatic drain valve (114) to remove condensate/moisture from the compressed air tank (100, 100A, 100B, 145). If a zero-loss automatic drain is used, then minimal compressed air is lost when removing the condensate/moisture. Once all or the majority of the condensate/moisture has been removed from the tank, the automatic drain valve (114) will likely not need to open again until a system activation occurs and the tank is subsequently re-pressurized.
   ii. Control power for controllers (104), monitoring devices, relays (209), and sensors (111, 112, 177).
   iii. “Holding” power to hold any motorized/solenoid valves in a particular position.
   iv. If the compressed air tank (100, 100A, 100B, 145) is installed outdoors and the project-specific requirements/calculations indicate that cooling or heating of the compressed air tank (100, 100A, 100B, 145) is required/desired (not required in many cases), then there may be some energy consumption to cool and/or heat the compressed air tank (100, 100A, 100B, 145) using various cooling and/or heating devices (178, 185, 187, 188) or using the compressor itself (113).

The compressed air ride-through system is activated by responding to at least one indication of a non-standard operating condition (102). When the compressed air ride-through system is activated, the automatic releasing valve (101, 101A, 101B, 101C) automatically opens. For example, in the case of a normal utility power failure, the loss of normal power can be at least one indication of a non-standard operating condition (102) which activates the compressed air ride-through system and thus opens the automatic releasing valve (101, 101A, 101B, 101C). See the discussion of control sequences herein for more information.

The compressed air ride-through system is only intended to operate for a short period, such as a few seconds to a few minutes (up to thirty minutes in some cases). Although longer runtimes are certainly possible, the compressed air ride-through system's cost-effectiveness and performance may start to diminish with longer runtimes, primarily due to the increased compressed air tank (100, 100A, 100B, 145) quantity or size that would be needed to accommodate longer runtimes, and the more gradual temperature drop of the compressed air associated with a longer runtime. The compressed air ride-through system is most cost effective when it is sized only for the minimum ride-through time required (this duration will be specific to each project).

The compressed air will expand and cool as it is released from the compressed air tank (100, 100A, 100B, 145). Depending on the configuration/embodiment and the components used, the air in the compressed air ride-through system will undergo several different thermodynamic processes at various points in the compressed air ride-through system such as adiabatic, isothermal, isentropic, isenthalpic, polytropic, Joule-Thomson cooling, extraction of pressure-volume work, conversion from potential to kinetic energy, conversion of stagnation properties to static properties, momentum transfer, and choked flow/sonic flow limiting.

The pneumatically-powered fluid movers (116, 123A, 150, 152, 162, 162A, 174, 194, 203, 205A, 205B, 211) utilize the released compressed air to move a cooling fluid which then absorbs/extracts heat from the ITE. The pneumatically-powered fluid movers (116, 123A, 150, 152, 162, 162A, 174, 194, 203, 205A, 205B, 211) make use of the compressed air in several ways (some of which may be combined):
a. As a means of generating high-velocity streams/jets which can entrain/induce ambient air inside the data center (mostly via the Venturi Effect or Coanda Effect); this has the effect of amplifying the total airflow. For every one SCFM of released compressed air, a much higher amount of ambient air (up to 25 times or 50 times in some cases) can be entrained/induced, thus amplifying the total airflow by a large amount.
b. As a source of cold air which then can be mixed with the entrained/induced ambient air for a less-severe temperature drop and a higher airflow.
c. As an energy source to drive pneumatic motors (150), which then drive other devices, such as fans (152), pumps (162), or compressors (211), which then move a cooling fluid.
d. As an energy source to drive pneumatic fans, pumps, and compressors, such as reaction-type fans (174), air-operated diaphragm pumps (162A), airlift pumps (194), or pneumatically-powered compressors (211) which then move a cooling fluid.
e. As an energy source to pneumatically-override principal cooling equipment fans, pumps, and compressors (123A, 150, 203, 203A, 203B, 204, 205, 205A).
f. As a means of generating a pressure differential.
g. As a heat exchanger fluid.
h. As a direct means of airflow and cooling.

The pneumatically-powered fluid mover(s) (116, 123A, 150, 152, 162, 162A, 174, 194, 203, 205A, 205B, 211) may consist of any of the following or other similar devices:
a. Air amplifiers (116), such as Coanda-type air amplifiers, venturi blowers, air-operated in-line conveyors, air knives, air ejectors, entraining air nozzles, or similar. These devices use the compressed air to entrain or induce ambient air (120) to increase the total airflow (and generate a pressure differential in some cases) and mix the compressed air with entrained/induced ambient air (120) to deliver a mixed discharge airstream (121) with a mixed air temperature which is cooler than the entrained/induced air (120). For several air amplifiers (116), the volume of ambient air which can be entrained/induced is several times larger than the compressed air volume itself. For example, a common air amplifier device may be able to entrain/induce twenty-five standard cubic ft per min (SCFM) of ambient air (120) for every one SCFM of compressed air “consumed”/delivered through the device.
b. Pneumatic motors (150), which convert the energy in the compressed air to rotational energy to drive other devices, such as fans (152), pumps (162), or compressors (211).
c. Reaction-type fans (174) (or sometimes called vaneaxial jet fans), which direct the compressed air to the trailing edge of the fan blades themselves, which provides thrust to spin the fan blades directly. The compressed air released from the blades also mixes with the air entrained/induced (148) into the fan.
d. Pneumatically-overridden principal cooling equipment fans, pumps, or compressors (123A, 150, 203, 203A, 203B, 204, 205, 205A).

For air-cooled ITE (125, 157), the use and arrangement of the air amplifiers (116), pneumatically-powered fans (152), reaction-type fans (174), or pneumatically-overridden principal cooling equipment fans (123A) will help to create a differential pressure (DP) across the ITE (125, 157). Creating a DP across the ITE (125, 157) is important in preventing recirculation in or around the ITE cabinets (i.e. if there is insufficient pressure difference across the cabinet an IT cabinet, it can recirculate warm discharge air within itself or immediately around itself back to the ITE inlets, resulting in a breach of the temperature limits—this effect can occur even if the cold aisle temperature is within its normal temperature range). In many cases, this pressure differential may be as important as, or in some cases more important than, a cool cold aisle temperature in terms of maintaining the ITE at acceptable temperature levels.

After the compressed air tank (100, 100A, 100B, 145) has completed a release of the compressed air (most likely a few seconds to a few minutes after the initial activation of the compressed air ride-through system), the principal cooling systems (123) will have assumedly restarted and re-established cooling, and the cooling burden is shifted back to the principal cooling equipment (123). At this point, the compressed air ride-through system will be reset manually or automatically, and the compressed air tank (100, 100A, 100B, 145) will be recharged/re-pressurized manually or automatically. The compressed air ride-through system will then sit dormant (or sit in “standby”) until it is required to activate again (i.e. until the next utility failure or other non-standard operating condition).

The compressed air ride-through system is not intended to act as or replace the principal cooling equipment in a data center. It is only intended for (and is only viable for) short-term operation during a relatively short window, such as a utility failure or other non-standard operating condition.

The compressed air ride-through system may be configured with only the basic components and features or may be configured in a multitude of different ways. The descriptions herein and the associated drawings attempt to describe and depict the most likely and most useful configurations, embodiments, features, accessories, and options, many of which may be combined within the same system. Several components and systems are shown on the same diagram, but may not necessarily all be used in the same embodiment. Likewise, components and systems from different drawings may be used within the same embodiment. The final choice of combination of options for each particular project or installation will be case-by-case to suit the specific needs of each project and the desires of the parties involved.

### Some Benefits and Advantages of Many Embodiments of the Invention

In comparison to the other strategies used by data centers to ride through a normal utility power failure or other non-standard operating condition (described herein), the compressed air ride-through system is intended to be a lower initial cost, lower lifetime cost, lower energy use, more reliable, simpler, longer-lasting, more scalable, more independent, more flexible, and lower maintenance alternative, without reliance on special/exotic chemicals, and without reliance on consumable components (other than minor air filters).

One of the primary advantages of the compressed air ride-through system is that its implementation avoids or prevents the need for principal cooling equipment to be powered by UPS power.

The compressed air ride-through system requires minimal or no modifications to other established systems typically installed in data centers. For example, the compressed air ride-through system does not require special ITE, special ITE racks, special power system arrangements, nor special arrangements of the principal cooling systems in most embodiments.

By resigning/dedicating the intent of the compressed air ride-through system to only short-term movement of a cooling fluid for ride-through applications, the compressed air ride-through system size is reduced down to only what is required to achieve the minimum ride-through time (this duration will be specific to each project). This makes the compressed air ride-through system highly cost-effective.

By using compressed air as the means of energy storage, provided that the compressed air tank (100, 100A, 100B, 145) and assuming the connected components have been installed in an airtight manner with no leaks, the compressed air ride-through system will use very little energy, if any, while dormant. See previous discussion for the minor energy consumption items (controls power, drain power, tank heating and cooling, if necessary, etc.).

The compressed air ride-through system only uses a small amount of energy to recharge/re-pressurize the tank (and the recharging/repressurizing only occurs as needed following an activation of the compressed air ride-through system, such as for a utility failure or other non-standard operating condition, which are infrequent events). Only the portable or permanent compressor is needed to run to pressurize the tank, and then no other power (except the minor items described previously) is required until the next activation of the compressed air ride-through system. Although compressor power, output, efficiency, and configurations vary widely, a rough order of magnitude example is given for demonstration purposes only:
a. Suppose that the site-specific calculations (depending on many factors) indicate that a one (1) MW data hall requires a compressed air ride-through system which includes a 2,000 gallon compressed air tank pressurized to 200 PSIG to maintain the ITE within an acceptable temperature range for a ride-through time of 60 seconds. The thermodynamic energy to recharge a 2,000 gal air tank from 0 PSIG to 200 PSIG would range from 4 kilowatt-hours (kWh) to 9 kWh, depending on whether the compression process is closer to adiabatic or isothermal. For an actual compressor, the energy input to perform this compression may be around 26 kWh (depending on many factors). Assuming an average utility energy cost of $0.15/kWh, this means that the cost to recharge the compressed air tank in this example would be $3.90. If only one utility failure or other non-standard operating condition occurred in a given year, the total annual energy cost of the compressed air ride-through system in this example would still be only $3.90 (plus the minor energy consumption described previously). For comparison, this is less energy than the annual energy consumption of a single coffee maker used daily. For another comparison, a 60 watt light bulb would consume 525.6 kWhr of energy if left on for a full year and would have an annual energy cost of $78.84. Therefore, the compressed air ride-through system in this example would use about 5% (or one twentieth) of the energy used by a 60 watt light bulb running for a year. The compressed air ride-through system would not use any further energy (except the minor energy consumption described previously) until the next activation of the compressed air ride-through system, such as during the next utility failure or other non-standard operating condition. This is far less energy consumption than the alternative of putting principal cooling equipment on UPS power.

The pressure in the compressed air tank (100, 100A, 100B, 145) for the compressed air ride-through system would be relatively low in most embodiments, such as 200 PSIG or less, which is in the range of residential air compressor systems. Keeping the compressed air tank pressure below 200 PSIG makes the compressed air ride-through system inherently safer than high-pressure systems and may assuage concerns from local authorities having jurisdiction about implementation. It also allows inexpensive residential-type portable compressors to be used, if desired. The use of a relatively low compressed air pressure also means that leaks are less likely (and less air is lost if minor leaks do develop). Despite this, much higher compressed air pressures could be used in some embodiments, such as if a compressed air cylinder was used as the compressed air tank.

Can actually save energy in many data centers. This is because with the compressed air ride-through system installed, the data center operators may no longer need to keep the cold aisle temperature setpoints artificially low for the sake of riding through a utility failure or other non-standard operating condition, since the compressed air ride-through system would provide the movement of the cooling fluid(s) and/or cooling necessary during a utility failure or other non-standard operating condition, thus alleviating the need for the principal cooling equipment to constantly maintain low temperatures setpoints 24/7 in anticipation of a utility failure or other non-standard operating condition. The cold aisle temperature setpoints and/or liquid/refrigerant temperature setpoints could be raised (provided good airflow management practices are in place), thus increasing principal cooling equipment efficiency and increasing the number of economizer hours. In this manner, the compressed air ride-through system may actually pay for itself in energy savings in a relatively short period. Furthermore, these energy savings would not have to be offset by the additional electrical energy consumption or heat generation and parasitic cooling that would accompany comparable UPS systems serving principal cooling equipment.

In most embodiments, no special chemicals are used, such as those used in the manufacturing of batteries.

Long life span for entire compressed air ride-through system as well as for the individual components.

The compressed air ride-through system will most likely operate at a lower cost than UPS alternatives, both in initial costs and lifetime costs.

Unlike UPS systems, the compressed air ride-through system requires minimal, or no, parasitic cooling in most embodiments. If the compressed air tank (100, 100A, 100B, 145) is installed indoors in a conditioned space, cooling would potentially only be required during the recharge/re-pressurization period and a relatively short period thereafter, and then no cooling thereafter until the next activation of the compressed air ride-through system (and the cooling for an indoor compressed air tank (100, 100A, 100B, 145) may be accomplished with exhaust fans alone).

With the compressed air ride-through system installed, there is no need for automatic transfer switches (ATSs) or static transfer switches (STSs) upstream of or built into the principal cooling equipment to switch to a UPS or battery source (ATSs and STSs may still be utilized by the principal cooling equipment for switching between normal and emergency/standby power, but no additional ATS or STSs would be required for switching to a UPS or battery source).

With the compressed air ride-through system installed, the need for a UPS or battery source upstream of the principal cooling equipment is avoided, and thus the electrical and heat losses associated with an upstream UPS or battery source are also avoided. This includes the electrical or heat losses associated with on-line UPSs, offline UPSs, battery charging, transformers, spinning a flywheel, rectifiers, inverters, surge suppressors, etc. This also means that the cooling energy required from the principal cooling equipment associated the heat generation of these losses is also avoided as well. Furthermore, the potential initial cost of purchasing and installing additional principal cooling equipment to cool the additional heat load associated with these losses is also avoided.

In many embodiments, for both air-cooled ITE and liquid-cooled ITE, the compressed air ride-through system provides immediate and simultaneous movement of ambient air, cooling of the ambient air, movement of a cooling liquid/refrigerant, and cooling of the cooling liquid/refrigerant, all within the same system. In comparison, a chilled water buffer tank would require the associated chilled water pumps to be on UPS power and the CRAC/CRAH fans to be on UPS power to accomplish the same thing.

Provides a source of rotational energy if pneumatic motors are implemented. These can then power pumps, fans, or compressors during a utility failure or other non-standard operating condition.

The compressed air ride-through system is simple and reliable. In many embodiments, no special programming nor digital controls are needed at all (although some embodiments may include some controls, monitoring, programming, and settings if desired by the user/client).

Provides a source of immediate cooling fluid movement and/or cooling within the same system.

The compressed air ride-through system can serve for both air-cooled ITE and liquid-cooled ITE with the same system.

The compressed air ride-through system is scalable since additional compressed air tanks (100, 100A, 100B, 145) and pneumatically-powered fluid movers (116, 123A, 150, 152, 162, 162A, 174, 194, 203, 205A, 205B, 211) can be added as needed. They can be headered together with the original system or left separate if desired.

In most embodiments, there are no “consumables” in the compressed air ride-through system, except optional filters (143, 143A), optional desiccants (132), and optional break-through seals (118, 119, 159). Most, if not all, other components in the system are permanent and should last the life of the compressed air ride-through system and last the life of the data center (134).

For most embodiments, no special or new manufacturing processes are required. Except for some optional accessories in some embodiments, all individual components of the system are readily-available parts and products which currently exist on the market.

Compressed air systems are a well-established technology with a long history and several standards exist for such systems.

Except for the indication of a non-standard operating condition, in many embodiments, the compressed air ride-through system operates independently of other systems (such as BMS systems and UPS systems) and/or does not rely on other systems to operate properly. By not interfacing (or minimizing the interface) with and/or not relying (or minimizing the reliance) on other systems, the compressed air ride-through system's reliability is not dependent on other systems.

Minimal maintenance is required, such as periodic visual inspections, periodic valve stroking, periodic compressed air tank wall inspections, and periodic short-duration activations of the compressed air ride-through system. For periodic checks, the automatic releasing valve (101, 101A, 101B, 101C) can be tested with an upstream valve closed so that no air is lost (or the compressed air ride-through system can be fully tested with all manual valves open, and limited to a discharge of only few seconds to verify the operation and limit the energy needed for re-charging).

The compressed air ride-through system has flexibility in its installation location; many components can be placed indoors, outdoors, in a plenum, above a ceiling, in a CRAH gallery, in the actual data center, or underground.

### DETAILED DESCRIPTION OF THE INVENTION

The compressed air ride-through system comprises at least one compressed air tank (100, 100A, 100B, 145) to act as a reservoir for receiving, holding, and releasing compressed air. The compressed air tank(s) (100, 100A, 100B, 145) may be installed in several different locations, such as a roof, outdoors at grade, indoors, buried underground, in the data center or adjacent spaces, etc. The compressed air tank (100, 100A, 100B, 145) may be constructed of steel, aluminum, carbon fiber, fiber-reinforced polymer, or other similar material. For safety reasons, the compressed air tank (100, 100A, 100B, 145) may be rated/certified in accordance with ASME BPV section VIII or the Steel Tank Institute or other certifying/underwriting agency. The tank could be constructed in several different shapes, such as cylindrical, with flat or rounded/dished ends, rectangular, spherical, etc. The compressed air tank (100, 100A, 100B, 145) would be pressurized with compressed air. The target pressure chosen would be influenced by several factors, such as the load being served, the duration of the ride-through time required, local codes, industry best practices, safety, limitations and characteristics of the connected equipment, cost, the outdoor conditions and weather extremes, etc.

The compressed air tank (100, 100A, 100B, 145) can be constructed/configured in different ways, such as a tank (100), a self-contained assembly (100A), or multiple compressed air tanks (100, 100A, 100B, 145) can be headered together (100B), or constructed out of single or double wall air-pressurized piping (145). If multiple compressed air tanks (100, 100A, 100B, 145), they may be configured with dissimilar sizes or dissimilar pressures, which may help to optimize or maximize the cooling capacity of the released compressed air.

The compressed air tank (100, 100A, 100B, 145) could be mounted on, inside of, adjacent to, or in the vicinity of principal cooling equipment (123) in various arrangements or mounted in other spaces within or outside of the facility (100A).

The compressed air tank (100, 100A, 100B, 145) would incorporate a filling port (110) for compressed air to be delivered to the compressed air tank (100, 100A, 100B, 145). The compressed air would be delivered to the filling port from a portable or permanent compressor (113) through a compressed air conduit (109). The filling port may be fitted with an optional check valve (164). The compressor could be fitted with optional air dryers, dehumidifiers, intercooler(s), aftercoolers, or other typical compressor accessories. The compressor may or may not be integral to the compressed air tank (100, 100A, 100B, 145). The compressor would not be required to be permanent in all cases; a portable compressor could be used if there was no desire for the compressed air ride-through system to automatically recharge/re-pressurize (in such a case, a generator-backed convenience outlet/receptacle in the vicinity of the compressed air tank (100, 100A, 100B, 145) would be recommended so that the compressed air tank (100, 100A, 100B, 145) could be recharged/re-pressurized with a portable compressor during an extended loss of normal utility power).

The compressed air tank (100, 100A, 100B, 145) may be fitted with an optional coating/lining (147) on the inner surface of the compressed air tank (100, 100A, 100B, 145), such as epoxy or polyurea (or similar). This coating would serve many purposes:
a. Reducing the corrosion to the inner surface of the compressed air tank (100, 100A, 100B, 145).
b. Inhibiting heat transfer from the compressed air tank (100, 100A, 100B, 145) walls to the air during expansion for better cooling performance of the compressed air ride-through system, by the nature of the coating having a significantly lower thermal conductivity than the compressed air tank (100, 100A, 100B, 145) material itself.
c. By inhibiting heat transfer, it also keeps the compressed air tank (100, 100A, 100B, 145) walls closer to the air temperature around the compressed air tank (100, 100A, 100B, 145) and prevents the compressed air tank (100, 100A, 100B, 145) from undergoing severe temperature changes. This would reduce thermal expansion/contraction, and reduce the risk of embrittlement or fatigue failure.
d. In the case of polyurea or other similar coatings, the coating may significantly reduce the damage/danger posed if a compressed air tank (100, 100A, 100B, 145) rupture were to occur.
e. The coating minimizes or eliminates the formation of rust particles and thus minimizes or eliminates the chance of rust particles entering the discharge airstream, the downstream devices, the data center, and the ITE.

To reduce installation costs and/or rigging costs, the volume needed in the compressed air tanks (100, 100A, 100B, 145) may be split up into smaller compressed air tanks (100, 100A, 100B, 145) of a size which may fit inside a passenger or freight elevator.

The compressed air tank (100, 100A, 100B, 145) and the other components of the compressed air ride-through system would be designed and constructed in accordance with applicable local, state, and national codes, which may include but is not limited to ASME BPV section VIII, Steel Tank Institute standards, 2021 International Fire Code Chapter 53, OSHA 29CFR1910, ASHRAE TC9.9, and the Compressed Air & Gas Institute standards.

The compressed air tank (100, 100A, 100B, 145) may be fitted with optional external insulation (147A).

The compressed air tank (100, 100A, 100B, 145) would be fitted with a relief valve (107) to prevent over-pressurization.

The compressed air tank (100, 100A, 100B, 145) could be fitted with several other devices, such as, but not limited to:
a. An optional pressure sensor (111) used for monitoring or control functions.
b. An optional temperature sensor (112) used for monitoring or control functions.
c. An optional humidity sensor (177) used for monitoring or control functions.
d. An optional pressure gauge (130) for manually reading the pressure in compressed air tank (100, 100A, 100B, 145).
e. An optional drain line (115) with optional manual valves (105) for removing condensate and moisture build up within the compressed air tank (100, 100A, 100B, 145).
f. An optional automatic or mechanical condensate/moisture drain/trap (114) for automatic removal of condensate and moisture build up within the compressed air tank (100, 100A, 100B, 145).
g. An optional moisture/water sensor.
h. An optional access port or manhole.
i. An optional ladder or platform.
j. Optional support members.
k. An optional capped future port.
l. An optional means of electrical grounding (133).
m. An optional means of mitigating/slowing corrosion, such as sacrificial anodes, an internal lining (147), a cathodic protection system, or combination thereof.
n. An optional cooling or heating device/system (178, 185, 187, 188) if deemed necessary.
o. An optional enclosure (168).

The opening of an automatic releasing valve (101, 101A, 101B, 101C) would release the compressed air from the compressed air tank (100, 100A, 100B, 145) to the pneumatically-powered fluid mover(s) (116, 123A, 150, 152, 162, 162A, 174, 194, 203, 205A, 205B, 211). To incorporate redundancy and protect against valve seizing, two (2) or more automatic releasing valves (101, 101A, 101B, 101C) can optionally be arranged in parallel, possibly from different manufacturers to minimize the risk of a common cause of failure. The automatic releasing valve (101, 101A, 101B, 101C) would be a powered-closed, fail-open (i.e. spring-opened or capacitor-opened) motorized valve, a slow-opening powered-closed, fail-open (i.e. spring-opened or capacitor-opened) solenoid valve, a pneumatically operated valve (101C), a pilot valve (206) controlling a pneumatically operated valve (101C), a deluge-type valve, a cylinder valve, or similar.

In all cases, at least one automatic releasing valve (101, 101A, 101B, 101C) opens in response to at least one indication of a non-standard operating condition (102). At least one control or power wire (103) is used to indicate or communicate the non-standard operating condition (102) to the automatic releasing valve (101, 101A, 101B, 101C) or to a pilot valve (206) which controls the automatic releasing valve (101, 101A, 101B, 101C). The control or power wire (103) may be a continuous wire or continuous group of wires, or it may be a control or power wire (103) used in a transmitter and receiver of a wireless communication package. In order to achieve the automatic opening functionality of the automatic releasing valve (101, 101A, 101B, 101C) in response to at least one indication of a non-standard operating condition (102), there are several possible arrangements, including, but not limited to:
a. Powering the powered-closed, fail-open automatic releasing valve (101, 101A, 101B) directly from a normal power source (i.e. a utility power source), wherein the loss of normal power acts as the indication of a non-standard operating condition (102).
b. Wiring the indication of a non-standard operating condition (102) directly to the automatic releasing valve (101, 101A, 101B, 101C) or to a pilot valve (206) which controls the automatic releasing valve (101, 101A, 101B, 101C).
c. Wiring the indication of a non-standard operating condition (102) to a relay (209) and then wiring the relay (209) to the automatic releasing valve (101, 101A, 101B, 101C) or to a pilot valve (206) which controls the automatic releasing valve (101, 101A, 101B, 101C).
d. Wiring the indication of a non-standard operating condition (102) to a controller (104) and then wiring the controller (104) to the automatic releasing valve (101, 101A, 101B, 101C) or to a pilot valve (206) which controls the automatic releasing valve (101, 101A, 101B, 101C).
e. Wiring the indication of a non-standard operating condition (102) to a normally open or normally closed circuit and then wiring a normally open or normally closed circuit to the automatic releasing valve (101, 101A, 101B, 101C) or to a pilot valve (206) which controls the automatic releasing valve (101, 101A, 101B, 101C).

Each facility/user may have a different set of non-standard operating conditions for which they want the compressed air ride-through system to activate. In most cases, a loss of normal utility power will be the main (but not necessarily sole) non-standard operating condition for which the facility/operators would want the compressed air ride-through system to activate in response to. However, there are many non-standard operating conditions for which the compressed air ride-through system will be of benefit, and the compressed air ride-through system can be configured to activate in response to one or a plurality of indications of non-standard operating conditions. Consequently, there are many indications that a non-standard operating condition has occurred. As noted in the Glossary, examples of indications of non-standard operating conditions include, but are not limited to:
a. a loss of normal utility power,
b. a loss of at least one source of normal utility power,
c. a principal cooling equipment alarm/signal,
d. generator/emergency/standby power system alarm/signal,
e. a transfer switch alarm/signal,
f. a cooling fluid alarm/signal,
g. a cold aisle alarm/signal,
h. a differential pressure alarm/signal,
i. a leak alarm/signal,
j. a temperature sensor alarm/signal,
k. an ITE alarm/signal,
l. an ITE failure alarm/signal,
m. an ITE high temperature alarm/signal,
n. a user-configurable alarm/signal,
o. a building management system alarm/signal,
p. a power management system alarm/signal,
q. a state change of an electrical switch,
r. a state change of a relay,
s. an opening of a circuit,
t. a closing of a circuit,
u. an opening of a relay,
v. a closing of a relay,
w. a manual activation signal, and
x. a maintenance event alarm/signal.

In all the cases above, the compressed air ride-through system activates (i.e. at least one automatic releasing valve (101, 101A, 101B, 101C) automatically opens) in response to at least one indication of a non-standard operating condition (102) which is communicated via power/control wiring (103) to the automatic releasing valve(s) (101, 101A, 101B, 101C) or to a pilot valve (206) which controls the automatic releasing valve (101, 101A, 101B, 101C). A controller (104), a relay (209), or a circuit may be implemented into the communication between the indication of a non-standard operating condition (102) and the automatic releasing valve(s) (101, 101A, 101B, 101C) or the pilot valve (206) which controls the automatic releasing valve (101, 101A, 101B, 101C) as well.

The sequence of operation governing the opening and closing of the automatic releasing valves (101, 101A, 101B, 101C) could be built directly into the automatic releasing valve (101, 101A, 101B, 101C) itself, or could be configured/programmed in an optional controller (104) and/or an optional relay (209). The optional controller (104) could also monitor the compressed air ride-through system and deliver monitoring points, warnings, alarms, and faults back to a central monitoring system, such as building management system. For most applications of the compressed air ride-through system, the following is a non-exhaustive list of some possible high-level control sequences, considerations, and control arrangements (note that the sequence/control arrangement may be custom for each project, depending on the specific needs of each project):
a. Use a powered-closed, fail-open (i.e. spring-opened or capacitor-opened) motorized or solenoid valve (must be slow-opening if a solenoid valve) with a latching/holding feature which holds the valve open until it is automatically or manually reset, such that once the valve opens, it remains open until it is reset (the latching/holding feature prevents the valve from re-closing prematurely if there is only a short interruption to the power source). The valve would then be powered with normal and emergency power with no UPS backup. Then use a combination of electrical components (such as alternating-type switches or relays) or control logic and a timing mechanism, such that each time there is an interruption to the power (whether an interruption to the normal power or the emergency power), the valve opens to fully release the compressed air. One method of holding open the powered-closed, fail-open (i.e. spring-opened or capacitor-opened) motorized or solenoid valve is to utilize a time delay relay (209) configured for an ON delay, such that the valve opens immediately upon loss of power, but it does not re-close until the time delay has been reached (assuming normal or emergency power is available again at the end of the time delay). This arrangement would allow the compressed air ride-through system to activate both during a normal utility failure AND during the re-transfer from generator power back to normal power (assuming the ATS upstream of the principal cooling equipment is arranged as an open-type or open-delayed type where power is interrupted momentarily). By bringing normal and emergency power to the compressed air ride-through system, the compressed air ride-through system is able to recharge/re-pressurize while the generators are operating, following a utility failure (if only normal power was used, then the compressor would not be able to recharge/re-pressurize the compressed air tank while only on generator power, nor would the valve be able to automatically reset). If the site is configured such that a simple interruption of the normal or emergency power is not a direct indication/analog of an interruption to the power source to the principal cooling equipment (such as if multiple ATSs are used and more than just the non-redundant quantity of principal cooling equipment is powered downstream, and the ATS itself malfunctioned; this would interrupt power to a quantity of principal cooling equipment larger than the tolerable redundant amount, and it would not necessarily be indicated by a loss of normal utility power, depending on where the normal power was being sensed/or derived from), then the compressed air ride-through system can be configured to take a multitude of inputs and utilize logic to activate based on those inputs.
b. Utilize a pilot valve (206) to control or actuate a pneumatic valve (101C). In this configuration, at least one indication of a non-standard operating condition (102) would be connected to the pilot valve (206) by power/control wiring (103), and upon receipt of the indication of a non-standard operating condition (102), the pilot valve (206) would open, allowing compressed air from the compressed air tank (100, 100A, 100B, 145) to reach the pneumatic valve (101C), thus opening the pneumatic valve (101C). The pneumatic valve (101C) could be configured to then re-close once the pressure inside the compressed air tank (100, 100A, 100B, 145) had dropped to near-atmospheric pressure and/or once the pilot valve (206) re-closes.
c. Incorporate a manual release mechanism (i.e. a button, breakglass, handwheel, lever, etc.) which allows the compressed air ride-through system to be manually activated. If the automatic releasing valve (101, 101A, 101B, 101C) is fitted with a manual override, this may serve this purpose.
d. Incorporate a manual “abort” mechanism (i.e. a button, breakglass, handwheel, lever, etc.) which allows the compressed air ride-through system to be manually deactivated (i.e. closes the automatic releasing valve(s)). If the automatic releasing valve (101, 101A, 101B, 101C) is fitted with a manual override, this may serve this purpose.
e. Use a combination of methods, possibly with different methods for different automatic releasing valves (101, 101A, 101B, 101C) to minimize the risk of a common mode of failure/single point of failure.
f. There may be facilities where they are not concerned with or interested in a second activation of the compressed air ride-through system during the re-transfer back to normal utility power (the re-transfer back to normal utility power is often conducted under close supervision, one ATS at a time, and so the principal cooling equipment may be sequentially transferred from generator power back to normal power in small enough increments as to not warrant any sort of ride-through cooling during that specific event). In such cases, a simpler controls configuration may be utilized. The following is a high-level example of such a sequence:
   i. Use a powered-closed, fail-open (i.e. spring-opened or capacitor-opened) motorized, solenoid valve (must be slow-opening if a solenoid valve), pneumatically operated valve, pilot-operated valve, deluge valve, cylinder valve, or similar with a latching/holding feature, such as a time delay relay (209), which holds the valve open until it is automatically or manually reset, such that once the valve opens, it remains open until it is reset (the latching/holding feature prevents the valve from re-closing prematurely if there is only a short interruption to the power source). And power it with normal power only with no generator nor UPS backup. This arrangement would allow the compressed air ride-through system to activate during a normal utility failure only. The compressed air tank (100, 100A, 100B, 145) may or may not be able to be re-charged/re-pressurized by the compressor (113), depending on how the compressor is powered (the compressor is not necessarily powered by the same source as the automatic releasing valve) and the reset mechanism on the automatic releasing valve (101, 101A, 101B, 101C).
g. Use the building management system (BMS) to command the valve open and closed, based on a set of criteria. Although this would be possible and may even be desired/requested by some clients, this approach is not recommended. Utilizing a BMS for critical applications or critical functions such as opening an automatic releasing valve (101, 101A, 101B, 101C) introduces risk for a multitude of reasons, some of which are described below:
   i. Such a configuration inherently adds two (2) steps to the compressed air ride-through system activation process, both of which could experience issues: a) recognizing the failure condition, and b) reacting to the failure condition to send a command to the automatic releasing valve(s) (101, 101A, 101B, 101C).
   ii. BMS systems are often programmed incorrectly, and/or all the edge cases have not been considered/programmed.
   iii. The engineers specifying the BMS sequences often merely write a high-level description of the desired sequence, without considering all the different facets and edge cases which could inhibit the sequence from working properly under all reasonable conditions.
   iv. The personnel tasked with actually writing the code may be several degrees removed from the personnel who understand the intent of the compressed air ride-through system and all the possible safeguards which must be implemented into the programming.
   v. BMS systems and sequences are often not rigorously tested for all possible scenarios. Even with a detailed testing/commissioning effort, a particular set of untested conditions may cause unexpected behavior.
   vi. Changes are often made to BMS systems on a regular basis, and thus even if the compressed air ride-through system activation sequences were fully tested and commissioned at one point in time, later changes may jeopardize the sequence.
   vii. During a utility failure, lots of alarms will likely be sent to the BMS simultaneously, which could cause lag issues or possibly overload the compressed air ride-through system at the exact time when it needs to react quickly to send a command to the automatic releasing valve(s) (101, 101A, 101B, 101C).
   viii. In order for a BMS to deliver a command to the compressed air ride-through system immediately after a normal utility power failure, the BMS panels would likely need to be served by UPS or have internal battery backup. It may be possible to arrange the BMS command to the automatic releasing valve(s) (101, 101A, 101B, 101C) as a constantly-powered circuit, such that the loss of utility or the loss of the BMS panels themselves activates the compressed air ride-through system. However, this too could be jeopardized with future changes to the BMS.
   ix. If the BMS did not behave in the expected manner, possibly following a failure, the root cause may not be identified, even if significant money is allocated for the investigation. Other corrective actions may be implemented without finding or addressing the root cause.
   x. Unlike manufacturer-provided control systems which have the benefit of being rigorously tested under non-duty, controlled conditions, and are purpose-built for a particular application (and the application engineers/programmers can learn from multiple deployments of the control system), the programming in each BMS system tends to be a custom, “one-off” solution, and thus will usually be less reliable.

The optional controller (104) can manage some or all of the functions described above, or other control and monitoring functions. The optional controller (104) can monitor and/or control the various devices and sensors in the compressed air ride-through system (including, but not limited to, 101, 101A, 101B, 101C, 106, 111, 112, 113, 114, 119, 140, 150, 162, 163, 163A, 167, 167A, 167B, 165, 146, 106, 150, 152, 163, 164, 174, 178, 181A, 181B, 185, 187, 188, 189, 191, 192, 193, 198, 199A, 200, 201, 204, 205, 207, 177, 206, etc.), and/or assist in communicating the indication of a non-standard operating condition (102) to the automatic releasing valve (101, 101A, 101B, 101C) or to a pilot valve (206) which controls the automatic releasing valve (101, 101A, 101B, 101C). The following is a non-exhaustive list of some possible functions, features, and accessories of the optional controller (104):
a. Generate warnings/alarms if the compressed air tank (100, 100A, 100B, 145) or connected appurtenances appear to have a leak. Could incorporate a logical function which accounts for temperature changes as well (a pressure drop in the compressed air could occur simply due to a temperature drop, without any leaks present).
b. Generate other warnings/alarms based on criteria which is established for the other monitored devices/points.
c. Communicate warnings, alarms, statuses, real-time monitoring data, digital points, analog points, virtual points, etc. to the BMS or to remote panels or devices. A common building communication protocol could be used, such as BACnet or Modbus (or other protocols) or hardwired connections could be used.
d. Accept signals from external devices, such as the BMS or temperature sensors or power-sensing switches.
e. Control the activation, resetting, and re-charging/re-pressurization of the compressed air ride-through system.
f. Incorporate a digital or analog display showing various information regarding the compressed air ride-through system.
g. Perform internal calculations using the monitored data and other inputs, such as performing a calculation to approximate the discharge time of the compressed air ride-through system, or to approximate the discharge airflow, discharge temperature, system performance, cooling capacity and duration, etc. The results of these calculations could be displayed locally and/or communicated to external systems.
h. Incorporate manual controls, dials, switches, buttons, indicator lights, touchscreens, labels, etc. to act as a human-machine interface (HMI).
i. Record alarm and event history.
j. Incorporate a sequence and a means of initiating/scheduling automatic and manual checks, tests, and maintenance sequences. The nature of the compressed air ride-through system is to generally sit dormant (i.e. in standby) and activate infrequently when needed, therefore, without periodic testing, an issue with the compressed air ride-through system may not manifest, be recognized, or surface until it is actually needed to activate. So, incorporating a means of conducting periodic testing would help identify any potential issues early, under non-emergency conditions—this helps minimize the chance that an issue manifests during a real activation/emergency. The periodic testing could be conducted manually or automatically (or possibly a combination, with manual initiation of the periodic checks, but with a subsequent automatic sequence after manual initiation of the checks). One simple, manual periodic check would be simply opening a disconnect upstream of the optional controller (104) or automatic releasing valve(s) (101, 101A, 101B, 101C), which would simulate a loss of utility power, and witnessing the compressed air ride-through system activate automatically. The compressed air ride-through system could be allowed to fully release in order to witness the entire sequence, or the activation of the compressed air ride-through system could then be aborted shortly after the initiation if desired to minimize the energy required for recharging/repressurizing the compressed air ride-through system. Note that periodic opening/stroking of valves, running pumps and fans, opening/closing of dampers, etc. is often good for these devices and extends their longevity and reliability. During these periodic checks, the optional controller (104) may record the performance of the compressed air ride-through system and possibly generate alarms or warnings. For example, during a periodic test of the compressed air ride-through system, if the pressure in the tank is dropping slower than expected (as determined through internal calcs and system-specific inputs), the optional controller (104) may generate an alarm or warning suggesting possible causes, such as dirty filters, clogged pneumatically-powered fluid movers (116, 123A, 150, 152, 162, 162A, 174, 194, 203, 205A, 205B, 211), valves not fully opening, etc.

Once the compressed air is released via the automatic releasing valve(s) (101, 101A, 101B, 101C), the compressed air is then conveyed to the pneumatically-powered fluid mover(s) (116, 123A, 150, 152, 162, 162A, 174, 194, 203, 205A, 205B, 211) through at least one compressed air conduit header (109) and/or at least one compressed air conduit branch (122), comprising single wall or double wall rigid or flexible pipes, hoses, or tubes. The compressed air conduit (109, 122) may or may not be insulated and may or may not be fitted with an optional internal liner/coating. The material used for the compressed air conduit (109, 122) may differ for different applications and projects. Utilizing a polymer-type compressed air conduit (109, 122) or a polymer liner or a different liner with low thermal conductivity would minimize the heat transfer from the cold compressed air to the inner walls of the compressed air conduit (109, 122) (as opposed to a metal inner surface, which has a higher thermal conductivity). Unlike a steady-state scenario, the transient nature of the compressed air ride-through system means that the temperature of the compressed air conduit (109, 122) will likely be equal to the air temperature of its surroundings initially, and will thus transfer heat to the cold compressed air once the compressed air ride-through system activated, regardless of the presence of external insulation (external insulation would inhibit further heat transfer from the air surrounding the compressed air conduit (109, 122) to the cold compressed air, but would not inhibit the initial transient heat transfer from the compressed air conduit (109, 122) to the cold compressed air). Thus, the released compressed air will gain heat from the compressed air conduit (109, 122), and the compressed air conduit (109, 122) will lose heat to the released compressed air. The lower the thermal conductivity of the inner surface of the compressed air conduit (109, 122), the less heat transfer that occurs. If the possibility exists for the exterior surface of the compressed air conduit (109, 122) to drop below the dewpoint of the surrounding air, then condensation may occur, and either a thicker wall, a different material, or external insulation may be required. However, since the compressed air ride-through system will only release compressed air for a short period, there may not be enough time for the external surface of the compressed air conduit (109, 122) to drop below the dewpoint, even if the thermal conductivity of the compressed air conduit (109, 122) is relatively high. Using double wall compressed air conduit (109, 122) would add an insulation layer in the form of an air gap. If the compressed air conduit is utilized as a header (109), the end of the compressed air conduit header (109, 122) would be capped (129).

One or more compressed air conduit branches (122) may split off from the compressed air conduit header (109) to serve pneumatically-powered fluid mover(s) (116, 123A, 150, 152, 162, 162A, 174, 194, 203, 205A, 205B, 211). A multitude of different pneumatically-powered fluid mover(s) (116, 123A, 150, 152, 162, 162A, 174, 194, 203, 205A, 205B, 211) of different types may be served by the compressed air conduit (109, 122). On the drawings, a compressed air conduit which serves additional undepicted pneumatically-powered fluid movers which are not shown on the figure is labeled as (124).

For pneumatic motors (150) and air-operated diaphragm pumps (162A), the compressed air discharged from the compressed air outlet can be directed through a secondary compressed air conduit (160) to then serve a secondary device, such as another pneumatically-powered fluid mover (116, 123A, 150, 152, 162, 162A, 174, 194, 203, 205A, 205B, 211), a pneumatic control valve (167B), a submerged compressed air direct injector (197) in a thermal storage tank (189), a pneumatically-powered agitator (198) in a thermal storage tank (189), or a pneumatically-overridden piece of principal cooling equipment (123A, 203, 203A, 203B, 204, 205, 205A). The compressed air in the secondary compressed air conduit (160) would have a lower pressure, but likely a lower temperature as well. If the compressed air ride-through system is configured with devices in series which utilize a secondary compressed air conduit (160), the added resistance from the secondary device fed by the secondary compressed air conduit (160) must be considered when analyzing the sizing and performance of the system.

Various manual valves (105) may be used throughout the compressed air ride-through system for isolation, maintenance, and testing purposes.

Optional air filters (131) or optional air dryers (132) may be incorporated into the compressed air ride-through system to minimize the delivery/release of debris, particles, and moisture to the downstream devices and into the data center. The presence of air dryers (132) will also minimize the risk of condensation and freezing in the downstream devices and downstream compressed air conduit (109, 122).

Note that in some configurations/embodiments, it may be beneficial to omit the optional air dryers (or arrange/select them in such a way that the released air has a moderate humidity level instead of totally dry air). This is because the presence of water/moisture in the airstream increases the heat transfer coefficient of air (i.e. moist air has a higher heat transfer coefficient than dry air). However, most users would likely not tolerate the possibility of water drips, so a moisture management system/device would likely be necessary if the intent were to discharge moist air.

An optional regulating valve (106) may be incorporated into the compressed air ride-through system in order to control the compressed air pressure, control the compressed air mass flowrate, control the compressed air temperature, control the compressed air discharge time, or a combination thereof. The optional regulating valve (106) may also be used to control the pressure, temperature, cooling capacity, flowrate, or operation of pneumatically-powered fluid movers (116, 123A, 150, 152, 162, 162A, 174, 194, 203, 205A, 205B, 211) and other downstream devices, such as air amplifiers (116), compressed-air-to-cooling-fluid heat exchangers (163), primary-to-secondary heat exchangers (163A), vortex coolers (178), pneumatic motors (150) or reaction-type fans (174), airlift pumps (194), submerged compressed air direct injectors (197), pneumatic belt tensioner or clutch (205, 205A), pneumatically-powered agitators (198), air-operated diaphragm pumps (162A), and pneumatically-overridden principal cooling equipment (123A). The optional regulating valve (106) may be controlled mechanically, electronically, pneumatically, or digitally.

Optional throttling/Joule-Thomson (JT)/expansion type valves (146) may be incorporated into the compressed air ride-through system to drop the temperature of the air via the Joule-Thomson effect, in which a gas will drop in temperature due to a pressure drop, provided the initial conditions are below the Joule-Thomson inversion point. The JT valve(s) (146) may be used for ensuring that during the initial moments of the compressed air ride-through system activation, before the air inside the tank has been able to drop in temperature due to expansion and imparting pressure-volume work, that a temperature drop can be achieved. As the air inside the compressed air tank (100, 100A, 100B, 145) expands over the course of the compressed air ride-through system activation, the temperature drop caused by the JT valve (146) may not be necessary at that point, and thus may be bypassed or may go full open so that the final temperature of the released compressed air entering the pneumatically-powered fluid mover(s) (116, 123A, 150, 152, 162, 162A, 174, 194, 203, 205A, 205B, 211) is not too cold. In some embodiments, the JT valve (146) may provide the majority of the cooling/temperature drop in the compressed air ride-through system, in others it may only make a minor contribution, or may not be needed at all. The JT valve(s) (146) may be incorporated on the compressed air conduit header (109), or on the compressed air conduit branch lines (122, 124). The JT valve(s) (146) may be controlled mechanically, electronically, pneumatically, or digitally, or may simply have a fixed orifice.

As part of the calculations conducted by the inventor for this patent to quantify the performance of the backup system described herein, a possible fundamental optimization point may have been found, at least under isentropic conditions. It is unknown if this apparent optimization point has been discussed in compressible flow literature previously. When releasing a fixed mass of compressed air isentropically from a compressed air tank (100, 100A, 100B, 145), the mass flowrate of air leaving the compressed air tank (100, 100A, 100B, 145) is initially high, and then drops over the course of the release, eventually dropping to no flow when the pressure inside the compressed air tank (100, 100A, 100B, 145) has dropped to atmospheric pressure. Similarly, the stagnation temperature of the compressed air leaving the tank is initially “high” (i.e. it is equal to the initial starting stagnation temperature), and then the stagnation temperature of the compressed air drops over the course of the release, because as more compressed air leaves the compressed air tank (100, 100A, 100B, 145) each remaining portion of compressed air in the tank expands further. If a differential temperature (i.e. difference in temperature or delta-T) as the difference between the initial stagnation temperature of the compressed air in the compressed air tank (100, 100A, 100B, 145) and the stagnation temp in the compressed air tank (100, 100A, 100B, 145) over the course of the release; this delta-T obviously gets larger over the course of the release. Then an isentropic “self-referential” convective cooling power can be defined for the compressed air releasing from an adiabatic tank (meaning the tank doesn't gain or lose any of the heat stored in its walls to the compressed air, nor does the tank gain or lose any heat from the environment) as the product of the (specific heat of the compressed air)×(the mass flowrate of compressed air leaving the tank)×(the delta-T between the initial stagnation temperature and the stagnation temperature of the compressed air leaving the tank). The term “self-referential” is used because the delta-T is based on the initial stagnation temperature of air inside the tank, not the temperature of some target object, and “convective” is used because this definition is based on the cooling potential of the air stream released from the tank, not considering the potential cooling from conductive or radiative effects. So, since the mass flowrate of the compressed air leaving the tank drops over the course of a release, whereas the self-referential stagnation delta-T of the released compressed air increases, multiplying these two values along with the specific heat (which is constant under assumptions of a thermally-perfect gas and a calorically-perfect gas) at each time increment along a release results in a curve with a peak. The peak can be considered a maximum isentropic “self-referential” convective cooling power of the released gas and thus may be considered an optimized point or a desired target operating point. Although additional research is required, one interesting finding is that the peak of this curve, i.e. the point along the release of the air from the tank where the maximum isentropic “self-referential” convective cooling power is achieved, seems to always occur when the absolute stagnation pressure in the tank has dropped to about 0.36 to 0.37 of the initial absolute stagnation pressure, provided that the switch in the leaving mass flowrate from sonic flow to subsonic flow at the discharge opening occurs after this apparent maximum cooling power peak. In other words, if the initial stagnation pressure in the tank is high enough such that the switch from sonic flow exiting the tank to subsonic flow exiting the tank occurs after this apparent maximum cooling power peak, then apparent maximum cooling power peak seems to always occur at a fixed pressure ratio of around 0.36 to 0.37. This value is very close to 1/e, but that may or may not be a coincidence (this finding may simply be a natural result of the entropy equations where a natural logarithm of a pressure ratio exists, but further investigation will be conducted). And this apparent maximum cooling power peak seems to occur at the same pressure ratio not just for air, but for any gas under thermally-perfect gas and calorically-perfect gas assumptions, regardless of the specific heat ratio, initial temperature, individual gas constant, atmospheric pressure, orifice area, etc, provided that the switch in the leaving mass flowrate from sonic flow to subsonic flow at the discharge opening occurs after this apparent maximum cooling power peak. Therefore, for the purposes of the backup system presented herein, it may be beneficial to use the 0.36 to 0.37 pressure ratio as a metric or a target value when configuring the backup system. Note however that this is a purely theoretical value which doesn't account for a) the heat gain from the walls of the tank and the walls of the piping/hosing/tubing, b) additional friction losses down the piping/hosing/tubing, c) compressibility/real gas effects, d) air amplification and mixing effects, and e) the fact that the target of the cooling (the ITE) is not necessarily at the same temperature as the tank's initial starting temperature. Therefore, a more specific, real-world optimization point most likely exists which is likely the better target value for any optimization schemes which are considered. It may also be possible to manipulate different aspects of the backup system during a release in order to manipulate the point at which this apparent maximum cooling power point occurs, or which extend the duration at which a range of near-maximum cooling power points occur. Also, another goal or target may be maximizing the area under the cooling power curve so as to maximize the total cooling which can be achieved.

For airside cooling and airflow, an air amplifier (116) is one type of pneumatically-powered fluid mover which may be used. These types of devices can be categorized as Coanda-type air amplifiers, venturi blowers, air-operated in-line conveyors, air knives, air ejectors, and entraining air nozzles, or similar. These devices utilize compressed air to create high-velocity jets or streams, which then create a low-pressure area. The air amplifier (116) is arranged to utilize the low-area pressure to entrain or induce ambient air from the space (120) into a discharge airstream (121), which consists of the compressed air and the entrained/induced air (120). Therefore, these devices use the compressed air to entrain or induce ambient air (120) to increase the total airflow (and generate a pressure differential in some cases) and mix the compressed air with ambient air to deliver a discharge airstream (121) with a mixed air temperature which is cooler than the entrained/induced air (120). For several air amplifiers, the volume of ambient air which can be entrained/induced is several times larger than the compressed air volume itself. For example, a common air amplifier (116) may be able to entrain/induce up to twenty-five standard cubic ft per min (SCFM) of ambient air (120) for every one SCFM of compressed air “consumed”/delivered through the device. Note that the use of air amplifiers (116) offers many benefits over simply releasing the compressed air directly, such as:
a. Multiplies the airflow, which reduces the tank size required.
b. Allows ducting across the ITE and/or across a threshold, such as a ceiling plenum or containment wall, so that a pressure differential can be created across the ITE.
c. Allows a delivery mechanism for moving the already-cool cold-aisle air to the inlets of the ITE.
d. Mixes the cold compressed air to result in a mild temperature drop of the ambient air (120) (as opposed to discharging compressed air directly into the data center, which would likely be cold enough to create condensation and even frost).
e. Reduces the sound level to a tolerable level (as opposed to >100 dB for direct compressed air release).

The compressed air ride-through system may be arranged in a “self-contained” assembly (144) with air amplifier(s) (116) connected directly to an automatic releasing valve (101, 101A, 101B, 101C), which is directly connected to a compressed air tank (100A), wherein the compressed air conduit (109, 122) is relatively short. This configuration may be suitable for small data centers, such as IT closets, MDF rooms, and similar. Conversely, a large quantity of self-contained assemblies (144) may be used in a data center to simplify the installation.

Instead of utilizing air amplifiers (116), the compressed air can be used to power a pneumatic motor (150) which then drives a fan (152). Similar to air amplifiers (116), a pneumatic motor (150) driving a fan (152) (i.e. a pneumatically-driven fan or a pneumatically-powered fan) essentially accomplishes the same behavior. Depending on the characteristics of the pneumatic motor (150) and fan (152), this configuration may produce a smaller or larger effective amplification ratio and may result in a colder or warmer discharge air. Using a pneumatic motor (150) may have the benefit in certain arrangements of extracting additional work from the compressed air, possibly resulting in a colder temperature at the outlet (151) of the pneumatic motor (150) than could be achieved via expansion in the compressed air tank (100, 100A, 100B, 145) alone. The fan inlet air (148) would be pulled from the data center itself (similar to Configuration-1 described in a subsequent section) or pulled from a separate space within the return pathway (similar to Configuration-2 described in a subsequent section). The compressed air leaving the pneumatic motor (151) could then be directed to the inlet of the fan (152) through a re-directing conduit (151A), where it would mix with and cool down the fan inlet air (148), resulting in a cool discharge air (149), consisting of the fan inlet air (148) plus the compressed air discharged from the pneumatic motor (150). This configuration could be ducted (117), similar to Configuration-2 (described in a subsequent section). The pneumatic motor (150) and fan (152) could be configured in a housing (153) as well. Also similar to Configuration-2 (described in a subsequent section), the pneumatic motor and fan assembly could be fitted with a negative side damper/isolating device (118), a positive side damper/isolating device (119), a second inlet (117A) for a second pathway for fan inlet air (148A), isolating/modulating devices (140, 141), filters (143, 143A), and other accessories/features described herein.

Similar to the item above, pneumatically driven reaction-type fans (174) (or sometimes called vaneaxial jet fans) may be used instead of using pneumatic motors (150) to drive a fan (152). Pneumatically driven reaction-type fans (174) omit the pneumatic motor (150) by delivering compressed air directly to the fan blades, where the compressed air exit port/nozzle (175) is arranged on the trailing edge of the fan blades to produce thrust to spin the fan (174). The released compressed air from the ports/nozzles on the blades (174) is discharged into the airstream so that it mixes with the fan inlet air (148), resulting in a discharge airflow (176) which consists of the fan inlet air (148)+the released compressed air from the fan blade discharge ports/nozzles (174). Depending on the characteristics of the reaction-type fan (174), it may produce a smaller or larger effective amplification ratio than air amplifiers (116) and pneumatic motors (150) driving fans (152) and may result in a colder or warmer discharge air. Using a reaction-type fan (174) may have the benefit in certain arrangements of extracting additional work from the compressed air, possibly resulting in a colder temperature at the fan blade outlets (175) than could be achieved via expansion in the compressed air tank (100, 100A, 100B, 145) alone. The fan inlet air (148) would be pulled from the data center itself (similar to Configuration-1 described in a subsequent section) or pulled from a separate space within the return pathway (similar to Configuration-2 described in a subsequent section). This configuration could be ducted (117), similar to Configuration-2 (described in a subsequent section). Pneumatically driven reaction-type fans (174) could be configured in a housing (153) as well. Also similar to Configuration-2 (described in a subsequent section), the reaction-type fan (174) assembly could be fitted with dampers/isolating devices (118, 119), a second inlet (117A) for a second pathway for fan inlet air (148A), isolating/modulating devices (140, 141), filters (143, 143A), and other accessories/features described herein.

Air amplifiers (116), pneumatically-driven fans (152), and reaction-type fans (174) may also be fitted with a means of modulation, so that they may modulate their output based on an input. For example, a particular air amplifier (116) may be fitted with a thermally-operated actuator which increases or decreases the orifice opening size in the air amplifier (116) in response to the discharge temperature of the air amplifier (116). Another example may be using a thermally-operated or pressure-operated actuator to open and close a damper/valve (140, 141) on the inlet or outlet of the air amplifier (116) in response to the incoming compressed air pressure or temperature.

For a mechanical means of notification that the compressed air ride-through system has activated, an optional air whistle (173) could be implemented.

Note that, although researched and analyzed in the process of creating this patent, the compressed air ride-through system specifically avoids/omits the use of vortex tubes/coolers for cooling the ITE (vortex tubes/coolers are described herein as an optional feature for cooling or heating the compressed air tank (100, 100A, 100B, 145) and thermal storage tank (189), but not for cooling the ITE). This is for the following reasons:
a. Vortex tubes inherently generate a stream of hot air along with the stream of cold air (the compressed air at the inlet of the vortex tube is essentially split into a cold stream and a hot stream). The hot stream of air is a form of waste heat and must be extracted or cooled or diluted (or otherwise “managed”), which would add additional cost.
b. Vortex tubes are generally only available in relatively small sizes. Although larger vortex tubes can be built, they tend to be custom-built in larger sizes and thus very costly.
c. Vortex tubes inherently have a trade-off between cold-side discharge temperature and cold-side discharge airflow.
d. Vortex tubes are not designed to incorporate a means of air amplification on the cold-side discharge, as the back-pressure created from a connected air amplifier causes the performance of the vortex tube to suffer.
e. Vortex tubes rely on their internal structure to spin and separate the compressed air into two concentric vortices, which creates cold air on one end and waste hot air on the other, whereas the compressed air ride-through system utilizes the rapid expansion of a stored volume of compressed air to generate cold temperatures, and thus the compressed air ride-through system can make use of all of the stored compressed air for cooling purposes.
f. Although vortex tubes can create high-velocity jets on both their cold-side and hot-side openings which will entrain/induce some amount of ambient air, they are not specifically designed to do so, and thus would have small amplification ratios. And the minimal amount of entrained air will not have much ability, if any, to overcome flow resistances (such as the resistance of pulling air through a piece of ITE or ITE rack). The minimal amount of ambient air entrained by a vortex tube would likely be just a circulating stream of ambient air which merely circulates within the open space where the vortex tube discharge opening resides. Furthermore, vortex tubes are not specifically designed to mix ambient air with the discharge air, and thus there may be uneven temperatures between the discharge air and the small amount of entrained air.

The compressed air ride-through system is primarily intended to be operated with regular air (and this is most likely the most viable option). Although the compressed air ride-through system would still work as intended (with some slightly different performance) if a different gas or a mixture of gases were used instead, doing so would pose a number of issues; the gas used must still be breathable without any short-term or long-term health effects, and the gas must be readily available for recharging/re-pressurizing the compressed air tank (100, 100A, 100B, 145) following an activation of the compressed air ride-through system. Using carbon dioxide or air with a higher concentration of carbon dioxide may offer some benefits, but the associated increase in costs and logistics most likely would not warrant its use. Similarly, a liquid or solid could be used inside the compressed air tank (100, 100A, 100B, 145) which evaporates/flashes to a gas or otherwise undergoes a phase change when the pressure in the compressed air tank (100, 100A, 100B, 145) drops—this would likely have a cooling effect on the remaining air inside the compressed air tank (100, 100A, 100B, 145). The use of such a liquid or solid must again not pose any short-term or long-term health effects and not be corrosive to the compressed air tank (100, 100A, 100B, 145). In the example of carbon dioxide, if it were used directly in the compressed air tank (100, 100A, 100B, 145), the pressure inside the compressed air tank (100, 100A, 100B, 145) would need to be considerably high to keep the CO2 in liquid form at typical outdoor or room temperatures. To avoid the need to pressurize the entire compressed air tank (100, 100A, 100B, 145) to a high pressure, liquid or solid CO2 could be held in a separate, smaller chamber at a higher pressure and released into the larger compressed air tank (100, 100A, 100B, 145) upon activation of the compressed air ride-through system. The implementation of such an option would require additional material, additional actuated devices, and would require replenishment of the non-air gas, liquid or solid, which may render the option cost-prohibitive, but nonetheless it would be possible.

Since the compressed air ride-through system acts, in part, as an energy storage system (storing the compressed air in a compressed air tank (100, 100A, 100B, 145)), it would be possible for the compressed air tank (100, 100A, 100B, 145) to be recharged (i.e. re-pressurized) using renewable/alternative energy sources. For example, the portable or permanent compressor (113) could optionally be powered by solar or wind power when available, and could pressurize the compressed air tank (100, 100A, 100B, 145) during the periods when those renewable/alternative energy sources are available. The power for the compressor (113) or other powered devices, such as the optional tank heating and cooling devices (187, 188), could be arranged to be partly derived from renewable sources.

Although the period of time in which the compressor (113) would be running would be relatively small (only needed to run to recharge/re-pressurize the compressed air tank (100, 100A, 100B, 145) following an activation of the compressed air ride-through system), the heat of compression could be extracted through the intercooler or some other heat exchanger to provide useful heating. The demand for the heating would have to occur simultaneously with the operation of the compressor; and given the small window of time of compressor operation, such a configuration would likely require some other means of heating when the compressor was not running. This means that attempting to extract the heat of compression from the compressor (113) is most likely not economically viable for the compressed air ride-through system, but nonetheless, it is possible. One possible configuration would be extracting the heat of compression for a heating demand while the facility is on generator power, since it is likely that the compressor (113) would be running for at least the first few hours of a utility failure or other non-standard operating condition to recharge/re-pressurize the compressed air tank (100, 100A, 100B, 145), depending on the configuration. One viable use for this heat may be for reheating the released compressed air prior to entering a pneumatic motor (150), reaction-type fan (174), or a flywheel, although this would not likely be necessary for most pneumatic motors (150) and reaction-type fans (174) in the configuration described herein.

### Description of Some Embodiments for Airside Applications in which the Entrained/Induced Air is Drawn from the Overall Volume of the Data Center (General Configuration-1)

The air amplifiers (116), pneumatically-powered fans (152), and reaction-type fans (174) may be arranged in several different configurations, depending on the specific needs of each application. This section describes the embodiments/configurations where the entrained/induced air (120, 148) is drawn from the overall volume of the data center (134) and the discharge air (121, 149, 176) (which consists of compressed air and entrained/induced air (120, 148)) is directed into or towards the cold aisles (126) or cold aisle containment (137).

The statements in this section are written in terms of air amplifiers (116), but these statements are applicable to pneumatically-powered fans (152) and reaction-type fans (174) as well.

In this configuration the entrained/induced air (120) is pulled from the overall volume of the data center itself (134). If the air amplifier (116) is located generally in the cold aisle (or anywhere in the room outside of the hot aisle containment (128), essentially making the rest of the room an extension of the cold aisle), then the entrained/induced air (120) will be relatively cool (generally ranging from around 68° F. to 78° F.). This means that cool discharge air (121) will immediately be available from the air amplifier (116) upon activation of the compressed air ride-through system. The released compressed air from the compressed air tank (100, 100A, 100B, 145) will initially be at the temperature of the air inside compressed air tank (100, 100A, 100B, 145) (although there will likely be some minor Joule-Thomson cooling taking place as well). If the compressed air tank (100, 100A, 100B, 145) is located outdoors, and the activation of the compressed air ride-through system occurs on a hot day, the initial air inside the compressed air tank (100, 100A, 100B, 145) will be roughly at the outdoor air temperature, which would likely be too warm to discharge directly to the ITE. However, this is only true for the released compressed air; it will mix with the entrained/induced air (120) in the data center to result in an acceptable temperature level at the ITE inlets (the high amplification ratio of the air amplifiers (116) ensures that the final discharge temperature is weighted towards the temperature of the entrained/induced air (120)). Further mixing then occurs as the discharge air (121) mixes with the ambient air in the cold aisle. Therefore, again, this configuration ensures that the discharge air (121) will be sufficiently cool immediately upon activation of the compressed air ride-through system.

This configuration will generate a large airflow directed into the cold aisles (126), which will help reduce recirculation in and around the ITE cabinets/racks (125). Recirculation in and around the ITE cabinets/racks (125) is undesirable both in normal operation and during a utility failure or other non-standard operating condition, since it allows warm air from the hot aisles (127) to mix with the cool air in the cold aisles (126), thus elevating the mixed air temperature at the inlets to the ITE. By delivering air from the air amplifier (116) to the cold aisles (126), the percentage of ITE airflow which is pulled from the adjacent hot aisles (127) is reduced.

Although slight pressure differences within the data center (134) could be achieved in this arrangement, the magnitude of the differential pressure across the ITE cabinets/racks (125) will be small, since the entrained/induced air (120) is being pulled from the same volume that the discharge air (121) is being delivered to. Separating the entrained/induced air (120) from the discharge air (121) across a “container” or “divider” is necessary to create a more substantial differential pressure (this is described in the next section).

This configuration is likely the most suitable if the data center (134) has no means of containment, no ceiling plenum (135), no raised floor (139), or possibly does not have well-defined/well-arranged cold aisles (126) and hot aisles (127).

### Description of Some Embodiments for Airside Applications in which the Entrained/Induced Air is Drawn from a Space or Location Connected to a Hot Aisle (General Configuration-2)

The air amplifiers (116), pneumatically-powered fans (152), and reaction-type fans (174) may be arranged in several different configurations, depending on the specific needs of each application. This section describes the embodiments/configurations where the entrained/induced air (120, 148) is drawn from a hot aisle (127) or from a separate space/plenum connected to a hot aisle, such as a ceiling plenum (135), a hot aisle containment assembly (128), an adjacent CRAC/CRAH gallery (135A), the inlets of the principal cooling equipment (123), or some other space/room outside of the data center (135B), and the discharge air (121, 149, 176) (which consists of compressed air and entrained/induced air (120, 148)) is directed into or towards to a cold aisle (126), a cold aisle containment assembly (137), a raised floor plenum (139), or another supply pathway.

The statements in this section are written in terms of air amplifiers (116), but these statements are applicable to pneumatically-powered fans (152) and reaction-type fans (174) as well.

This configuration generates a large airflow directed into the cold aisles (126), which would help reduce recirculation in and around the ITE cabinets/racks (125). Recirculation in and around the ITE cabinets/racks (125) is undesirable both in normal operation and during a utility failure or other non-standard operating condition, since it allows warm air from the hot aisles (127) to mix with the cool air in the cold aisles (126), thus elevating the mixed air temperature at the inlets to the ITE. By delivering air from the air amplifier (116) to the cold aisles (126), the percentage of ITE airflow which is pulled from the adjacent hot aisles (127) is reduced.

This configuration would result in less recirculation than Configuration-1 because this configuration generates a significant differential pressure across the ITE (125). This large differential pressure across the ITE is the primary advantage of Configuration-2 over Configuration-1. The large differential pressure is achieved by utilizing a barrier, threshold, container, or divider which exists between the supply and return airstreams. This barrier comes in the form of a ceiling plenum (135), containment wall (128, 137), data center wall, raised floor (139), etc., as described above. This effectively separates the entrained/induced air (120) from the discharge air (121). The magnitude of the differential pressure created by the air amplifiers (116) would be larger than the airside pressure differential across the ITE cabinet produced by the internal fans of the ITE alone, and the air amplifiers (116) should be sized to ensure that the air pressure in the cold aisle (126) is higher than the air pressure in the hot aisle (127) to minimize recirculation.

For this configuration, since a passageway would inherently be created between the supply and return airstreams, the presence of this passageway would likely constitute in a small, but significant amount of “bypass air” or “leakage” during normal operation. That is to say, the normal cool supply air would likely be able to bypass the ITE and pass backwards through the air amplifier (116) during normal operation, reducing overall efficiency. To prevent this configuration from reducing the efficiency of the principal cooling equipment (123) during normal operation, an optional means of preventing backflow through the air amplifier (116) could be implemented. This could come in the form of a backdraft damper, valve, spring-loaded damper, pneumatically-operated damper, disposable cap, “break-through” paper seal, or similar, and it could be implemented on either the positive side (119) or negative side (118) of the air amplifier (116).

To minimize the risk of delivering dust and particulate to the ITE, an optional filter (143) could be implemented on the entrained/induced air (120) inlet or the discharge air (121) outlet. The filter could be arranged as a curved or hemispherical filter (143A) to increase the filtration surface area and spread out the discharge pattern. The filter (143, 143A) may also incorporate a means of moisture collection/absorption, such as a mist eliminator, an oil/grease eliminator, a desiccant, a hydrophilic material, a sponge, a hydrophilic foam, or a combination thereof. The collected/absorbed moisture could then evaporate into the ambient air over time after an activation of the compressed air ride-through system.

To facilitate mounting of the air amplifier (116) on the wall/divider/ceiling, an optional mounting plate/bracket (136) could be implemented.

On the discharge side of the air amplifier (116), an optional tapered or untapered duct, nozzle, cone, pipe, or fitting (142) may be implemented to direct and manipulate the discharge air as needed. It may or may not penetrate a wall, ceiling, containment panel, etc.

A possible drawback of this configuration is the chance that the initial discharge air (121) from the air amplifiers (116) is too warm for the ITE inlets (125). This may occur because the entrained/induced air (120) would be at the hot aisle temperature, and the released compressed air from the compressed air tank (100, 100A, 100B, 145) has not yet expanded enough inside the compressed air tank (100, 100A, 100B, 145) to mix with and cool the entrained/induced air (120) down to a more acceptable discharge air (121) temperature. For example, if the data center typically operated with a cold aisle temperature setpoint of 72° F., and the ITE generally had a 25° F. delta-T, then the hot aisle would generally be at 97° F. (assuming no recirculation). If the compressed air ride-through system utilized an outdoor compressed air tank (100, 100A, 100B, 145) and the compressed air ride-through system was activated on a hot day with an outdoor air temperature of around 88 F, and the air amplifier (116) had a compressed air consumption of 4 SCFM and an amplification ratio of 27, then the initial discharge air (121) temperature of the air amplifiers would be approximately:

$$a . [ ( 97 \times ( ( 4 \times 27 ) - 4 ) + ( 88 \times 4 ) ] / ( 4 \times 27 ) = 96.67 ° F .$$

Depending on several variables, it will generally take several seconds for the released compressed air from the compressed air tank (100, 100A, 100B, 145) to drop in temperature enough to sufficiently cool down the high-temperature entrained/induced air (120) from the hot aisle or associated communicable return air spaces to an acceptable cold-aisle temperature. Again, this is only a concern for this particular configuration and would only materialize if the compressed air tank (100, 100A, 100B, 145) were installed outdoors and the compressed air ride-through system activated on particularly warm day. Despite this, there are several ways that this can be mitigated:
a. Using a JT valve (146) to drop the initial temperature further via the Joule Thomson Effect.
b. Arrange the air amplifier (116) sufficiently away from the ITE inlets so that the discharge air (121) further mixes with the cool air already present in the cold aisles (however, this option will cease to be effective fairly quickly when the discharge air displaces the volume of cool air in the cold aisle, which could occur in a matter of seconds).
c. For data centers with raised floors (139), arrange the air amplifier (116) to pull from the hot aisles (127) and discharge directly into the raised floor (139), which will then reach the cold aisles via the floor grilles (138). This will allow the discharge air (121) to further mix with the cool air already present in the raised floor plenum (139) (however, this option will cease to be effective fairly quickly when the discharge air displaces the volume of cool air in the raised floor plenum, which could occur in a matter of seconds).
d. Arrange the air amplifier (116) so that either the entrained/induced air (120) or the discharge air (121) passes over or through the principal cooling equipment (such as a CRAC/CRAH) (123). This would take advantage of the residual thermal mass of the cooling coil in the principal cooling equipment (123), allowing the initially-warm discharge air to be cooled by the cooling coil in the same way as normal operation (whether that is achieved via passing the entrained/induced air (120) over the coil or passing the discharge air (121) over the coil). This option would likely produce a sufficiently-cool temperature for a time period long enough for the compressed air in the compressed air tank (100, 100A, 100B, 145) to expand sufficiently to cool the entrained/induced air (120) on its own. The drawback to this option is a likely drop in performance of the air amplifier (116) due to the higher airside resistance of pushing/pulling through the principal cooling equipment without the aid of the principal cooling equipment's fans (although there will be some aid during the fan's initial ramp down period). Another possible drawback is the “wind-milling” of the internal fans in the principal cooling equipment, which could cause electrical issues (the fan motor acting as a generator), although this condition is likely already accounted for in the factory controls of the principal cooling equipment (but not guaranteed).
e. Utilize a second inlet (117A) for a second pathway for entrained/induced air (120A) which pulls cooler air from the data center volume (134) or the cold aisle (126). An optional isolating/modulating device (such as a damper or valve) could be used on the second inlet (140) or the main inlet (141), or both, and can be used to initially pull some or all of the entrained/induced air (120, 120A) from the cooler data center volume (134) or cold aisle (126). Then the isolating/modulating devices (140, 141) could fully or partially open/close after a set time period or after a means of control directed it, so that the majority or all of the entrained/induced air (120) is then pulled from the hot aisle (127), ceiling plenum (135), hot aisle containment (128), CRAC/CRAH return gallery (135A) or other communicable return air space, creating the desirable differential pressure across the ITE for the remainder of the compressed air ride-through system release, now that the released compressed air is cold enough to cool the entrained/induced air (120) down to an acceptable cold aisle temperature.
f. Arrange the air amplifier (116) such that it pulls the entrained/induced air (120) from the hot aisle (127) or hot aisle containment (128) and directs the discharge air (121) towards a space or area which is either separated from the cold aisle (126) or just a distance away from the cold aisle (126), such as discharging to the CRAC/CRAH gallery (135A). This would extract the heat from the hot aisle and create a differential pressure across the ITE (125), and it would essentially create a small-time buffer where the cool air on the supply side of the principal cooling equipment (123) is pushed through the system to the cold aisles (126). This may create enough of a time buffer for the released compressed air from the compressed air tank (100, 100A, 100B, 145) to expand sufficiently to drop in temperature enough to create an appropriate cold aisle discharge air (121) temperature from the air amplifiers (116).
g. Implement an optional passive airside thermal storage heat exchanger (208) in the path of the entrained/induced air (120) or in the path of the discharge air (121). The optional passive airside thermal storage heat exchanger (208) is described in the next section.

### Description of Some Embodiments for a Passive Airside Thermal Storage Heat Exchanger

In both General Configuration-1 and General Configuration-2, depending on several variables, there may be a short period after the initial activation of the compressed air ride-through system where the compressed air from the compressed air tank (100, 100A, 100B, 145) has not yet expanded sufficiently to drop in temperature low enough to produce an acceptable discharge air (121) temperature when mixed with the entrained/induced air (120). This may or may not be an issue, since the discharge air (121) from the air amplifiers (116) will likely mix with the cool air already in the flooded room/cold aisles (126). If the conditions and criteria on a particular project require that the discharge air (121) from the air amplifiers (116) be immediately cool upon system activation with no delay, then the entrained/induced air (120) or discharge air (121) may be passed through an optional passive airside thermal storage heat exchanger (208) installed in the flooded room/cold aisle (126), wherein the optional passive airside thermal storage heat exchanger (208) contains a fixed mass of heat exchange material. The passive airside thermal storage heat exchanger (208) would help ensure that the discharge air (121) from the air amplifier (116) is at an acceptably-cool temperature immediately from the start of the compressed air ride-through system activation (rather than achieving an acceptably-cool discharge temperature a few seconds after the start of the compressed air ride-through system activation because the compressed air has not expanded sufficiently). The optional passive airside thermal storage heat exchanger (208) would accomplish this immediate cooling of the entrained/induced air (120) or discharge air (121) by simply residing in the flooded room/cold aisle (126), where the fixed mass of heat exchange material comprising the optional passive airside thermal storage heat exchanger (208) would naturally acclimate the cool temperatures in the flooded room/cold aisle (126) and remain at that cool temperature until the compressed air ride-through system activates, thus acting as a form of thermal storage. When the compressed air ride-through system activates, the entrained/induced air (120), which may be considerably warm in General Configuration-2 if being pulled from the hot aisle (128) or ceiling plenum (135), would pass over/through the cool material in the optional passive airside thermal storage heat exchanger (208), and thus the discharge air (121) will experience some immediate cooling, before the compressed air in the compressed air tank (100, 100A, 100B, 145) has expanded enough to cause sufficient cooling on its own.

The passive airside thermal storage heat exchanger may be installed on an air amplifier (116), a pneumatically-driven fan (152), a reaction-type fan (174), or a pneumatically-overridden piece of principal cooling equipment (123A).

Several different arrangements and material options may be used in the optional passive airside thermal storage heat exchanger (208) (or a combination thereof), including, but not limited to:
a. A solid mesh, solid screen, solid wire in a grid pattern, solid wire in a coil pattern, or solid wire in a different type of pattern with a large surface area. These are likely the simplest, most viable options for the optional passive airside thermal storage heat exchanger (208), since these options require no form of “reset” (the solid automatically acclimates back down to the temperature of the flooded room/cold aisle (126)), and can achieve a large temporary cooling power by the nature of the large surface area.
b. A packed bed or grid of solid spheres or pellets.
c. A closed and hollow volume of solid tubing, a closed and hollow volume of a solid coil, or a packed bed or grid of closed and hollow volumes of solid spheres or pellets, wherein the closed, hollow volume(s) encapsulate a solid, a liquid, a gas, or a phase-change material (PCM) with a high specific heat.
d. A phase-change material (PCM), with a phase transition temperature (such as melting point or boiling point) at a point in between the flooded room/cold aisle (126) temperature and the hot aisle (127) or ceiling plenum (135) temperature. For example, paraffin wax, cocoa butter, or a refrigerant inside of a tube, coil, spheres, pellets, or other encapsulation method may be used as PCM's. Heat pipes/thermosiphons, which contain a PCM such as water, alcohol, or ethanol, may also be used to quickly transfer heat to the surrounding air external to the optional passive airside thermal storage heat exchanger (208). The primary benefit of PCM's is their ability to absorb a large amount of heat during a phase transition for their given mass or volume (effectively their specific heat capacity values “spike” during a phase transition). A solid filler material, such as copper mesh, may be distributed within the PCM to increase the overall effective thermal conductivity of the PCM.

Examples of the solid materials which may be used in the optional passive airside thermal storage heat exchanger (208) for the solid mesh, solid screen, solid wire, solid spheres, solid pellets, closed and hollow volume of solid tubing, closed and hollow volume of a solid coil, packed bed or grid of closed and hollow volumes of solid spheres, and packed bed or grid of closed and hollow volumes of solid pellets include, but are not limited to:
a. Metals, such as copper, aluminum, or steel;
b. Polymers, such as polyethylene, high density polyethylene, low density polyethylene, polypropylene, polybutylene terephthalate, polyetherimide, or acrylic;
c. Other materials, such as rubber or paraffin; or
d. a combination thereof.

Examples of the materials which may be encapsulated in the optional passive airside thermal storage heat exchanger (208) include, but are not limited to, water, glycol, dielectric fluid, paraffin, paraffin wax, wax, beeswax, cocoa butter, aqueous salt solutions, salt hydrates, hydrocarbons, lipids, sugar alcohol, refrigerants, or a combination thereof.

The optional passive airside thermal storage heat exchanger (208) may be arranged in the form of a tapered opening or cone (208A) in the path of the discharge air from the air amplifier (116) or the pneumatically driven fans (152, 174).

In addition to helping to ensure cool discharge air (121) temperatures immediately after the compressed air ride-through system activation, the optional passive airside thermal storage heat exchanger (208) may have other benefits as well, such as:
a. Acting as a filter for debris/particulate if arranged in a mesh structure.
b. Acting as a mist eliminator to catch water droplets from the compressed air or from condensation. If arranged/configured to act as a mist eliminator, the optional passive airside thermal storage heat exchanger (208) may be fitted with weep holes and/or a pan for collecting any captured water droplets so that the water could evaporate over time.
c. Inhibiting/discouraging cool air from bypassing the ITE (125) through the air amplifier (116) during normal operation.
d. Reducing the magnitude of the negative pressure at the entrained/induced air inlet (120).
e. Increasing the flow resistance of an air amplifier (116), pneumatically-driven fan (152), or reaction-type fan (174), effectively reducing the amplification ratio. For example, several air amplifiers (116) currently on the market, especially in the larger ranges, have an amplification ratio which is high enough (i.e. 20-50) that even very cold primary compressed air temperatures from the compressed air tank (100, 100A, 100B, 145) will not drop the entrained/induced air (120) temperature adequately, simply because of the disproportionate mass flowrates of the primary air vs the entrained/induced air (120). For example, for an air amplifier (116) with a nominal compressed air consumption of 4 SCFM and a nominal amplification ratio of 27, pulling from a hot aisle (127) at 97° F., and being supplied/powered by very cold compressed air at −50° F. (i.e. 50 degrees below 0° F.), the final discharge air (121) temperature would still be approximately 91.56° F., as shown here:

$$i . [ ( 97 \times ( ( 4 \times 27 ) - 4 ) + ( - 50 \times 4 ) ] / ( 4 \times 27 ) = 91.56 ° F .$$

f. In other words, for air amplifiers (116), pneumatically-driven fans (152), or reaction-type fans (174) with high amplification ratios, although they can produce very large airflows for a relatively small amount of primary compressed air, even a primary compressed air temperature of −50° F. gets diluted into the large volume of entrained/induced air (120), and thus will not produce sufficiently-cold discharge air (121) temperatures. But the presence of an optional passive airside thermal storage heat exchanger (208) in the path of the entrained/induced air (120) or the path of the discharge air (121) will increase the flow resistance of the air amplifier (116), pneumatically-driven fan (152), or reaction-type fan (174), thus dropping the amplification ratio to a more desirable value, albeit at the detriment of airflow amplification. For the same example above, if an optional passive airside thermal storage heat exchanger (208) were implemented and its construction was such that the added airside resistance dropped the amplification ratio of the air amplifier from 27 to 15, the new discharge air (121) temperature would be approximately 87.2° F., which is now within the ASHRAE TC9.9 A1 Allowable Range, as shown here:

$$i . [ ( 97 \times ( ( 4 \times 15 ) - 4 ) + ( - 50 \times 4 ) ] / ( 4 \times 15 ) = 87.2 ° F .$$

Note that caloric materials with a solid-solid latent heat transition, such as elastocaloric and barocaloric materials, may also be viable options for the fixed mass of heat exchange material in an optional passive airside thermal storage heat exchanger (208), but further research is required, and thus they are mentioned here for reference only. Examples of elastocaloric materials include nickel-titanium alloys, copper-aluminum-nickel alloys, nickel-titanium-copper-chromium alloys, nickel-titanium-copper alloys, and rubber. Examples of barocaloric materials include neopentylglycol, plastic crystals, organic ion plastic crystals, and ammonium iodide. For example, Nitinol (nickel-titanium alloy) is an electrocaloric material (sometimes called a “shape memory alloy”) which can be manufactured to have a phase transition temperature between the expected flooded room/cold aisle (126) temperature and the hot aisle (127) or ceiling plenum (135) temperature. When it experiences temperatures above or below its transition point(s), its crystalline structure begins to change, accompanied by a “spike” in its specific heat capacity, and a contraction, elongation, or shape change of the material itself. However, solid-solid caloric materials often have separate “peaks” for the onset of the phase transition depending on whether the material is being cooled or heated, and the phase transition often occurs over a range of temperatures (unlike “pure” substances like water for which a phase transition occurs at a single discrete temperature for a given pressure). This means that a caloric material may only be able to be fully “reset” automatically if the entire temperature range of the phase transition occurred within the relatively narrow band of temperatures between the expected flooded room/cold aisle (126) temperature and the hot aisle (127) or ceiling plenum (135) temperature. Furthermore, some external mechanical means of stressing/straining (whether manual or automatic) the caloric material may also be required to fully reset the material in preparation for the next system activation, which may prove difficult or cost-prohibitive to implement.

### Description of Some Embodiments for Data Center Room-Level Pressurization Relief

Since the compressed air ride-through system would release a large volume of compressed air into the data center (134), there will be a slight increase in air pressure within the data center. Note that the mass of air which is released into the data center would be roughly equal to the mass of air inside the compressed air tank (100, 100A, 100B, 145) when expanded to local atmospheric conditions (the mass of air introduced to the data center does not include the entrained/induced air (120), since the entrained/induced air (120) is merely recirculated, not added). Depending on the compressed air ride-through system configuration and load density, the volume flowrate of the compressed air being introduced into the data center (134) may or may not be comparable to the amount of outdoor air which is normally added to data center space (134) on a regular basis for ventilation, dilution, and pressurization purposes (usually around 0.06 ACFM/square foot). In many cases, the normal outdoor air supplied to a data center for ventilation is done without any return or exhaust so that the data center is intentionally slightly pressurized. Therefore, if the compressed air flowrate to the data center (134) is comparable to the normal outdoor airflow, and assuming that the outdoor air fan(s) shut down temporarily upon a loss of utility power, then the data center space may not need any special/additional provisions for pressure relief/equalization (158, 159) to accommodate the compressed air ride-through system. This temporary mass imbalance and pressure imbalance will naturally “push” a portion of the air within the data center to the spaces outside of the data center through any gaps/leakage (158) in the data center construction, such as doors, penetrations (158), etc. If the gaps/leakage (158) in the data center construction are not sufficient to prevent the air pressure within the data center from exceeding a safe limit (such as the pressure that the weakest walls can withstand), then a space pressure reliever (159) may be implemented. The space pressure reliever may come in the form of a relief damper, backdraft damper, counterbalanced backdraft damper, pneumatic damper, motorized damper, check valve, or “break-through” seals, intentional openings/leakage (158), etc. If a space pressure reliever (159) is implemented, it would be desirable in most cases for the space pressure reliever to remain closed under normal operation to prevent bypass air (i.e. a continual loss of cooling). The space pressure reliever (159) would allow a pathway for the relief air to exit the data center (134), thus preventing over-pressurization. The methods used to quantify the adequacy of the data center construction for leakage, and whether or not a means of relief is necessary, would be similar to those found in NFPA 2001 and FSSA Application Guide to Estimating Enclosure Pressure & Pressure Relief Vent Area for Use with Clean Agent Fire Extinguishing Systems.

### Description of Some Embodiments for a Fire-Alarm-Interlocked Valve

Since the compressed air ride-through system would release a large amount of air into a space, there may be installations where the local authorities having jurisdiction (AHJs) may be concerned with the possibility of a fire occurring in the space served by the compressed air ride-through system, and an activation of the compressed air ride-through system occurring simultaneously during a fire. The probability of a fire occurring in the space and an activation of the compressed air ride-through system simultaneously is low, but not impossible. In such a scenario, the AHJs may be concerned that the release of air into the space would feed the fire and/or contribute to the spread of the fire and/or smoke (note that this may be an appropriate research topic to characterize the effect of a release of the compressed air ride-through system during a fire or smoke event in the space served). Therefore, it is reasonable to imagine that some AHJs would demand a means of interlocking the compressed air ride-through system with the fire alarm system to prevent/inhibit the activation of the compressed air ride-through system. In such a case, the compressed air ride-through system could be fitted with an optional fire-alarm-interlocked automatic valve (108) which would close when commanded from the fire alarm system, which would prevent the release of air into the data center. Another possibility may be to simply have a fire alarm sequence built into the optional controller (104) which prevents the automatic releasing valve (101, 101A, 101B, 101C) from opening when commanded by the fire alarm system. To avoid jeopardizing the reliability of the compressed air ride-through system (i.e. to avoid the possibility of a fire-alarm-interlocked valve from accidentally closing and preventing an activation of the compressed air ride-through system when there is no fire or smoke in the space served), note the following for the optional fire-alarm-interlocked automatic valve:
a. The fire-alarm-interlocked motorized valve actuator should ideally be powered closed, fail-open. Although fire-alarm-interlocked devices normally are arranged as powered open, fail-closed (or otherwise go to their “safe” position upon the loss of power), doing so would directly inhibit the operation of the compressed air ride-through system. This is because the compressed air ride-through system is primarily intended to activate and release air when there is a loss of utility power. Therefore, if the fire-alarm-interlocked motorized valve closes when there is a loss of power (i.e. if it's arranged as powered open, fail closed), the compressed air ride-through system will fail to release the compressed air.
b. Even if the fire alarm system has integral battery backup (such that the fire alarm system and assumedly the fire-alarm-interlocked motorized valve maintain power during a utility failure), any problem with the integral battery backup would jeopardize the operation of the compressed air ride-through system. Furthermore, an issue with the fire alarm system and/or its integral battery backup may not manifest until a utility failure actually occurs, at which point it would be too late to remedy (the compressed air ride-through system would have missed the window for activation in such a scenario). This is a further reason for omitting a fire-alarm-interlocked motorized valve unless demanded by the local AHJ, and further reason for using a powered-closed, fail-open actuator when such an interlock is required.
c. The criteria used for commanding the fire-alarm-interlocked motorized valve to close should ideally be based on a double-interlock type detector configuration. For example, requiring both a smoke detector and a heat detector to both activate prior to commanding the fire-alarm-interlocked motorized valve to close (similar to a pre-action system). In some jurisdictions (such as NYC), double-interlock activation may not be allowed, and only single-interlock configurations would be used in these jurisdictions.

### Description of Some Embodiments for Heating and Cooling a Compressed Air Tank

When the compressed air ride-through system initially activates, the temperature of the compressed air leaving the compressed air tank (100, 100A, 100B, 145) will initially be equal to the starting temperature of the air inside the compressed air tank (100, 100A, 100B, 145) prior to activation (the compressed air released from the compressed air tank (100, 100A, 100B, 145) will rapidly drop in temperature during the activation of the compressed air ride-through system due to expansion and other processes, but it will initially start at the temperature that was inside the compressed air tank (100, 100A, 100B, 145) prior to the activation). The temperature of the air inside the compressed air tank (100, 100A, 100B, 145) prior to activation (i.e. the air temperature inside the tank when the compressed air ride-through system is sitting dormant/in standby) will be close to the temperature of the air surrounding the compressed air tank (100, 100A, 100B, 145). If the compressed air tank (100, 100A, 100B, 145) is installed outdoors, then the air temperature around it will be the outdoor air temperature, and the air inside the compressed air tank (100, 100A, 100B, 145) will be close to the outdoor air temperature (may be slight differences due to radiative heat transfer). This means that if the compressed air ride-through system were to activate on a very hot day, say 95° F., the initial stagnation temperature of the air leaving the compressed air tank (100, 100A, 100B, 145) will be close to 95° F. (the static temperature of the flowing air will be significantly lower, but it will rise back up close to the stagnation temperature when it comes to a halt or stops due to contact with a surface). Although some drop in the stagnation temperature of the initially-released air could be achieved using a JT valve (146) via the Joule-Thomson effect, this initial temperature drop is limited by the drop in pressure. And given the likelihood that the most preferred embodiment/configuration of the compressed air ride-through system is to use a relatively low pressure inside the compressed air tank (100, 100A, 100B, 145) (i.e. approximately 200 PSIG or less), then the maximum drop in temperature solely due to Joule Thomson cooling will only be most likely less than 10° F. However, the stagnation temperature of the air released from the compressed air tank (100, 100A, 100B, 145) will drop quickly along the duration of the compressed air ride-through system activation, but the magnitude of the temperature drop will be mitigated by the heat gain from the walls and/or lining (147) of the tank and the compressed air conduit (109, 122, 124). Depending on many variables, the actual stagnation temperature drop may not be sufficient/viable under all operating scenarios. There will also be some level of cooling achieved through extraction of pressure-volume work when the released compressed air drives a pneumatic motor (150), reaction-type fan (174), an airlift pump (194), or drives a liquid directly through direct injection of compressed air into the liquid via a submerged compressed air direct injector (197), which also may or may not be sufficient/viable under all operating scenarios. On the opposite end, if the compressed air ride-through system were to activate on a very cold day, say 29° F., the initial stagnation temperature of the air leaving the tank will be close to 29° F., and although this will aid in the cooling performance of the compressed air ride-through system, such a cold temperature may cause other issues, such as condensation on downstream compressed air conduit (109, 122) or pneumatically-powered fluid movers (116, 123A, 150, 152, 162, 162A, 174, 194, 203, 205A, 205B, 211). Therefore, if the compressed air tank (100, 100A, 100B, 145) is installed outdoors, an optional means of cooling and heating the compressed air tank (100, 100A, 100B, 145) may be incorporated into the compressed air ride-through system in order to temper the air, if necessary to meet the requirements of the project (this will not be necessary in many cases). For a compressed air tank (100, 100A, 100B, 145) which is installed indoors, the compressed air tank (100, 100A, 100B, 145) will likely be held at a roughly human comfort condition (approx. 72° F.-76° F.), which would be suitable for the initial release air temperature when the compressed air ride-through system activates. However, if installed indoors, then some cooling may or may not be required after an activation of the compressed air ride-through system, when the compressed air tank (100, 100A, 100B, 145) is recharging/re-pressurizing, depending on the intercooling method, whether exhaust fans are present, and several other factors (but the potential cooling for an indoor tank would be very intermittent-likely only required once following an activation of the compressed air ride-through system, until the next activation occurs). The following is a non-exhaustive list of some possible methods which may be utilized for heating and cooling a compressed air tank (100, 100A, 100B, 145), if required/desired by the specific client or project, some of which may be combined in different configurations:
a. Utilize the portable or permanent compressor (113) and/or the relief valve (107), automatic releasing valves (101, 101A, 101B, 101C), or the isolating/modulating devices/valves (181, 181A, 181B) to achieve some or all of the heating and cooling necessary, possibly as a byproduct of maintaining a pressure setpoint inside the compressed air tank (100, 100A, 100B, 145). For example, when the air temperature around the tank drops, the pressure inside the tank will also drop slightly due to the temperature drop of the air inside the tank through conduction (with a time lag) via the ideal gas law. If the compressor (113) then energizes to bring the pressure of the tank back up to a particular pressure setpoint, it will also end up warming up the air inside the tank as well. Similarly, when the air temperature around the tank rises, the pressure inside the tank will also rise by the same mechanism. Air could then be released from the tank via the relief valve (107), automatic releasing valves (101, 101A, 101B, 101C), or the isolating/modulating devices/valves (181) to maintain the pressure setpoint, which will also have a cooling effect on the air inside the tank. The project-specific calculations would determine the magnitude of these heating and cooling effects and their energy impact.
b. Incorporate a vortex-type cooler (178) to heat and cool the tank shell along with an optional outer shell or insulating jacket (186). A vortex-type cooler (178) utilizes compressed air to split the air into a cold air stream (179) and a hot air stream (180). If heating or cooling was needed, an isolating/modulating device (181) would open, which releases some compressed air from the tank towards the vortex-type cooler (178), and either the cold end or hot end isolating/modulating device (181A, 181B) would direct the air from the cold end or hot end (179, 180) towards the tank shell, and the opposite isolating/modulating device (181A, 181B) would direct its associated airstream to atmosphere. In order to contain the cold or hot air around the compressed air tank (100, 100A, 100B, 145), an outer tank shell or insulating jacket (186) would likely be required. This could simply be the outer shell of a double wall tank or could be a layer of insulating material/jacketing which is offset from the surface of the compressed air tank (100, 100A, 100B, 145) by a short distance to create an annular space for the cold or hot air to circulate through. The cold or hot air could then leave the annular space through an opening with an optional check valve (164). If utilizing this method, the pressure in the compressed air tank (100, 100A, 100B, 145) will drop slightly by the release of air to drive the vortex-type cooler (178), which will also have a slight cooling effect on the air inside the compressed air tank (100, 100A, 100B, 145), but then the drop in pressure may require the compressor (113) to run in order to maintain the pressure setpoint in the tank, which would add heat to the air in the compressed air tank (100, 100A, 100B, 145). The project-specific calculations would determine the magnitude of these heating and cooling effects and their energy impact.
c. Utilize traditional electric-powered heaters/heat tracing (187) and coolers (188) along with an optional outer shell or insulating jacket. These devices would be similar to traditional methods of heating and cooling small enclosures, such as electric-resistive heaters, small, air-cooled DX coolers, Peltier-type coolers (utilizing the thermoelectric effect), or similar. These too would likely benefit from an outer tank shell or insulating jacket (186) to help minimize the losses when heating or cooling the compressed air tank (100, 100A, 100B, 145). Using traditional electric-powered heaters/heat tracing (187) and coolers (188) would not require the addition or release of air from the compressed air tank (100, 100A, 100B, 145) for cooling or heating purposes, and thus may offer some energy benefits and/or initial cost benefits. The project-specific calculations would determine the magnitude of these heating and cooling effects and their energy impact.
d. Utilize optional solar panels (207) to power the aforementioned heating/cooling devices and/or power other devices in the compressed air ride-through system which may not require steady, consistent power (for example, the automatic condensate drain (114)).
e. Utilize optional sky-facing radiative-cooling panels (185), which would provide some level of cooling passively without any energy consumption.

### Description of Some Embodiments for Moving a Cooling Fluid in a Principal Cooling Equipment Liquid Loop

For applications where the principal cooling equipment (123) transfers/rejects its heat to a principal cooling equipment liquid loop (156), such as chilled water, condenser water, glycol, etc., it may be beneficial to keep the flow of liquid in the principal cooling equipment liquid loop (156) moving during a utility failure or other non-standard operating condition and possibly, immediately after a utility failure or other non-standard operating condition. For example, if a chilled water system utilizes buffer tanks to provide a reservoir of cool chilled water at the supply chilled water temperature setpoint while the chillers restart following a utility failure, then keeping the chilled water flowing during the utility failure may be beneficial in some cases (although the compressed air ride-through system would reduce or eliminate this need in many cases). An optional pneumatic motor (150) and associated pneumatically driven pump (162) could be implemented on the principal cooling equipment liquid loop (156) to keep the liquid flowing for the duration of the activation of the compressed air ride-through system, along with optional manual valves (105) and check valves (164). Using the compressed air ride-through system in this manner would eliminate the constant, 24/7 energy consumption of the alternative of powering the primary electric-driven liquid pump (203) with UPS-backed power. The compressed air outlet of the pneumatic motor (150) could then be directed through a secondary compressed air conduit (160) to serve a secondary device, such as another pneumatically-powered fluid mover (116, 123A, 150, 152, 162, 162A, 174, 194, 203, 205A, 205B, 211), a pneumatic control valve (167B), a submerged compressed air direct injector (197) in a thermal storage tank (189), a pneumatically-powered agitator (198), or a pneumatically-overridden piece of principal cooling equipment (123A, 203, 203A, 203B, 204, 205, 205A).

### Description of Some Embodiments for Pneumatically-Overridden Principal Cooling Equipment

It would be possible for the manufacturer of the principal cooling equipment (123) to implement features/accessories directly into their equipment which allows a connection (170) of compressed air to the principal cooling equipment (123) to accomplish the same goal of providing a means of moving a cooling fluid during a utility failure or other non-standard operating condition. Such an arrangement would be considered a pneumatically-overridden piece of principal cooling equipment (123A). For example, the pneumatically-overridden piece of principal cooling equipment (123A) may integrate air amplifiers (116), compressed-air-to-cooling-fluid heat exchangers (163), primary-to-secondary heat exchangers (163A), pneumatic motors (150), pneumatically driven fans (152, 174), pneumatically driven pumps (162, 162A), pneumatically-driven compressors (211), and/or motors with pneumatic motor override assemblies (203, 203A, 203B, 204, 205, 205A) into the housing of the pneumatically-overridden piece of principal cooling equipment (123A). This connection (170) may offer benefits such as lower installation costs, consistent air distribution patterns, making use of residual cooling in the coils of the pneumatically-overridden piece of principal cooling equipment (123A), lower inrush for the principal cooling equipment fans, faster restart times, etc.

Similarly to the application above, the flow of air or liquid/refrigerant could also be maintained during a utility failure or other non-standard operating condition without the need for adding additional fans or pumps. This could be achieved by utilizing the existing electrically driven fans in the principal cooling equipment (123) and existing electrically driven pumps (203, 203A) and implementing an assembly which allows the fan or pump to be “overridden” and powered by a pneumatic motor (150) temporarily. The benefit of such an arrangement is that no additional pumps or fans are needed—the existing pumps and fans are utilized, and merely the power source for the pumps and fans, which is usually an electric motor (203A), is modified such that it can be overridden/de-clutched to allow a pneumatic motor (150) to temporarily drive the pump or fan. One method of implementing such an override may be using sheaves/pulleys (204) mounted on the shafts of the electric motor (203A) and the pneumatic motor (150) and belt(s) between them, along with a means of overriding the electric motor (203A). In order to override the electric motor (203A) to allow the pneumatic motor to temporarily deliver power to the pump or fan, a pneumatic belt-tensioner/clutch (205) can be implemented, which utilizes a pneumatic actuator to tighten the belt(s) when it receives air pressure during an activation of the compressed air ride-through system. This would allow the belt to remain loose under normal operation (thus not imposing any extra resistance under normal conditions), and only tighten upon an activation of the compressed air system.

A similar function would be achieved by utilizing dual-shafted electric motors (203B) with “double-sided” or “pass-through” type shafts and connecting the pneumatic motor (150) along with a clutching mechanism (205A) to the opposite side of the shaft. The general arrangement of utilizing the existing pumps and fans and overriding them with a pneumatic motor (150) can be enhanced by also implementing a means of temporarily de-clutching the electric motor (203A, 203B) from the fan or pump when the pneumatic motor assumes control-without this, the pneumatic motor will have to deliver enough power/torque to drive the pump/fan and drive an unenergized electric motor (203A, 203B) simultaneously (this will increase the necessary size of the pneumatic motor and increase the air consumption). By de-clutching the electric motor (203A, 203B) temporarily, the pneumatic motor would only have to drive the pump or fan. If the electric motor (203A, 203B) is left engaged while the pneumatic motor (150) drives the pump or fan, there may be electrical issues caused from inducing a current in the motor windings. Also note that this method of overriding an electric motor (203A, 203B) to drive a pump or fan with a pneumatic motor (150) requires that the shaft driving the pump or motor be exposed.

### Description of Some Embodiments for Re-Warming Components after an Activation of the Backup System

In some situations, it may be beneficial to incorporate a means of warming up the various components in the compressed air ride-through system after an activation of the backup system. This could be accomplished in a number of ways, such as utilizing a motorized or solenoid valve (171) and fan (172) which are tied into the compressed air conduit header (109). For example, if the surface temperature of the compressed air conduit (109, 122, 124) and the various pneumatically-powered fluid mover(s) (116, 123A, 150, 152, 162, 162A, 174, 194, 203, 205A, 205B, 211) were expected to drop to a temperature below the dewpoint of the surrounding air around each component through the course of an activation of the compressed air ride-through system, then the valve (171) could open and the fan (172) could start, which would allow warm air to be distributed through the compressed air ride-through system to prevent the dewpoint temperature from being reached on the surfaces of the various components. The warmer air from the fan (172) could be directed into the compressed air conduit (109, 122, 124) which the compressed air passes through, or could be directed down the annular space of double wall compressed air conduit (109, 122, 124). Other means of condensation control could be implemented as well, such as drip pans, insulation, a means of re-heating the released compressed air, mixing devices, or similar.

### Description of Some Embodiments for Moving Liquid and Refrigerant Cooling Fluids and Using the Released Compressed Air as a Heat Sink

Note that there are several previous references to liquid-cooled ITE applications in the description above. The items below further describe the liquid-cooling applications of the compressed air ride-through system.

In addition to providing cooling and airflow to traditional air-cooled ITE (125), the compressed air ride-through system can also move liquid and refrigerant cooling fluids as well to serve liquid-cooled ITE (154) and to serve principal cooling equipment (123, 123A) which is served by a liquid/refrigerant in a similar manner. And the pneumatically-powered fluid mover(s) for moving liquid and refrigerant cooling fluids can be incorporated into the same system as pneumatically-powered fluid mover(s) for air-cooled ITE (125), which makes the compressed air ride-through system quite flexible. For example, the compressed air ride-through system may be installed at a location and initially only air amplifiers (116) are connected to serve only air-cooled ITE. Then, later on, liquid and/or refrigerant pneumatically-powered fluid movers (123A, 150, 162, 162A, 194, 203, 205A, 205B, 211) can be added to the exact same system if needed.

Note that there exists a somewhat “transitional” arrangement for ITE which makes use of both air-cooling and liquid cooling: a “sidecar” arrangement (157), which is a liquid-cooled ITE rack with a “sidecar” air-cooled rack adjacent to it, with piping between the liquid-cooled and “sidecar” racks (157A). This arrangement/equipment is offered by some manufacturers as a low-initial-cost way to be able to integrate a liquid-cooled ITE rack into an existing data center with only air-cooling available (also note that this arrangement loses some of the benefits of cooling efficiency when compared to pure liquid-cooled ITE). The compressed air ride-through system would provide cooling and airflow to this kind of “sidecar” arrangement (157) with the air-cooling methods described above (i.e. using air amplifiers (116) or pneumatically driven fans (150, 152, 174)). For liquid-cooled ITE without an air-cooled “sidecar” arrangement, other cooling methods are described herein.

For airside cooling and airflow, an air amplifier (116) is one type of pneumatically-powered fluid mover which may be used. These types of devices could be categorized as Coanda-type air amplifiers, venturi blowers, air-operated in-line conveyors, air knives, air ejectors, and entraining air nozzles, or similar.

To move liquid or refrigerant cooling fluids serving liquid-cooled ITE (154) or serving principal cooling equipment (123, 123A), the following is a non-exhaustive list of pneumatically-powered fluid mover(s) which may be used:
a. A pneumatically-driven pump, comprising a pneumatic motor (150) connected to a pump (162),
b. An airlift pump (194) or other type pf submersible pneumatic pump,
c. An air-operated diaphragm pump (162A),
d. A pneumatically-driven refrigerant compressor, comprising a pneumatic motor (150) connected to a refrigerant compressor (211), or
e. A piece of pneumatically-overridden principal cooling equipment (123A), such as a normally-electric-driven pump (203A, 203) with a belt sheave (204) and a belt tensioner (205) connected to a pneumatic motor (150) with a belt sheave (204), or a normally-electric-driven pump (203) with a dual-shafted electric motor (203B) and a clutching mechanism (205A) and a pneumatic motor (150) connected to the opposite end of the shaft.

Other devices, described below, would also aid in the proper implementation of liquid-cooling applications. Again, these may be implemented into the same system as the air-cooling devices described previously.

A compressed-air-to-cooling-fluid heat exchanger (163) would utilize the cold temperature of the released compressed air to extract (i.e. absorb) heat from the piping loop serving the liquid-cooled ITE. The cold temperature of the released compressed air would be achieved in several ways: by expansion of the air leaving the compressed air tank (100, 100A, 100B, 145), by naturally dropping in temperature when flowing through the heat exchanger at high speed via conversion of internal energy to kinetic energy (i.e. the air will drop in temperature down to the “static” conditions when moving through a pipe vs the higher stagnation temperature inside the compressed air tank (100, 100A, 100B, 145)), by Joule-Thomson cooling, and under certain conditions by a simple difference in temperature between the air temperature surrounding the compressed air tank (100, 100A, 100B, 145) and the temperature of the liquid/refrigerant in the piping loop.

The type of compressed-air-to-cooling-fluid heat exchanger (163) may vary from project to project, depending on the specific needs of each client. In some cases, a shell-and-tube heat exchanger may work best, whereas a plate-and-frame or brazed-plate or other heat exchanger type might work best for others. For a shell-and-tube arrangement, it most likely would make sense to pass the compressed air through the tubes and pass the liquid/refrigerant through the shell, although this could be reversed in some cases.

The temperature of the liquid/refrigerant leaving the compressed-air-to-cooling-fluid heat exchanger (163) would likely have to be controlled to narrow range of acceptable temperatures, which can be accomplished in several ways. An optional temperature sensor (165) may be implemented on the discharge of the compressed-air-to-cooling-fluid heat exchanger (163) or on the mains of a technology cooling system (TCS) loop (161), which serves the liquid-cooled ITE. An optional regulating valve (106) may be implemented to control the flow, pressure, or temperature of the compressed air passing through the compressed-air-to-cooling-fluid heat exchanger and/or control the flow, pressure, or temperature of the compressed air passing through passing through the pneumatic motor (150). The exact combination and arrangement of sensors and controlled devices would likely be project-specific to meet the needs of each client/system.

In many cases, the compressed air leaving the compressed-air-to-cooling-fluid heat exchanger (163) and the compressed air leaving the pneumatic motor (150) may still have enough pressure and still be cool enough to then be discharged into the data center and/or be connected to air amplifiers (116) or to other pneumatic motors (150) serving fans or to reaction-type fans (174). Depending on the specific characteristics of the pneumatic motor (150), the extraction of pressure-volume work from the compressed air will likely result in a lower exit temperature than the inlet temperature, provided that the heat gain from the walls of the motor (the mass of the motor walls and internal components will likely initially be at the temperature of the surrounding air when the compressed air ride-through system activates) and the heat from friction does not exceed the cooling effect (i.e. the drop in stagnation temperature due to the drop in enthalpy).

The compressed air conduit (109, 122, 124) serving the compressed-air-to-cooling-fluid heat exchanger (163) and the pneumatic motor (150) driving the pump (162) may be arranged in several ways, depending on several factors. In some cases, it may make the most sense to pipe the compressed air initially into the compressed-air-to-cooling-fluid heat exchanger (163), then take the outlet air and direct it through a secondary compressed air conduit (160) to the pneumatic motor (150), such that the two devices are piped in series. In other cases, they may still be piped in series, but with the pneumatic motor (150) first, then its outlet air passing through a secondary compressed air conduit (160) to the compressed-air-to-cooling-fluid heat exchanger (163) second. In other cases, it may make sense to pipe both devices in parallel instead of in series.

The facility may already have an existing pump serving the TCS piping (161) (i.e. the piping serving the liquid-cooled ITE). This existing pump may already be served with UPS power (or the manufacturer may recommend serving this pump with UPS power) because, as described previously, liquid-cooled ITE may reach failure temperatures due to a loss of liquid flow in a matter of seconds (i.e. quicker than the generators would be able to start in many cases). In such a circumstance, if a facility is implementing the compressed air ride-through system, they may choose one of the options or a combination thereof from the following non-exhaustive list (there are other viable options which are not specifically mentioned in this list as well):
a. Utilize the normal-operation UPS-powered pump to provide liquid flow during a utility failure (which has the detriment of consuming an amount of energy 24/7 simply to keep the UPS batteries charged or keep the UPS flywheel spinning). In such a case, the facility may choose to omit the pneumatic motor (150) and pneumatically driven pump (162) from the compressed air ride-through system, and only utilize the compressed-air-to-cooling-fluid heat exchanger (163). In some cases, it may be beneficial to utilize both the normal-operation UPS-powered pump and the pneumatic motor (150) and pneumatically driven pump (162) together.
b. Omit the UPS connection from the normal-operation pump (i.e. power the normal-operation pump with utility power and generator power, but not UPS power), and utilize the pneumatic motor (150) and pneumatically driven pump (162) from the compressed air ride-through system to maintain liquid flow during a utility failure or other non-standard operating condition. The compressed-air-to-cooling-fluid heat exchanger (163) would be present in both cases.
c. Implement a pneumatically-overridden pump configuration (150, 203, 203A, 203B, 204, 205, 205A).
d. Implement a thermal storage tank (189).

The compressed-air-to-cooling-fluid heat exchanger (163) and pneumatic motor (150) and pneumatically driven pump (162) could optionally be housed within an enclosure (168). These devices would then most likely be piped in parallel with the return main of the TCS loop (161). It would likely be advantageous to allow the liquid/refrigerant to pass through the pump (162) and heat exchanger (163) continually (as opposed to using an actuated valve to allow flow through these devices only when activated). By allowing liquid/refrigerant flow through these devices continually, this has the following benefits:
a. Not reliant on an actuated valve to open.
b. These devices would be continually flushed with the liquid/refrigerant, so that there would be no sudden release of particulate/debris when activated (any particulate would be continually flushed away).
c. Aids in rejecting heat from the TCS loop (161) since these devices would be piped on the return side of the TCS loop (161) (depending on where the devices are located, the small heat rejection offset may simply be transferred to a different system, such as the CRAH's).
d. Offers a small reservoir to increase cycle time of the TCS loop (161) (it would not act the same as a buffer tank since it's on the return side, not the supply side).
e. Keeps air bubbles out of the devices and the piping (i.e. constantly flooded).
f. No real extra pressure drop on the TCS loop (161) except for the check valve. Having a parallel path actually will most likely result in an overall reduction in pressure drop, since there is a second path for the liquid/refrigerant to take before returning to the main.

The compressed-air-to-cooling-fluid heat exchanger (163) may or may not be insulated (147A) for various reasons, such as condensation concerns, better heat transfer, partial heat rejection during normal operation, etc. Other components, such as the pneumatically driven pump (162) may or may not also be insulated.

Various valves may also be required in the TCS loop (161) for successful operation, depending on numerous factors. For example, if a more centralized cooling distribution unit (CDU) (155) is used as the principal, 24/7 means of liquid/refrigerant cooling, it may or may not be necessary to implement a motorized 2-way control valve (167), a motorized 3-way control valve (167A), a pneumatic control valve (167B), and/or a check valve (164) to bypass the CDU (155) while the compressed air ride-through system is active. For example, this may be necessary if the CDU (155) had an internal fail-closed valve, or if the internal liquid/refrigerant loop pump was not provided with UPS-backed power. Furthermore, the configuration and operation of the principal cooling equipment liquid loop (156) connected to the CDU (155) may also influence whether or not control valves (167, 167A, 167B) and check valves (164) would be necessary to bypass the CDU (155).

The compressed air conduit (109, 122) may also connect directly to a CDU (155) to override internal components, such as fans, pumps, and compressors, such that it becomes a pneumatically-overridden piece of principal cooling equipment.

For a more de-centralized configuration of CDUs, such as in-rack CDUs (169), the same statements above are true, and control valves (167, 167A, 167B) and check valves (164) may be necessary for successful operation of the compressed air ride-through system with in-rack CDUs (169) as well.

Other devices which may be necessary or desirable for the liquid-cooling application may include strainers (166), isolation valves (105), air filters (131), air dryers (132), and various controls and sensors possibly managed by an optional controller (104).

### Description of Some Embodiments for Moving Liquid and Refrigerant Cooling Fluids and Using Other Mediums as a Heat Sink

The embodiments above describe, in part, some various methods/embodiments for achieving short-term movement of a liquid/refrigerant cooling fluid and short-term cooling for liquid-cooled ITE by using a compressed-air-to-cooling-fluid heat exchanger (163). However, the ability to transfer heat from water (or other liquids) to compressed air is somewhat limited due to the relative low density and, to a lesser degree, low specific heat of air. The low density of air, even at a pressure of 200 PSIG and a low temperature of −100° F., is only approximately 1.67 pound-mass per cubic foot, which is about 37 times smaller than the density of water (and about 817 times smaller than water when comparing air at standard temperature and pressure). This means that, in relative terms, an extremely large volume flowrate of compressed air (i.e. in order to achieve a comparable mass flow rate) would be needed to cool down a given flowrate of water. The compressed air would first need to cool down the mass of the heat exchanger interface walls before then cooling down the liquid/refrigerant on the other side of the heat exchanger. The seemingly ineffectiveness of compressed air to act as a heat sink for water (or other similar liquids) is somewhat offset by compressed air's inherent ability to undergo a severe temperature drop during rapid expansion, and if directly injected into water, its ability to cool the water through evaporation (both of which would enhance the heat transfer between the air and the water). However, despite those abilities, using compressed air as a heat sink for water or for the liquid/refrigerant in a liquid-cooled ITE application will still likely be deemed impractical/unfeasible on several projects (but not all) when the project-specific calculations are conducted. In those cases, a different form of heat exchanger may be used instead, such as a primary-to-secondary heat exchanger (163A) or an immersed coil/heat exchanger (191) inside a thermal storage tank (189), and the compressed air would serve a different purpose than absorbing heat from the liquid/refrigerant through a compressed-air-to-cooling-fluid heat exchanger (163). Therefore, the following items are a non-exhaustive list of some other possible methods/embodiments for achieving short-term movement of a liquid/refrigerant cooling fluid and/or cooling of liquid-cooled ITE with the compressed air ride-through system (many of the features and methods below can be arranged in different combinations to suit the needs of the project).

As an alternative to using the released compressed air as the heat sink for the TCS loop (161), the following thermal storage media may be used as a heat sink instead: water, glycol, a phase-change material (PCM), outdoor air, ambient air in a cold aisle/flooded room, or soil.

Using water as the thermal storage media (i.e. as the thermal storage liquid) for TCS loops (161) serving liquid-cooled ITE (154) is likely the most viable option for most applications, except in configurations where the water would be stored outdoors or underground in climates where a risk of freezing could occur. In these cases, glycol may be used as the thermal storage liquid instead to prevent freezing (the term “glycol” meaning a mix of water and propylene or ethylene glycol, not necessarily pure glycol), but at the detriment of a reduced heat transfer coefficient compared to pure water. The glycol mix percentage would have to be determined based on the worst-case, winter design conditions for the specific site and application.

Using a phase-change material (PCM) as the thermal storage media would primarily offer the benefit of remaining solid under normal conditions, which may assuage the concerns of data center operators who prohibit water inside the confines of their data centers. The PCM would ideally be capable of having its melting point be adjusted chemically for different applications to ensure that the melting point of the PCM falls between the highest expected storage temperature and the lowest expected return temperature of the TCS loop (161) (i.e. these temperatures can vary from site to site, so the PCM's melting point would ideally be able to be tweaked in order to fall between these values). A PCM would absorb heat via its latent heat of fusion (as opposed to simple sensible heat transfer), however, a large surface area would be required for the coil/interface (191) since the volume of PCM in between the gap between the walls of the coil/interface (191) would rely on conduction through the PCM to transfer the heat through the PCM (the conduction through PCM's tends be relatively low). This can be mitigated to a degree by using micro-encapsulation of the PCM and suspending it within a liquid, such as water, or by embedding conductive materials, such as copper mesh, within the PCM. However, the added cost of such measures to enhance the practical heat transfer capability of PCM's would likely be more expensive than simply using water alone and adding secondary and tertiary containment walls for leak prevention. But again, the use of a PCM is likely only warranted in the cases where the data center operators strictly prohibit water within the confines of the data center, even with tertiary containment. Also note that certain PCM's may have a corrosive nature, which may buttress the desire for macro- or micro-encapsulation.

If using water, glycol, or a PCM as the thermal storage media for a TCS loop (161), they must either be stored in a location which is maintained at a temperature at least lower than the TCS loop (161) return temperature, or a method of immediately cooling these mediums must be incorporated. This is the primary difference between using compressed air as the heat sink for a TCS loop (161) vs using water, glycol, or a PCM—the compressed air will inherently drop in temperature upon activation of the compressed air ride-through system, thus providing the necessary temperature difference to act as a heat sink (meaning that it can be held/stored at room temperature or relatively high temperatures), whereas water, glycol, or a PCM must be held at a relatively low temperature constantly or a means of immediately cooling it down must be incorporated. However, just like compressed air, the water, glycol, or PCM would not be generating any heat under normal, non-emergency conditions, so it would not consume any further cooling energy by itself once its temperature was dropped to (and held) at the low target temperature (heat gains from the enclosure, tank, or walls surrounding the water, glycol, or PCM may require periodic energy consumption, but not due to the water, glycol, or PCM itself).

There are usually three (3) locations at a data center facility where the temperatures are maintained at relatively low levels (i.e. lower than the return temperature of the TCS loop (161)): a) inside of the data center (134), b) inside of a different air-conditioned room within the data center building (135B), or c) underground (183).

If the thermal storage tank (189) containing the water, glycol, or PCM is installed inside the data center (134), then only a one-time energy consumption is needed to cool down the water, glycol, or PCM following each activation of the compressed air ride-through system. This one-time energy consumption will be imposed on the principal cooling equipment (such as CRACs/CRAHs) (123), but once the water, glycol, or PCM reaches the temperature of the surrounding cool air in the data center (134), it will simply remain at that temperature with no further energy consumption until an activation of the compressed air ride-through system (similar to a column, wall, cabinet, or other solid object inside the data center—these objects are held at a constant temperature with no energy consumption simply due to their location within the data center). One hurdle to this type of implementation is that some data center operators have an aversion to allowing any water inside the data center (although many data centers have eased this aversion with the adoption of chilled water principal cooling equipment). To mitigate this concern, the thermal storage tank (189) can be fitted with a secondary containment shell/wall (182) or an optional tertiary containment basin or shell to minimize the risk of a leak. Leak detectors and periodic testing/inspections would also minimize this risk. By keeping the thermal storage tank (189) inside the data center, this also will likely minimize the piping length/cost to connect the TCS loop (161) to the thermal storage tank (189) and/or to the primary-to-secondary heat exchanger (163A). This location also minimizes the length of compressed air conduit (109, 122, 124) running from the outlets of the pneumatic motors (150) to the cold aisles (126). Also note, if water is used as the thermal storage media inside a thermal storage tank (189), only a relatively small volume/footprint is needed. For example, to cool one (1) MW of heat from liquid-cooled ITE (154) operating at a 10° F. delta-T, a water flowrate of 275 gallons per minute is required, and thus for 60 seconds of ride-through time, a tank volume of only approximately 275 gallons is needed (this is a nominal value, and a larger or smaller volume may be required due to heat exchanger inefficiencies, the various heat transfer coefficients, and the ability for the TCS loop (161) to tolerate a temporary increase in the delta-T). For a 275 gallon tank which is 65″ tall, the footprint could be as small as 6.78 sq ft, or 32″×32″, which is around the size of a single IT cabinet. Also note that unlike using air as the heat sink, the walls of the coil/heat exchanger (163A) in this type of arrangement will already be at the low temperature of the water, glycol, or PCM, and thus no time is wasted in cooling down the mass of the interface walls before cooling down the TCS loop (161). Provided that the data center operators are comfortable with the storage of water, glycol, or a PCM within the data center (again, possibly mitigated by secondary or even tertiary containment), then this location would likely be the most cost-effective option. It also has the benefit of keeping all the TCS piping (161) within the confines of the data center (134), where the security level is high.

Similar to the item above, if the thermal storage tank (189) containing the water, glycol, or PCM is installed indoors in a different room (135B) other than the data center (134), then any concerns about a leak from the thermal storage tank (189) or concerns about real estate within the data center (134) would likely be mitigated. The room (135B) would need to have a source of cool air for the one-time cooling of the thermal storage tank (189) immediately following an activation of the compressed air ride-through system. This could be achieved with a typical dedicated or non-dedicated air conditioner (if non-dedicated, the air conditioner may serve occupied support spaces/offices in the vicinity). For example, a small unused office could be used to house the thermal storage tank (189), or if the space (135B) is adjacent to a data center space (134), cool air from the data center could be ducted to it. One potential concern with this option is that the liquid/refrigerant piping would need to leave the confines of the data center to reach the thermal storage tank (189), which may pose security and reliability concerns, unless this other room (135B) had a security level similar to the data center space (134).

If installed underground (183), the underground thermal storage tank (189A) containing the water, glycol, or PCM will likely be held at a somewhat steady temperature, depending on the local climate, soil conditions, depth, soil moisture content, surface conditions, etc. But generally, at a depth of even less than 10 ft in many cases, the soil temperature can be considered relatively steady year-round, and is often cooler than the outdoor air. Provided that the maximum soil temperature at the buried depth of the underground thermal storage tank (189A) is cooler than the TCS loop (161) return temperature, then burying the underground thermal storage tank (189A) is a viable option for maintaining the water, glycol, or PCM at a steady low temperature. Although burying the underground thermal storage tank (189) may be more expensive than using a thermal storage tank (189) in the data center (134) or other indoor space, it has the benefit of not using any indoor real estate, and any potential leak from the tank would not damage any indoor equipment. It also allows for a much larger, more centralized tank to be used, if desired (as opposed to multiple smaller tanks installed indoors), which may prove to be more cost effective for a larger data center facility. The underground thermal storage tank (189A) may even be built directly below the slab of the data center facility (with appropriate access hatches) so that no additional land space is utilized outdoors, which would potentially allow the TCS piping (161) to connect to the underground thermal storage tank (189A) within the confines of the data center (134), provided that a structural analysis is performed (however, this would likely be more costly is most cases than simply utilizing the land around a data center facility, when available). Or the underground thermal storage tank (189A) could be built below a parking lot if desired. Repairs and replacement for an underground thermal storage tank (189A) would likely be more expensive than the indoor thermal storage tank (189) option. Any associated equipment, such as pumps (162), heat exchangers (163A), etc. could be placed in an enclosure directly above the underground thermal storage tank (189A), however, this may require heating and/or cooling of the enclosure. And depending on the depth of the underground thermal storage tank (189A), there may be a risk of losing prime in the pump if an open-type loop is used within the buried tank (unless a submersible-type pump is utilized), which would be mitigated by the presence of foot valves (164A) or check valves (164).

In some cases, it may be more cost-effective to omit an underground thermal storage tank (189A) and use a direct-burial coil/pipe (192), similar to ground-source heat rejection loops, such that the thermal storage media (water or glycol in this case) absorbs heat from the TCS loop (161) through a primary-to-secondary heat exchanger (163A) and then rejects the heat directly to the soil (183). It is likely that the benefit of using a direct-burial coil/pipe (192) would be maximized when a vertical arrangement is used for the coil/pipe (192), which minimizes the land area used (as opposed to a horizontal arrangement, which would potentially require a much larger land area, albeit at a shallower depth).

The piping for transferring the heat from the TCS loop (161) to the thermal storage media can be arranged as a primary-only arrangement, comprised of a primary loop (161A), or a primary-secondary arrangement, comprised of a primary loop (161A) and a secondary loop (161B).

A primary loop (161A) in a primary-only arrangement would be arranged such that the TCS loop (161) extends into the thermal storage tank (189) containing the thermal storage media. Control valves (167, 167A, 167B) can be used to isolate the TCS loop (161) from the thermal storage tank (189) and thermal storage media under normal operation, and then the control valve (167, 167A, 167B) would open upon an activation of the compressed air ride-through system, allowing the liquid/refrigerant cooling fluid in the TCS loop (161) to pass through the immersed coil/heat exchanger (191) inside of the thermal storage tank (189). Depending on the arrangement of the overall system, additional control valves (167, 167A, 167B) and check valves (164) may be required to properly direct the liquid/refrigerant cooling fluid through the immersed coil (191) and thermal storage tank (189) temporarily for the duration of the compressed air ride-through system activation. Additionally, a means of maintaining flow of the liquid/refrigerant cooling fluid in the TCS loop (161) during the compressed air ride-through system activation may be required, and thus a pneumatic motor (150) and associated pump (162) may be incorporated into the same enclosure (168) as the thermal storage tank (189). A primary-only arrangement would be simpler and cheaper than a primary-secondary arrangement, but it also carries a potentially increased risk of a leak on primary loop (161A), which could affect the TCS loop (161), due to the submergence of the immersed coil/heat exchanger (191) in the thermal storage tank (189). In other words, the primary loop (161A) and the immersed coil/heat exchanger (191) are both a direct extension of the TCS loop (161) in the primary-only arrangement, and thus a leak in the immersed coil/heat exchanger (191) would lead to a leak in the TCS loop (161), although such a leak may not be identified until the control valve (167, 167A, 167B) opens, either during periodic testing or during an actual activation of the compressed air ride-through system. This risk could be mitigated several ways:
a. Performing pressure testing on the immersed coil/heat exchanger (191) and primary loop (161A) initially during installation (and possibly periodically as well if desired).
b. Using an increased wall thickness on the immersed coil/heat exchanger (191).
c. Periodically opening the control valve (167, 167A, 167B) (either manually or automatically on a schedule) for a brief period (1-2 seconds most likely) and using sensors to determine if a leak is present. For example, a pressure sensor or a level sensor in the thermal storage tank (189) would register a spike in pressure or an increase in the liquid level if a leak were present, otherwise if the immersed coil/heat exchanger (191) were intact, no change would be registered, and thus no alarm generated. By only opening the control valve (167, 167A, 167B) for a couple seconds, only a small amount of liquid/refrigerant cooling fluid in the TCS loop (161) would be lost if a leak were actually present (and none would be lost if there were no leaks), which would be tolerable by most, if not all, systems. By performing this check periodically (for example, once a month), this would help minimize the chance that a leak is discovered in the immersed coil/heat exchanger (191) during an activation of the compressed air ride-through system, which is when the TCS loop (161) would be open to the immersed coil/heat exchanger (191) for an extended period (i.e. finding a leak early during a periodic check means that it can be fixed under controlled conditions).

In a primary-only arrangement where the thermal storage media inside the thermal storage tank (189) is a liquid, such as water or glycol (i.e. a thermal storage liquid), it may be beneficial to incorporate a means of agitating/circulating (198, 197) the thermal storage liquid within the thermal storage tank (189) for better heat transfer to the immersed coil/heat exchanger (191). Without a means of agitation/circulation (198, 197), there will still be some level of natural convection within the thermal storage tank (189), but the total heat transfer between the TCS loop (161) and the thermal storage liquid will be limited by the natural convection heat transfer coefficient. By incorporating a means of agitation/circulation (198, 197) within the thermal storage tank (189), the convection coefficient will be closer to the values for forced convection, and thus higher (ultimately meaning less surface area required for the same total heat transfer). Agitation/circulation within the thermal storage tank (189) may be achieved through the use of a pneumatic motor (150) connected to a pneumatically-powered agitator (198). The pneumatically-powered agitator (198) may be in the form of a propeller, wheel, paddle, screw, etc. Similar to other pneumatic motors (150) described herein, the compressed air outlet of the pneumatic motor (150) driving the pneumatically-powered agitator (198) could be directed to other pneumatically-powered fluid movers (116, 123A, 150, 152, 162, 162A, 174, 194, 203, 205A, 205B, 211), such as air amplifiers (116). Another means of agitation/circulation may be a submerged compressed air direct injector (197) in the thermal storage tank (189), which may have an added cooling effect via both sensible heat transfer and latent vaporization of the water (i.e. the water would lose additional heat by vaporizing in the presence of air which is below 100% relative humidity). However, the magnitude of the additional cooling effect from a submerged compressed air direct injector (197) will likely be small, and the presence of air bubbles within the thermal storage tank (189) would reduce the effective heat transfer area of the immersed coil/heat exchanger (191). The overall heat transfer of the immersed coil/heat exchanger (191) would nonetheless be enhanced with a submerged compressed air direct injector (197), but the project-specific calculations would indicate whether a pneumatically-powered agitator (198) or a submerged compressed air direct injector (197) makes more sense for each project. Note that by using a submerged compressed air direct injector (197), the thermal storage tank (189) would likely have to carry a higher pressure rating, a means of venting (195) the humid air out of the tank would be needed, and an automatic air vent (196) would likely be needed to allow air out of the tank, but not water. Because of these extra considerations for a submerged compressed air direct injector (197) and the likely meager increase in cooling, using a pneumatically-powered agitator (198) would likely be the preferred option for most projects using a primary-only arrangement.

A primary-secondary arrangement would be arranged such that the TCS loop (161) extends to a primary-to-secondary heat exchanger (163A) via a primary loop (161A), where it transfers heat to a secondary loop (161B) which extends into the thermal storage tank (189). In this manner, the TCS loop (161) is hydraulically separated from the tank and thus no portion of the TCS loop (161) or the primary loop (161A) is submerged in the thermal storage tank (189) nor submerged in the thermal storage media. This arrangement may be more amenable to data center operators who are concerned with jeopardizing the integrity of the TCS loop (161). Note that using a primary-secondary arrangement does not totally eliminate the risk of a leak in the TCS loop (161), but the risk is closer to the “baseline” risk inherent in the TCS loop (161) (i.e. the “baseline” risk being the risk of a leak that already exists inherently in the existing piping, fittings, heat exchangers, devices present on the TCS loop (161), without any added risk from components comprising the compressed air ride-through system).

A primary-secondary arrangement also allows additional options to be considered, such as an open-type secondary loop (161B) passing through the thermal storage tank (189). For example, instead of using an immersed coil/heat exchanger (191) within the thermal storage tank (189), the thermal storage media in the thermal storage tank (189) may be a secondary cooling liquid which is pumped out of the thermal storage tank (189) and through the primary-to-secondary heat exchanger (163A), and then back to the thermal storage tank (189). Doing this eliminates the need for agitation/circulation (198, 197). The pump in the secondary loop (161B) could take the form of a pneumatic motor (150) and pneumatically driven pump (162), an airlift pump (194), an air-operated diaphragm pump (162A), a pneumatically-powered submersible pump, or similar. If the pump (162, 194, 162A) serving the secondary loop (161B) were installed outside of the thermal storage tank (189), foot valves (164A) and/or check valves (164) could be used to maintain prime in the suction line feeding the pump (162, 194, 162A). Alternatively, a pneumatically-powered submersible pump could be used and placed directly inside the thermal storage tank (189), although this would make maintenance difficult. An optional baffle (190) could be implemented into the thermal storage tank (189) to separate the warm return stream from the secondary cooling liquid in the remainder of the thermal storage tank (189). If the secondary loop (161B) is implemented as a closed-type secondary loop (161B) with an immersed coil/heat exchanger (191), then an expansion tank (193) would likely be required to prevent over-pressurization of the closed-type secondary loop (161B) due to thermal expansion. However, using a closed-type secondary loop (161B) and an immersed coil/heat exchanger (191) will likely not be cost effective, since the heat from the TCS loop (161) would have to be rejected through two subsequent heat exchangers (163A and 191), and a means of agitation (198, 197) would still likely be desired in such a case.

An airlift pump (194) may be used in a primary-secondary arrangement to achieve the pumping of the secondary cooling liquid in the open-type secondary loop (161B), as well as agitation and cooling, all with no moving parts. An airlift pump (194) injects air under the surface of the secondary cooling liquid, and the presence of the air bubbles in the vertical supply riser of the open-type secondary loop (161B) reduces the overall density of the column of secondary cooling liquid in the vertical supply riser of the open-type secondary loop (161B), which causes the rest of the secondary cooling liquid in the thermal storage tank (189) to push the lower-density air-bubble-and-liquid mixture upwards. Several airlift pumps (194) may be arranged in parallel or in series to achieve the desired pumping performance and lift performance. The benefits and detriments of using an airlift pump (194) on the secondary loop (161B) of a primary-secondary arrangement are as follows:
a. Airlift pumps (194) have no moving parts and are likely less expensive and require less (or no) maintenance compared to a pneumatic motor (150) and pump (162) or an air-operated diaphragm pump (162A) of equivalent performance.
b. Airlift pumps (194) require only a slight air pressure to operate (only slightly higher than the hydrostatic head pressure of the secondary cooling liquid in the thermal storage tank (189) at the depth of the airlift pump (194)). This means that an airlift pump (194) can most likely use the compressed air which has exited a pneumatic motor (150) through a secondary compressed air conduit (160). In such a case, the air exiting a pneumatic motor (150) and entering the airlift pump (194) via a secondary compressed air conduit (160) would be considerably colder than the stagnation temperature of the compressed air upstream of the pneumatic motor (150), and thus additional cooling of the secondary cooling liquid through direct injection via the airlift pump (194) in the thermal storage tank (189) can be achieved. This also would reduce the length of compressed air conduit (109, 122, 124), since the run from a pneumatic motor (150) to the airlift pump (194) would likely be shorter than a run all the way from the compressed air tank (100).
c. There is an additional cooling effect achieved with airlift pumps (194) due to direct mixing of the compressed air with the secondary cooling liquid, and due to the latent heat of vaporization. This cooling effect may be relatively minor (see previous description of the limiting factors for cooling a liquid with the direct injection of air), so it would still likely be necessary to store the thermal storage tank (189) in a constantly-maintained cool area. The cooling effect is further complicated by the fact that air bubbles would likely contact the primary-to-secondary heat exchanger (163A) and displace an equivalent volume of the secondary cooling liquid. The bubble contact with the primary-to-secondary heat exchanger (163A) can be reduced by arranging the primary-to-secondary heat exchanger (163A) external to the thermal storage tank (189) and after a vent (195) and automatic air vent (196). Even if relatively minor, this cooling effect may still help to increase the ride-through time for the same given volume of secondary cooling liquid (or alternatively, allow the reduction in the thermal storage tank (189) volume for the same given ride-through time).
d. The performance of airlift pumps (194) is highly dependent on the submergence ratio, which is driven by the dimensions and arrangement of the thermal storage tank (189) and associated piping/valving.
e. The outlet pressure/lift of airlift pumps (194) is limited, such that the secondary cooling liquid could only be pumped to a height above the liquid level in the thermal storage tank (189) equal to (at the most) the difference between the liquid level in the thermal storage tank (189) and the depth of the airlift pump (194). For example, if the thermal storage tank (189) was six feet tall, and the level of the secondary cooling liquid inside the thermal storage tank (189) was 5.5 feet, and the centerline of the airlift pump (194) was installed at a depth of 0.5 feet above the bottom of the thermal storage tank (189) (i.e. five feet below the liquid level), then the airlift pump (194) would not be able to pump the liquid any higher than 10.5 feet (i.e. five feet above the liquid level), and even less in reality. And the pumping performance drops significantly as the required lift approaches this limit. For this reason, the primary-to-secondary heat exchanger (163A) would have to be placed at a height either immediately above or below the secondary cooling liquid level inside the thermal storage tank (189). To avoid losing the benefit of a reduced risk of a leak in the TCS loop (161) with a primary-secondary loop (161B) arrangement, placing the primary-to-secondary heat exchanger (163A) below the secondary cooling liquid level to maximize performance of the airlift pump (194) would have to be done external to the thermal storage tank (189) (such as to the side of the tank), and a means of preventing the primary-to-secondary heat exchanger (163A) from being submerged or filled with the secondary cooling liquid under normal conditions would have to be implemented, such as check valves (164) or control valves (167, 167A, 167B).
f. During an activation of the compressed air ride-through system, the airlift pump (194) would discharge compressed air into the secondary cooling liquid in the thermal storage tank (189), and if installed within an enclosure (168), the air would then need a pathway to escape the enclosure (168) after it has performed the task of pumping the secondary cooling liquid via the airlift pump (194). This air will tend to be quite humid, and thus discharging this air directly into a data center (134) may not be desirable. So the enclosure (168) may be fitted with vents (202) which allow the air to escape, and ductwork and fans may be connected to these vents (202) to direct the humid air to more desirable locations, such as into an adjacent corridor outside of the data center, to the outdoors, or into the ceiling plenum of the data center (134), where the air would potentially be dehumidified by the principal cooling equipment (123), provided that the principal cooling equipment (123) is configured for dehumidification (some CRACs/CRAHs are not provided with drip pans because they are designed to operate at sensible-only conditions, with no latent dehumidification).

Additional accessories/features which may be incorporated for a liquid-cooling application system include, but are not limited to:
a. Corrosion inhibiting devices, such as sacrificial anodes or impressed current cathodic protection systems.
b. Filtration equipment.
c. Various sensors and gauges, such as temperature, pressure, flow, liquid or material level, humidity, and particulate sensors.
d. Leak detectors, drip pans, and pressure relief valves.
e. Manholes/access ports, fill and drain ports, inspection ports, etc.
f. Insulation and linings, such as insulation on the enclosure (184).
g. In order to heat or cool the thermal storage tank (189) housing the thermal storage liquid, a secondary tank shell or insulating jacket (210) around the thermal storage tank (189), and/or the enclosure (168) housing the thermal storage tank (189), some of the heating and cooling devices and methodologies described previously for the compressed air tank (100) may also be used, including, but not limited to:
   i. A vortex-type cooler (178) and isolating/modulating devices (181, 181A, 181B);
   ii. A traditional electric-powered heater/heat tracing (187), such as an electric-resistive heater;
   iii. A traditional electric-powered cooler (188), such as an air-cooled DX cooler, a Peltier-type cooler (utilizing the thermoelectric effect), or similar; or
   iv. A sky-facing radiative-cooling panel (185).
h. An optional solar panel (207) to power the aforementioned heating/cooling devices and/or power other devices in enclosure (168) housing the thermal storage tank (189) which may not require steady, consistent power (for example, a control panel or sensors).

### Description of Some Embodiments for Moving Liquid and Refrigerant Cooling Fluids and Using Domestic Water as a Heat Sink

Instead of storing a thermal storage liquid, secondary cooling liquid, or a PCM in a thermal storage tank (189) to act as a heat sink for the TCS loop (161), a primary-to-secondary heat exchanger (163A) may be used with an “on-demand” domestic water connection (199). If the data center is located in a municipality where the domestic water is not reliant on utility power, neither at the municipal level nor at the local level within the facility (a gravity-type municipal domestic water system would likely fit this criteria), and the domestic water was consistently at a temperature below the return temperature of the TCS loop (161) all year long (this is often, but not always, true by the nature of the domestic water running underground), then a domestic water line could be fitted with a control valve (167, 167A, 167B) and connected to a primary-to-secondary heat exchanger (163A). Alternatively, a mechanical float-operated valve (201) may be used instead of or in parallel with the control valve (167, 167A, 167B) to fill the thermal storage tank (189). If directing the domestic water through a primary-to-secondary heat exchanger (163A), this would allow cool domestic water to flow through the primary-to-secondary heat exchanger (163A) upon an activation of the compressed air ride-through system, thus absorbing heat from the TCS loop (161) without the need for a thermal storage tank (189). After the domestic water passes through the primary-to-secondary heat exchanger (163A), it would then be directed to a drain connection (200), such as down a drain, to the outdoors, to a holding tank, or similar. In some jurisdictions, there may be code restrictions against using domestic water for single-pass-through cooling applications, however, those code restrictions may be more intended to prohibit the regular use of domestic water for such applications, whereas the application described here could be considered as more of an emergency-type use, which may be more amenable to local code officials. Note the following considerations:
a. Utilizing domestic water for immediate, short-term cooling must include an analysis of the portion of the domestic water piping upstream of the primary-to-secondary heat exchanger (163A) or upstream of the thermal storage tank (189) which resides aboveground or indoors, as the domestic water inside this piping will likely be at a temperature close to the environment in which is resides. Although domestic water is typically relatively cool since it often runs underground, the “slug” of water inside the piping near the end of the run prior to connecting to the primary-to-secondary heat exchanger (163A) or the thermal storage tank (189) would likely be stagnant and thus will have warmed up to surrounding air temperature. This means that the initial flow of domestic water through the primary-to-secondary heat exchanger (163A) or into the thermal storage tank (189) would likely start out warm (at least compared to the upstream underground domestic water temperature), and would not reach a cool temperature until the volume of aboveground/indoor piping had been displaced by domestic water from the underground piping. Despite this, if the indoor sections of domestic water reside in spaces which are maintained at temperatures below the return temperature of TCS loop (161), then it may already be at a suitable temperature, which would alleviate this concern in such cases.
b. The domestic water connection (199) will most likely require a backflow preventer/reduced pressure zone assembly (RPZ) (199A) by code. The backflow preventer/RPZ (199A) must be sized large enough to allow the necessary water flowrate to be delivered to the primary-to-secondary heat exchanger (163A). As mentioned previously, to provide sixty seconds of cooling for a one megawatt load operating at a 10° F. delta-T, a nominal water flowrate of approximately 275 gallons per minute would be required (and a total volume of approximately 275 gallons would be needed). This may result in a fairly sizeable backflow preventer/RPZ (199A).
c. For a larger facility with several megawatts of liquid-cooled ITE, it may be necessary to upsize the domestic water utility connection (199) and associated domestic water meter in order to accommodate the necessary flowrate.
d. For facilities which incorporate a form of onsite domestic water storage for the purposes of fire protection (such as a sprinkler house tank), cooling tower makeup, evaporative cooling, or other purposes, the source of the domestic water may be derived from these onsite sources instead of using the domestic water directly. An analysis would likely have to be performed to ensure that the necessary reserve of water is maintained for fire protection or cooling tower makeup/evaporative cooling purposes. And if using such an onsite storage tank, an analysis of whether or not a supplemental pump (such as a pneumatically driven pump (162, 162A, 194)) would be necessary to achieve the desired flowrate from the tank, or if the relative height differences and piping/valving pressure drop between the water level in the tank and the primary-to-secondary heat exchanger (163A) would allow for a gravity-only type feed.
e. A hybrid combination using domestic water and a thermal storage tank (189) may be desirable in some cases. The domestic water connection (199) and drain connection (200) in such an arrangement may be simply opened to drain and re-fill the tank periodically under non-emergency conditions (or possibly to affect the water temperature inside the tank), or they may be opened upon an activation of the compressed air ride-through system to agitate the domestic water inside the thermal storage tank (189) and possibly extend the runtime by potentially further cooling the water inside the thermal storage tank (189) (provided that the domestic water is cooler than the water already in the thermal storage tank (189)). Another possible configuration may be keeping the thermal storage tank (189) empty under normal conditions, and using a coil (191) inside the tank, which would normally remain dry in this configuration, allowing a primary-only arrangement. In this configuration, the domestic water connection (199) may open upon an activation of the compressed air ride-through system and “quench” the coil (191) inside the thermal storage tank (189). The domestic water could also be fed to the thermal storage tank (189) through gravity alone if there was an onsite storage tank of water at a higher level.

### Mitigation of the Risk of a Rupture of a Compressed Air Tank

The risk of a rupture (and the risk of the effects of a rupture) of a compressed air tank (100, 100A, 100B, 145) may be mitigated in several ways, described below:
a. Following all local building codes and requirements of the authority having jurisdiction and following all Compressed Air Gas Institute recommendations.
b. Using American Society of Mechanical Engineers (ASME)-rated pressure relief valves.
c. Using only rated compressed air tanks (100, 100A, 100B, 145), such as ASME-rated or tank ratings from other organizations.
d. Storing the compressed air in the compressed air tank (100, 100A, 100B, 145) at a pressure which is significantly lower than the tank's pressure rating (for example, if a 200 PSIG compressed air tank is required, using a 300 PSIG rated tank).
e. Sizing the compressed air tank (100, 100A, 100B, 145) and other components to meet the project requirements with a compressed air pressure of 200 PSIG or less.
f. Using a coating or lining (147) on the interior surface of the compressed air tank (100, 100A, 100B, 145), such as epoxy or polyurea. This has five benefits:
   i. The coating or lining (147) reduces the corrosion to the inner surface of the compressed air tank (100, 100A, 100B, 145).
   ii. The coating or lining (147) inhibits heat transfer from the tank walls to the compressed air in the tank during an activation of the backup system for better cooling performance.
   iii. By reducing heat transfer, the coating or lining (147) keeps the tank walls closer to the surrounding air temperature and prevents the tank from undergoing severe temperature changes. Thus, the coating or lining (147) reduces thermal expansion/contraction of the tank and reduces the risk of embrittlement or fatigue failure of the tank.
   iv. In the case of polyurea or other similar coatings or linings (147) which can be deformed, the coating or lining (147) may significantly reduce the severity of a rupture by absorbing some of the kinetic energy of the rupture.
   v. The coating or lining (147) minimizes the formation of rust particles and thus minimizes the chance of rust particles entering the discharge airstream.
g. Placing the compressed air tank (100, 100A, 100B, 145) on a roof, outdoors, or in a room where the frequency of personnel in proximity to the tank is low.
h. Implementing various sensors (111, 112, 177) on the compressed air tank (100, 100A, 100B, 145) and configuring them to generate alarms to alert the operators.
i. Implementing periodic inspections of the compressed air tank (100, 100A, 100B, 145), such as visual inspections of the interior and exterior of the tank, tank wall thickness testing/tank integrity testing, and leak testing.
j. Utilizing automatic drains (114), compressed air dryers (132), dehumidifying the intake air upstream of the compressor (113), desiccants, or other means of moisture control to minimize rust development.
k. Adding an optional enclosure (168) around the compressed air tank (100, 100A, 100B, 145).
l. Adding sacrificial anodes to the compressed air tank (100, 100A, 100B, 145), or other means of corrosion protection.
m. Burying the compressed air tank (100, 100A, 100B, 145) underground.
n. Or a combination thereof.

### Mitigation of the Footprint of a Compressed Air Tank

The potentially-large footprint of a compressed air tank (100, 100A, 100B, 145) can be mitigated in several ways:
a. Placement of the compressed air tank (100, 100A, 100B, 145) outdoors on the ground, on a roof, underground, suspended overhead indoors, or in a plenum.
b. Splitting the total compressed air volume into multiple smaller compressed air tanks (100, 100A, 100B, 145) instead of a single, large tank. This also would allow the compressed air tanks (100, 100A, 100B, 145) to potentially be installed without the use of heavy machinery (for example, if the tanks are small enough to fit in a freight or passenger elevator). Note that this would increase the surface area and tank material necessary to contain the same amount of air, which would be more costly in terms of materials, but possibly less costly in terms of installation. Increasing the surface area of the compressed air tank (100, 100A, 100B, 145) also reduces the cooling performance of the compressed air ride-through system.
c. Utilizing an elongated compressed air tank, such as air-pressurized piping (145). The air-pressurized piping (145) then could be installed and routed in an uncongested area, possibly overhead to eliminate the use of floor space. Or it could be routed outside around the building, or even underground. Note that this would increase the surface area and tank material necessary to contain the same amount of air, which would be more costly in terms of materials, but possibly less costly in terms of installation. Increasing the surface area of the compressed air tank (100, 100A, 100B, 145) also reduces the cooling performance of the compressed air ride-through system.

### Mitigation of the Risk of Condensation and Moisture Entering or Forming in the Data Center

The risk of condensation and moisture entering or forming in the data center as a result of the activation of the compressed air ride-through system can be mitigated in several ways:
a. The transient, short-duration nature of the compressed air ride-through system operation means that in many scenarios, even though the expanding air will get quite cold, it may not spend enough time in the compressed air conduit (109, 122, 124), pneumatically-powered fluid movers (116, 123A, 150, 152, 162, 162A, 174, 194, 203, 205A, 205B, 211), and compressed-air-to-cooling-fluid heat exchangers (163) to conduct heat through these devices to the point where the external surfaces of these devices drops below the surrounding dewpoint temperature (as opposed to a steady-state system with a continuously-cold fluid temperature). The mass, conductivity, thickness, density, specific heat, surface condition, and local heat transfer coefficients of the components in contact with the released compressed air will influence the formation of condensation as well.
b. For air amplifiers (116), pneumatically-driven fans (150, 152), and reaction-type fans (174), the entrained/induced ambient air (120) may be warm enough in many cases to mix with the cold compressed air to result in mixed discharge air (121) which has a temperature above the dewpoint of the ambient air in the data center. Furthermore, the ambient air through and around the air amplifiers (116), pneumatically-driven fans (150, 152), and reaction-type fans (174) may not have enough contact time with the surface to actually develop condensation.
c. For most air amplifiers (116), the compressed air tends to create a “boundary layer” along the inner surface of the device, from the compressed air outlet/orifice opening(s) to the discharge end of the device, and the entrained/induced air (120) tends to pass through the center of the device. This means that even if the entrained/induced ambient air (120) is warm and moist, it may not actually come into contact with the potentially-cold inner surface of the air amplifier (116), since the compressed air is moving fast along the inner surface already. The speed of the entrained/induced ambient air (120) moving through the device also reduces the contact time.
d. Related to the item above, after the compressed air ride-through system has activated and the compressed air tank (100, 100A, 100B, 145) has fully discharged, the flow of compressed air will cease, and there will no longer be a boundary layer to separate the cold inner surface of air amplifiers (116) from the ambient air (although the device will no longer be actively entraining/inducing ambient air through it, ambient air will still migrate into the device and potentially “sit” within the device, simply by virtue of the device being open to the room). This can be mitigated by utilizing a re-closing type of damper/valve/device (118, 119, 140, 141) or other means of sealing up/closing the openings for air amplifiers (116) to help prevent condensation from forming after the compressed air ride-through system has completed its release.
e. The use of low thermal conductivity materials and/or coatings or liners (147), in the compressed air tank (100, 100A, 100B, 145), the compressed air conduit (109, 122, 124), and the pneumatically-powered fluid movers (116, 123A, 150, 152, 162, 162A, 174, 194, 203, 205A, 205B, 211) further slows down the rate at which the external surface temperature of these devices drops.
f. Implementing a re-warming means to deliver warmer air (171, 172) down the compressed air conduit (109, 122, 124) after the compressed air ride-through system has completed its release in order to warm up the downstream components.
g. Applying external insulation (147A) to the compressed air tank (100, 100A, 100B, 145), the compressed air conduit (109, 122, 124), and the pneumatically-powered fluid movers (116, 123A, 150, 152, 162, 162A, 174, 194, 203, 205A, 205B, 211).
h. Installing certain components outside of the data center where condensation would be less of a concern, such as the compressed air tank (100, 100A, 100B, 145) and the compressed air conduit header (109).
i. Using double-walled compressed air conduit (109, 122, 124).
j. For pneumatically-overridden principal cooling equipment (123A), the internal drip/drain pans (if present) integral to the pneumatically-overridden principal cooling equipment (123A) may collect any condensate.
k. Avoiding any orientations or installation locations of the pneumatically-powered fluid movers (116, 123A, 150, 152, 162, 162A, 174, 194, 203, 205A, 205B, 211) in which they would direct compressed air onto conductive surfaces or onto ITE cabinets or drip onto ITE cabinets.
l. For metal couplings, adapters, unions, threaded fittings etc. in the compressed air conduit, these may be externally insulated, or a sleeve of low thermal conductivity material may be placed over them.
m. Utilizing automatic drains (114), compressed air dryers (132), dehumidifying the intake air upstream of the compressor (113), desiccants, or other means of moisture control.
n. For components which are not suited for any of the mitigation strategies above, a means of moisture/condensate collection may be implemented, such as drip pans, filters (143, 143A) with mist-eliminating capability, desiccant, sponges, hydrophilic foam, or a combination thereof.

### Mitigation of the Time Necessary to Recharge/Re-Pressurize a Compressed Air Tank

This section includes considerations when evaluating the time necessary to recharge/re-pressurize a compressed air tank (100, 100A, 100B, 145) following an activation of the compressed air ride-through system, including considerations for the temperature rise inside the tank while recharging/re-pressurizing and associated risk mitigation strategies.

When a normal power utility failure occurs, the compressed air ride-through system would release the compressed air to the pneumatically-powered fluid movers (116, 123A, 150, 152, 162, 162A, 174, 194, 203, 205A, 205B, 211) to maintain the ITE (125, 154, 157) within an acceptable temperature range, and if sized and designed properly, this will give the principal cooling equipment sufficient time to restart/reboot so that the principal cooling equipment can resume its duty. Following an activation of the compressed air ride-through system, the onsite generators would have started and all generator-backed equipment (including the ITE and the principal cooling equipment) would be being fed by the generators (assuming the normal utility power had not resumed). The compressed air tank (100, 100A, 100B, 145) would now be at roughly atmospheric pressure and would need to be recharged/re-pressurized so that it would be ready for the next utility failure or other non-standard operating condition. The recharge/re-pressurization of the compressed air tank (100, 100A, 100B, 145) may be automatic (via a permanently-connected compressor) or manual (via a portable compressor). In both cases, the compressed air tank (100, 100A, 100B, 145) will take several minutes or several hours to recharge, depending on the tank size and compressor size/power, and the target pressure. Once recharged/re-pressurized, the air inside the compressed air tank (100, 100A, 100B, 145) will initially be considerably warm due to the heat of compression. It may take several hours for the air inside the compressed air tank (100, 100A, 100B, 145) to lose its heat to the walls of the tank, which then lose their heat to the surrounding air and settle to roughly the surrounding air temperature (the compressed air in the tank will also lose a small amount of pressure as it settles to the surrounding air temperature, but this can be compensated for by initially pressurizing to a slightly higher pressure). The compressed air ride-through system would be capable of re-activating at any point during the recharging/repressurizing process and during the temperature-settling time and still potentially provide a benefit, such as moving ambient air or powering a pneumatically-powered pump serving a TCS loop, but for any aspects of the system in which the released compressed air is used for cooling or used as a heat sink, the released compressed air would only operate at partial cooling capacity until the re-pressurized air had lost the heat of compression to the surroundings and fully settled back down to the target/design temperature (the compressed air will still cool down considerably when released, even if starting at a warm temperature). Similarly, if there are any thermal storage components in the compressed air ride-through system, such as a passive airside thermal storage heat exchanger (208) or a thermal storage tank (189), those components will also require time to settle back to their target/design temperature before being able to re-achieve their full design cooling capacity.

Despite this, there is most likely not much need for the compressed air ride-through system to be able to activate twice in a short period of time. For example, in some embodiments, when a normal utility power failure occurs, the compressed air ride-through system will activate to bridge the temporary loss of power to the principal cooling equipment while the onsite generators start up and the principal cooling equipment restarts/reboots. In order for the compressed air ride-through system to be needed to activate a second time shortly after the first activation, that means a secondary failure (or some other non-standard operating condition) has now occurred (the first failure being the loss of utility). The secondary failure could be a generator failing shortly after it has started, a piece of non-redundant electrical equipment (such as an ATS) failing shortly after it has switched to emergency, or more than just the redundant principal cooling equipment failing shortly after it has restarted (failure of one or a few pieces of principal cooling equipment within the limits of the redundancy would not be a failure; i.e. two CRAC's could fail in a properly-arranged N+2 system without reaching failure conditions). In all these cases, a second-order failure has occurred, and depending on the nature of the second-order failure, the compressed air ride-through system may not provide any benefit even if the compressed air tank (100, 100A, 100B, 145) had fully re-pressurized and settled to the design/target temperature prior to this second-order failure, or it may only be useful in re-activating if the second-order failure were of a short duration (i.e. if the issue resolved itself in short duration). For example, if a loss of utility occurred and the generators started, and then the generators failed shortly thereafter, there would be no backup power source to the generators (the generators are already the backup power source), and thus the ITE itself would end up losing power after the UPS batteries ran out (there is no point in trying to keep the ITE cool if the ITE has lost power). In such a scenario, the only way the compressed air ride-through system (or even the alternative of UPS-backed principal cooling equipment) would be useful for a second-order failure of this nature would be if the generators failed after starting and then they restarted again shortly after that. If the generators failed for a longer period, such that the UPS batteries ran out, even if generators were restarted a while after, the ITE and the principal cooling equipment would have both lost power and thus both failed. Both the compressed air ride-through system and the alternative of UPS-backed principal cooling equipment can only provide interim cooling for a short period—this means that they only succeed when a power source (whether normal power or standby/emergency power) comes back online within a time period which is shorter than the available ride-through window and shorter than the available UPS battery duration supporting the ITE.

Note that in addition to the initial interruption of power to the principal cooling equipment during a normal utility power failure, there will also usually be a second interruption of power to the principal cooling equipment much later when transferring back from generator power back to normal utility power, once normal utility power has resumed and remains steady (even for short interruptions to the normal utility power, many generator and ATS systems are configured to remain on generator power for a minimum duration, even if normal utility power resumes quickly). This is because the ATS's upstream of principal cooling equipment are usually arranged as “open-delayed,” which intentionally disconnects power from both the generators and the normal power source prior to connecting to the normal power source. This is done to allow a short period for mechanical and motor loads to dissipate their electrical “flux” to minimize the inrush on the normal power source. This re-transfer back to normal power is often conducted under supervision of the operators and the period of power interruption is much shorter. But it would likely be desirable for the compressed air ride-through system to be able to activate during this second interruption to the principal cooling equipment as well. The operators may wish to activate the compressed air ride-through system manually during this re-transfer back to normal power, or they may wish for the compressed air ride-through system to activate automatically. In both cases, if the compressed air ride-through system has been configured with options such that it can recharge/re-pressurize while the generators are running, and if sufficient time has passed since the initial loss of utility (or since the initial non-standard operating condition occurred) so that the compressed air in the compressed air tank (100, 100A, 100B, 145) has settled back down to its target/design temperature, then the compressed air ride-through system will have full capacity for this re-transfer back to normal power. If the re-transfer back to normal power is soon after the initial loss of utility (i.e. sooner than the recharge and temperature-settling time of the compressed air ride-through system), the compressed air ride-through system may only be able to deliver partial capacity, although that may still be sufficient given the potential quicker restoration of principal cooling equipment and especially if the temperature of the air surrounding the compressed air tank (100, 100A, 100B, 145) is relatively cool (results in a faster temperature-settling time).

If the compressed air tank (100, 100A, 100B, 145) is installed outdoors, note that the compressed air ride-through system would likely be sized/selected based on a worst-case (i.e. highest) outdoor air temperature to which the compressed air would settle to. Different metrics could be used for determining this design outdoor temperature, such as the ASHRAE 99.6% dry bulb values or the n=5, 10, 20, or 50 year extreme values. The intent would be that the compressed air ride-through system would provide the intended ride-through time when starting with compressed air at a temperature equal to the design outdoor temperature. The design outdoor temperature statistically only occurs for a few hours a year (or may not be reached at all in a given year, especially if using the ASHRAE extreme values). This means that for the vast majority of the year, the temperature-settling time will be inherently sped up, since the compressed air only needs to settle down to the design outdoor temperature in order to reach full capacity, not necessarily down to the actual current outdoor dry bulb temperature. For example, consider a system that is designed to achieve the necessary ride-through time using the ASHRAE 99.6% value for a particular location, and that location's 99.6% dry bulb temperature is 95° F. This means that the compressed air ride-through system would be sized to achieve the ride-through time with a starting compressed air temperature of 95° F. If the compressed air ride-through system activated on any day where the actual outdoor dry bulb temperature was cooler than the design outdoor temperature (which is true for 99.6% of the year, statistically) and then was recharged, the outdoor intake air entering the compressor would be cooler than the design outdoor temperature, and the compressed air leaving the compressor (i.e. the compressed air accumulating in the compressed air tank) would only have to cool back down to the design outdoor temperature of 95° F. before it would be ready to provide the full ride-through time once again. So, if the actual outdoor temperature was 72° F. when the compressed air ride-through system was recharging, the time it would take for the compressed air in the tank to lose the heat of compression and settle back down to 95° F. (and thus be at fully cooling capacity, since the system was designed for a starting temperature of 95° F.) would be considerably shorter than if the outdoor temperature was 95° F. Note that air movement, such as wind, around the compressed air tank (100, 100A, 100B, 145) will also assist in speeding up the temperature-settling time, since the convective heat transfer coefficient would be higher around the compressed air tank (100, 100A, 100B, 145).

If a particular facility has a desire to have the compressed air ride-through system capable of operating at full capacity a second time, shortly after the first activation, this can be accomplished/mitigated as follows:
a. Using a compressor with an air-cooled, liquid-cooled, or refrigerant-cooled intercooler and/or multiple compression stages, which helps reject a large portion of the heat of compression. This will speed up the temperature-settling time.
b. Use a larger or more powerful compressor to speed up the recharge/re-pressurization time. However, doing so will increase the compressed air temperature inside the tank, potentially requiring a longer temperature-settling time. The total time necessary for the compressed air ride-through system to regain full capacity is dependent on both the duration necessary to re-pressurize the tank to the target/design pressure and the duration necessary to lose the heat of compression and settle back to the target/design temperature.
c. Use two or more redundant compressed air tanks (100, 100A, 100B, 145), arranged to only release one at a time, where each tank is sized for the full capacity desired. The compressed air tanks (100, 100A, 100B, 145) could both serve the same header(s) and same pneumatically-powered fluid movers (116, 123A, 150, 152, 162, 162A, 174, 194, 203, 205A, 205B, 211), so there would not be a need to add other redundant components in this scheme.
d. If using a permanent compressor, bring normal and emergency power to the compressor and/or the optional controller (104), such that the compressed air ride-through system can recharge/re-pressurize when only generator power is available.
e. If using a portable compressor, ensure that a generator-backed convenience outlet/receptacle is installed in close proximity to the compressed air tank (100, 100A, 100B, 145).
f. Implement a vortex tube (178), a traditional electric-powered cooler (188), or a sky-facing radiative-cooling panel (185) on the compressed air tank (100, 100A, 100B, 145) to speed up the temperature-settling time.
g. Implement additional surface area on the exterior of the compressed air tank (100, 100A, 100B, 145), such as adding fins to the exterior.
h. Implement heat pipes or thermosiphons in or on the compressed air tank (100, 100A, 100B, 145) to accelerate the heat transfer to the surroundings.
i. Implement heat pipes or thermosiphons in or on the compressed air tank (100, 100A, 100B, 145) to accelerate the heat transfer to the surroundings.

### Mitigation of the Risk of Static Electricity Build-Up

The risk of static electricity build up can be mitigated by simply grounding (133) the compressed air tank (100, 100A, 100B, 145), the compressed air conduit (109, 122), and any downstream devices which do not have a metallic/conductive path back to the compressed air tank (100, 100A, 100B, 145).

Mitigation of the Risk of Discharging Dust or Small Particles into the Data Center

The risk of discharging dust or small particles into the data center can be mitigated by:
a. Using a coating or liner (147) on the inner surface of the compressed air tank (100, 100A, 100B, 145), on the compressed air conduit (109, 122, 124), and on the pneumatically-powered fluid movers (116, 123A, 150, 152, 162, 162A, 174, 194, 203, 205A, 205B, 211).
b. Using compressed air conduits (109, 122, 124) which have a plastic or polymer inner surface.
c. Using inline filters (131) on the outlet of the compressed air tank (100, 100A, 100B, 145), along the compressed air conduit (109, 122, 124), and at the inlet of the pneumatically-powered fluid movers (116, 123A, 150, 152, 162, 162A, 174, 194, 203, 205A, 205B, 211).
d. Using filters (143, 143A) at the discharge air outlet of air amplifiers (116), pneumatically-powered fans (152), reaction-type fans (174), and pneumatically-overridden pieces of principal cooling equipment (123A).
e. If using a passive airside thermal storage heat exchanger (208, 208A), arranging the fixed mass of heat exchange material in a mesh structure to act as a filter.
f. Avoiding the use of zinc-electroplated materials, thus preventing zinc whiskers from forming.

### Mitigation of the Risk of Over-Pressurizing the Data Center

The risk of over-pressurization of the data center can be mitigated by:
a. The presence of permanent openings (158) in the data center (134) already, such as door gaps, gaps in construction around penetrations, etc. Data centers are typically not fully sealed and have a significant aggregate leakage area through the walls, floors, and plenums.
b. Implementing provisions for pressure equalization, such as intentional gaps or openings (158).
c. Implementing a room-level pressure-relief device (159), such as a relief damper, backdraft damper, counterbalanced backdraft damper, pneumatic damper, motorized damper, check valve, or “break-through” seals.
d. Performing an analysis of the adequacy of the data center (134) construction for leakage, and whether or not a means of relief is necessary, similar to the guidance in NFPA 2001 and FSSA Application Guide to Estimating Enclosure Pressure & Pressure Relief Vent Area for Use with Clean Agent Fire Extinguishing Systems.
e. Note that if the compressed air flowrate to the data center (134) is comparable to the normal/principal outdoor airflow introduced to the data center (134) under normal conditions, and assuming that the principal outdoor air fan(s) shut down temporarily upon a loss of utility power, then the data center (134) space may not need any special/additional provisions for pressure relief/equalization (158, 159) to accommodate the compressed air ride-through system.
f. Related to over-pressurization is the risk of a potential “shock wave” being created by the releasing compressed air into the data center (134). The risk of a “shock wave” is mitigated by:
   i. Using semi-slow-opening automatic releasing valves (i.e. not using instant-opening solenoid valves).
   ii. Using only pneumatically-powered fluid movers (116, 123A, 150, 152, 162, 162A, 174, 194, 203, 205A, 205B, 211) which have converging orifices to discharge compressed air (as opposed to converging-diverging orifices, which could create supersonic flow).
   iii. The internal re-direction pathways and stagnation chambers which are present within most, if not all, pneumatically-powered fluid movers (116, 123A, 150, 152, 162, 162A, 174, 194, 203, 205A, 205B, 211), which helps to absorb any pressure waves (as opposed to just an open-ended pipe with no elbows).
   iv. Also note that the noise level during activation of the compressed air ride-through system is also mitigated by the pneumatically-powered fluid movers (116, 123A, 150, 152, 162, 162A, 174, 194, 203, 205A, 205B, 211), which reduce the noise level significantly, compared to just an open-ended pipe discharging compressed air. For example, all air amplifiers (116) which publish the sound ratings show decibel levels which are tolerable for the short duration that the compressed air ride-through system would operate (approx. 50-90 dB, depending on several factors).

### Other Potential Applications of the Invention

There may be additional applications where cooling is only required infrequently, for which the compressed air ride-through system may offer benefits over more traditional cooling methodologies. For example, suppose a data center is designed to normally operate at elevated air or liquid/refrigerant temperatures, such that the local outdoor air and humidity conditions at the given facility location are typically sufficiently cool to utilize the outdoor air directly or indirectly without the use of refrigerant compressors. For such a facility, a supplementary means of cooling may only be required during statistically-extreme periods of warm/humid outdoor conditions for short durations of time (for example, a short excursion of the outdoor air to the ASHRAE 50-year extreme dry bulb temperature for the given location). In such a case, the compressed air ride-through system may be more attractive than implementing a large, costly traditional principal cooling system which would likely only be required to operate for a few short periods over the lifespan of the data center. However, the compressed air ride-through system is likely only cost effective when sized to operate for a few minutes, whereas an extreme weather excursion could last several hours or even several days, and thus in order to be used successfully in such an application, the size of the compressed air tank (100, 100A, 100B, 145) would have to be much larger (or multiple compressed air tanks (100, 100A, 100B, 145) would have to be installed) and/or the pressure inside the compressed air tank (100, 100A, 100B, 145) may have to be increased dramatically. Furthermore, for the relatively slow release of the compressed air that would be needed for such a long operation of the compressed air ride-through system, the drop in the stagnation temperature of the compressed air will be relatively small, since the heat transfer from the tanks walls to the compressed air will partially “keep up” with the drop in stagnation temperature. This may make the compressed air ride-through system cost-prohibitive or unsuitable for such an application, but nonetheless, this type of application may still be possible (but likely with several modifications required).

Other applications may be systems or processes in which only immediate, short-term movement of cooling fluids and/or short-term durations of cooling (i.e. a few seconds to a few minutes) are required fairly infrequently, as opposed to constant/regular/principal cooling. For example, there may be processes in the medical, industrial, manufacturing, nuclear, military, semiconductor, and other fields where a short-term loss of cooling cannot be tolerated during a utility failure or other non-standard operating condition. The compressed air ride-through system may be suitable for such applications.

1. A backup system for maintaining information technology equipment within an acceptable temperature range for a duration of thirty minutes or less, the backup system comprising:
a. at least one compressed air tank for storing compressed air at a pressure of at least twenty-five pound-force per square inch gauge prior to activation of said backup system;
b. at least one automatic releasing valve for releasing said compressed air from said compressed air tank in response to at least one indication of a non-standard operating condition, wherein said indication of a non-standard operating condition comprises an indication of a loss of normal utility power;
c. at least one pneumatically-powered fluid mover, comprising a compressed air inlet and a compressed air outlet, wherein:
i. said pneumatically-powered fluid mover utilizes said compressed air to move a cooling fluid at a mass flowrate which is at least three times larger than the mass flowrate of said compressed air entering said pneumatically-powered fluid mover;
ii. said cooling fluid absorbs heat which originates from said information technology equipment; and
iii. said pneumatically-powered fluid mover is external to the cabinets which house said information technology equipment; and
d. at least one compressed air conduit for delivering said compressed air from said compressed air tank to said pneumatically-powered fluid mover, wherein said compressed air conduit comprises a pipe, a hose, a tube, or a combination thereof.

2. The backup system according to claim 1, wherein said cooling fluid is at least one fluid selected from the group consisting of ambient air, water, condenser water, glycol chilled water, glycol condenser water, facility water, technology cooling water, technology cooling liquid, refrigerant, dielectric fluid, deionized water, domestic water, thermal storage liquid, mineral oil, primary cooling fluid, primary cooling liquid, secondary cooling fluid, and secondary cooling liquid.

3. The backup system according to claim 1, further comprising a plurality pneumatically-powered fluid movers, wherein at least one pneumatically-powered fluid mover is of a dissimilar type than the other pneumatically-powered fluid movers present in said backup system.

4. The backup system according to claim 1, further comprising a plurality of pneumatically-powered fluid movers, wherein at least one pneumatically-powered fluid mover moves a dissimilar type of said cooling fluid than the other pneumatically-powered fluid movers present in said backup system.

5. The backup system according to claim 1, further comprising a plurality pneumatically-powered fluid movers, wherein at least two pneumatically-powered fluid movers are configured in an in-parallel arrangement or an in-series arrangement, wherein said in-series arrangement comprises a secondary compressed air conduit to deliver said compressed air from said compressed air outlet of at least one said pneumatically-powered fluid mover to said compressed air inlet of at least one similar or dissimilar type of said pneumatically-powered fluid mover.

6. The backup system according to claim 1, further comprising at least one communication means to communicate an indication of a non-standard operating condition to said automatic releasing valve, wherein said communication means comprises at least one power wire or at least one control wire.

7. The backup system according to claim 1, wherein:
a. said compressed air experiences a drop in stagnation temperature due to expansion of said compressed air caused by said release of said compressed air from said compressed air tank; and
b. said drop in stagnation temperature of said compressed air is utilized solely or in part to drop the stagnation temperature of said cooling fluid.

8. The backup system according to claim 1, further comprising at least one cooling fluid conduit for conveying said cooling fluid to or from said pneumatically-powered fluid mover, wherein said cooling fluid conduit comprises a pipe, a hose, a tube, a duct, or a combination thereof.

9. The backup system according to claim 1, further comprising at least one cooling fluid backflow prevention means for preventing backflow of said cooling fluid through said pneumatically-powered fluid mover, wherein said cooling fluid backflow prevention means comprises at least one cooling fluid backflow preventer selected from the group consisting of a backdraft damper, a spring-loaded damper, a pneumatically-operated damper, an isolating damper, a modulating damper, a disposable cap, a break-through paper seal, a valve, and a check valve.

10. The backup system according to claim 1, further comprising at least one compressed-air-to-cooling-fluid heat exchanger comprising a compressed air inlet, a compressed air outlet, a cooling fluid inlet, a cooling fluid outlet, and a heat exchange surface, wherein said compressed-air-to-cooling-fluid heat exchanger transfers heat from said cooling fluid to said compressed air.

11. The backup system according to claim 1, further comprising at least one air compressor for re-pressurizing said compressed air tank, wherein said air compressor is portable or permanently-installed.

12. The backup system according to claim 1, further comprising at least one coating or lining on the inner surface of said compressed air tank.

13. The backup system according to claim 1, further comprising at least one coating or lining on the inner surface of said compressed air tank, wherein said coating or lining is made primarily of epoxy, polyurea, or a combination thereof.

14. The backup system according to claim 1, further comprising at least one layer of insulation on the exterior surface of said compressed air tank.

15. The backup system according to claim 1, wherein said compressed air tank further comprises a second shell around the primary wall of said compressed air tank.

16. The backup system according to claim 1, wherein said compressed air tank further comprises a second shell around the primary wall of said compressed air tank and at least one layer of insulation on the exterior surface of said second shell.

17. The backup system according to claim 1, further comprising at least one means of heating said compressed air tank.

18. The backup system according to claim 1, further comprising at least one means of cooling said compressed air tank.

19. The backup system according to claim 1, further comprising at least one vortex tube arranged to provide heating, cooling, or a combination thereof to said compressed air tank, wherein said vortex tube utilizes said compressed air from said compressed air tank.

20. The backup system according to claim 1, further comprising at least one automatic condensate drain valve assembly on the bottom of said compressed air tank for removing condensate from said compressed air tank.

21. The backup system according to claim 1, further comprising at least one compressed air dryer for removing moisture from said compressed air.

22. The backup system according to claim 1, further comprising at least one electrical grounding connection on said compressed air tank, on said compressed air conduit, on said pneumatically-powered fluid mover, or a combination thereof.

23. The backup system according to claim 1, wherein said compressed air tank is constructed of air-pressurized piping, and wherein said air-pressurized piping is singlewall or doublewall piping.

24. The backup system according to claim 1, wherein said backup system complies with the American National Standards Institute's and Compressed Air & Gas Institute's Safety Standard for Air Compressor Systems.

25. The backup system according to claim 1, wherein said compressed air tank complies with the American Society of Mechanical Engineers' Boiler and Pressure Vessel Code, Section VIII, Division 1.

26. The backup system according to claim 1, wherein said compressed air tank stores said compressed air at a pressure between twenty-five pound-force per square inch gauge and two-hundred pound-force per square inch gauge prior to activation of said backup system.

27. The backup system according to claim 1, wherein said compressed air conduit further comprises at least one coating or lining on the inner surface of said compressed air conduit.

28. The backup system according to claim 1, wherein said compressed air conduit comprises an inner surface made primarily of plastic or polymer.

29. The backup system according to claim 1, wherein said compressed air conduit further comprises at least one layer of insulation on the exterior surface of said compressed air conduit.

30. The backup system according to claim 1, wherein said compressed air conduit is constructed of doublewall piping, doublewall hosing, doublewall tubing, or a combination thereof.

31. The backup system according to claim 1, wherein said compressed air conduit is constructed of doublewall piping, doublewall hosing, doublewall tubing, or a combination thereof, and wherein said doublewall piping, doublewall tubing, or doublewall hosing further comprises at least one layer of insulation on the exterior surface of said doublewall piping, doublewall tubing, or doublewall hosing.

32. The backup system according to claim 1, further comprising at least one re-warming means for re-warming said pneumatically-powered fluid mover, said compressed air conduit, or a combination thereof following an activation of said backup system.

33. The backup system according to claim 1, further comprising at least one re-warming fan connected to said compressed air conduit, wherein said re-warming fan re-warms said pneumatically-powered fluid mover, said compressed air conduit, or a combination thereof following an activation of said backup system by delivering ambient air into, around, or through said compressed air conduit.

34. The backup system according to claim 1, further comprising at least one in-line compressed air filter on said compressed air conduit to filter said compressed air upstream of said pneumatically-powered fluid mover.

35. The backup system according to claim 1, further comprising at least one in-line compressed air dryer on said compressed air conduit to remove moisture from said compressed air upstream of said pneumatically-powered fluid mover.

36. The backup system according to claim 1, further comprising at least one condensate collection means for collecting condensate produced by said backup system during and after an activation of said backup system, wherein said condensate collection means allows the collected condensate to evaporate, to be disposed of, or a combination thereof.

37. The backup system according to claim 1, further comprising at least one condensate collection means for collecting condensate produced by said backup system during and after an activation of said backup system, wherein said condensate collection means allows the collected condensate to evaporate, to be disposed of, or a combination thereof, and wherein said condensate collection means comprises at least one condensate collector selected from the group consisting of a drain, a drip pan, a mist eliminator, a grease eliminator, a desiccant, a hydrophilic material, a sponge, and a hydrophilic foam.

38. The backup system according to claim 1, further comprising at least one pressure regulating valve on said compressed air conduit.

39. The backup system according to claim 1, further comprising at least one throttling valve or Joule-Thomson valve on said compressed air conduit.

40. The backup system according to claim 1, wherein said automatic releasing valve is at least one valve selected from the group consisting of a fail-open valve, a powered-closed fail-open valve, a pneumatic valve, a pilot-operated valve, a pilot valve controlling a pneumatic valve, a diaphragm valve, a motorized valve, a solenoid valve, a deluge valve, an electro-pneumatic valve, and an automatic cylinder valve.

41. The backup system according to claim 1, further comprising at least one holding means for holding said automatic releasing valve open after said automatic releasing valve initially opens.

42. The backup system according to claim 26, wherein said holding means holds said automatic releasing valve open regardless of any changes to the state or status of said indication of a non-standard operating condition.

43. The backup system according to claim 26, wherein said holding means holds said automatic releasing valve open for a minimum duration sufficient to drop the absolute pressure inside said compressed air tank to a value which is approximately 0.37 times the initial absolute pressure inside compressed air tank or lower.

44. The backup system according to claim 1, further comprising at least one relay for adjustment of the duration for which said automatic releasing valve is held open.

45. The backup system according to claim 1, further comprising at least one full-release means for fully releasing said compressed air from said compressed air tank, such that the pressure inside said compressed air tank drops to atmospheric pressure or near atmospheric pressure.

46. The backup system according to claim 1, wherein said automatic releasing valve opens in response to said loss of normal utility power without requiring the assistance of digital controls, electronic controls, normal utility power, backup power, nor manual intervention.

47. The backup system according to claim 1, wherein:
a. said automatic releasing valve is a fail-open valve;
b. said fail-open valve opens in response to said loss of normal utility power without requiring the assistance of digital controls, electronic controls, normal utility power, backup power, nor manual intervention; and
c. said fail-open valve remains open to fully release said compressed air from said compressed air tank, such that the pressure inside said compressed air tank drops to atmospheric pressure or near atmospheric pressure, without requiring the assistance of digital controls, electronic controls, normal utility power, backup power, nor manual intervention.

48. The backup system according to claim 1, further comprising a re-closing means for re-closing said automatic releasing valve.

49. The backup system according to claim 1, further comprising at least two automatic releasing valves in parallel for redundancy.

50. The backup system according to claim 1, further comprising at least one automatic fire-alarm-interlocked valve in the pathway of said compressed air.

51. The backup system according to claim 1, further comprising at least one controller and a means responsive to said controller for opening said automatic releasing valve in response to said indication of a non-standard operating condition.

52. The backup system according to claim 1, wherein said indication of a non-standard operating condition is at least one indication selected from the group consisting of a loss of normal utility power, a loss of at least one source of normal utility power, a principal cooling equipment alarm, a principal cooling equipment signal, a generator alarm, a generator signal, an emergency power alarm, an emergency power signal, a standby power alarm, a standby power signal, a transfer switch alarm, a transfer switch signal, a cooling fluid alarm, a cooling fluid signal, a cold aisle alarm, a cold aisle signal, a differential pressure alarm, a differential pressure signal, a leak alarm, a leak signal, a temperature sensor alarm, a temperature sensor signal, an information technology equipment alarm, an information technology equipment signal, an information technology equipment failure alarm, an information technology equipment failure signal, an information technology equipment high temperature alarm, an information technology equipment high temperature signal, a user-configurable alarm, a user-configurable signal, a building management system alarm, a building management system signal, a power management system alarm, a power management system signal, a state change of an electrical switch, a state change of a relay, an opening of a circuit, a closing of a circuit, an opening of a relay, a closing of a relay, a manual activation signal, a maintenance event alarm, and a maintenance event signal.

53. The backup system according to claim 1, further comprising at least one controller, wherein said controller comprises:
a. a means for monitoring said indication of a non-standard operating condition;
b. a means for accepting an input signal for said indication of a non-standard operating condition;
c. a means for automatically opening said automatic releasing valve;
d. a means for automatically re-closing said automatic releasing valve;
e. a means for monitoring the pressure inside said compressed air tank;
f. a means for monitoring the temperature inside said compressed air tank;
g. a means for monitoring the humidity inside said compressed air tank;
h. a means for monitoring sensors and components within said backup system;
i. a means for controlling components within said backup system; or
j. a combination thereof.

54. The backup system according to claim 1, wherein said cooling fluid is ambient air and said pneumatically-powered fluid mover is at least one pneumatically-powered fluid mover selected from the group consisting of an air amplifier, a pneumatic motor connected to a fan, a reaction-type fan, and a pneumatically-overridden principal cooling fan.

55. The backup system according to claim 54, wherein said pneumatically-powered fluid mover is configured to mix said compressed air leaving said compressed air outlet with said cooling fluid while simultaneously moving said cooling fluid, resulting in a discharge mass flowrate from said pneumatically-powered fluid mover which is larger and colder than the mass flowrate of said cooling fluid entering said pneumatically-powered fluid mover.

56. The backup system according to claim 54, further comprising at least one filter in the pathway of said ambient air.

57. The backup system according to claim 54, further comprising at least one moisture collector in the pathway of said ambient air, wherein said moisture collector is selected from the group consisting of a drain, mist eliminator, a grease eliminator, a desiccant, a hydrophilic material, a sponge, and a hydrophilic foam.

58. The backup system according to claim 54, wherein:
a. said pneumatically-powered fluid mover draws said ambient air from at least one location selected from the group consisting of a data center space, a flooded room, a cold aisle, a hot aisle, a hot aisle containment structure, a ceiling plenum, a principal cooling equipment return gallery, a floor plenum, the outlet side of said information technology equipment cabinet, a piece of principal cooling equipment, and a point along a return air pathway; and
b. said pneumatically-powered fluid mover discharges said ambient air and said compressed air into or towards at least one location selected from the group consisting of a data center space, a cold aisle, a flooded room, a floor plenum, the inlet side of said information technology equipment cabinet, a cold aisle containment structure, a principal cooling equipment return gallery, a piece of principal cooling equipment, and a point along a supply air pathway.

59. The backup system according to claim 54, wherein:
a. said pneumatically-powered fluid mover is arranged to produce an airside pressure differential across said information technology equipment cabinet such that the ambient air pressure on the inlet side of said information technology equipment cabinet is greater than the ambient air pressure on the outlet side of said information technology equipment cabinet;
b. said airside pressure differential is larger than the airside pressure differential across said information technology equipment cabinet produced by the internal fans of said information technology equipment alone;
c. said airside pressure differential assists in minimizing recirculation of the warm discharge air from said information technology equipment cabinet back to the inlet of said information technology equipment cabinet; and
d. said airside pressure differential across said information technology equipment cabinet is achieved without requiring the assistance of principal cooling equipment fans.

60. The backup system according to claim 54, further comprising at least one passive airside thermal storage heat exchanger, wherein:
a. said passive airside thermal storage heat exchanger is upstream or downstream of said pneumatically-powered fluid mover, such that said passive airside thermal storage heat exchanger is in the pathway of said ambient air;
b. said passive airside thermal storage heat exchanger comprises a fixed mass of heat exchange material selected from the group consisting of a solid mesh, a solid wire, a packed bed of solid spheres, a grid of solid spheres, a packed bed of solid pellets, a grid of solid pellets, a solid encapsulated in a solid, a phase-change material encapsulated in a solid, and a liquid encapsulated in a solid; and
c. said fixed mass of heat exchange material absorbs heat from said ambient air.

61. The backup system according to claim 60, wherein said passive airside thermal storage heat exchanger further comprises a solid filler material distributed within said fixed mass of heat exchange material to increase the overall effective thermal conductivity of said fixed mass of heat exchange material.

62. The backup system according to claim 60, wherein said fixed mass of heat exchange material is a solid made primarily of at least one substance selected from the group consisting of copper, aluminum, steel, polyethylene, high density polyethylene, low density polyethylene, polypropylene, polybutylene terephthalate, polyetherimide, rubber, paraffin, acrylic, and plastic.

63. The backup system according to claim 60, wherein said fixed mass of heat exchange material is a liquid encapsulated in a solid, wherein said liquid is made primarily of at least one substance selected from the group consisting of water, glycol, dielectric fluid, paraffin, an aqueous salt solution, salt hydrates, hydrocarbons, and sugar alcohol.

64. The backup system according to claim 60, wherein:
a. said fixed mass of heat exchange material is a phase-change material encapsulated in a solid;
b. all or part of the heating phase transition temperature range of said phase-change material is below the temperature of said ambient air entering said passive airside thermal storage heat exchanger; and
c. said phase-change material is made primarily of at least one substance selected from the group consisting of paraffin, paraffin wax, wax, beeswax, cocoa butter, salt hydrates, lipids, sugar alcohol, and refrigerant.

65. The backup system according to claim 60, wherein said passive airside thermal storage heat exchanger further comprises at least one cone-shaped housing, a filter, a plurality of filters, a curved filter, or a combination thereof.

66. The backup system according to claim 60, wherein said passive airside thermal storage heat exchanger comprises a mesh structure such that said passive airside thermal storage heat exchanger performs as a filter in addition to performing as a heat exchanger.

67. The backup system according to claim 1, wherein said cooling fluid is a liquid or the liquid phase of a refrigerant, and said pneumatically-powered fluid mover is at least one pneumatically-powered fluid mover selected from the group consisting of a pneumatic motor connected to a pump, an air-operated diaphragm pump, an airlift pump, and a pneumatically-overridden principal cooling pump.

68. The backup system according to claim 67, further comprising at least one thermal storage tank, a thermal storage media, and a connection to a principal cooling equipment fluid loop, wherein said thermal storage media is stored inside of said thermal storage tank.

69. The backup system according to claim 68, further comprising at least one immersed heat exchanger, wherein:
a. said immersed heat exchanger is immersed or submerged within said thermal storage media inside of said thermal storage tank; and
b. said principal cooling equipment fluid loop is connected to said immersed heat exchanger to transfer heat from said principal cooling equipment fluid loop to said thermal storage media.

70. The backup system according to claim 69, wherein said pneumatically-powered fluid mover moves a primary cooling fluid through said immersed heat exchanger and through all or through a portion of said principal cooling equipment fluid loop.

71. The backup system according to claim 68, wherein said thermal storage media is at least one heat exchange material selected from the group consisting of a liquid, a phase-change material, a phase-change material encapsulated in a solid, a liquid encapsulated in a solid, and a solid.

72. The backup system according to claim 68, wherein said thermal storage media is a liquid, wherein said liquid is made primarily of at least one substance selected from the group consisting of water, glycol, dielectric fluid, paraffin, an aqueous salt solution, salt hydrates, hydrocarbons, and sugar alcohol.

73. The backup system according to claim 68, wherein said thermal storage media is a phase-change material, wherein said phase-change material is made primarily of at least one substance selected from the group consisting of paraffin, paraffin wax, wax, beeswax, cocoa butter, salt hydrates, lipids, sugar alcohol, and refrigerant.

74. The backup system according to claim 68, wherein said thermal storage tank further comprises a solid filler material distributed within said thermal storage media to increase the overall effective thermal conductivity of said thermal storage media.

75. The backup system according to claim 68, further comprising at least one pneumatically-powered agitator, wherein said pneumatically-powered agitator agitates or circulates said thermal storage media inside said thermal storage tank to increase the rate of heat transfer from said cooling fluid to said thermal storage media.

76. The backup system according to claim 68, further comprising at least one submerged compressed air direct injector, wherein said submerged compressed air direct injector cools and agitates or circulates said thermal storage media inside said thermal storage tank to increase the rate of heat transfer from said cooling fluid to said thermal storage media.

77. The backup system according to claim 68, further comprising at least one baffle inside said thermal storage tank, wherein said baffle helps separate the warm return stream of said thermal storage media coming back to said thermal storage tank from the cool remainder of said thermal storage media in the rest of said thermal storage tank.

78. The backup system according to claim 68, wherein said thermal storage tank is installed underground.

79. The backup system according to claim 68, further comprising at least one domestic water connection or at least one gravity-fed liquid connection to said thermal storage tank.

80. The backup system according to claim 68, further comprising at least one primary-to-secondary heat exchanger and a secondary liquid loop, wherein:
a. said thermal storage media is a secondary cooling liquid;
b. said pneumatically-powered fluid mover is connected to said secondary liquid loop for moving said secondary cooling liquid;
c. said principal cooling equipment fluid loop is connected to the hot fluid side of said primary-to-secondary heat exchanger;
d. said secondary liquid loop is connected to the cold fluid side of said primary-to-secondary heat exchanger and connected to said thermal storage tank;
e. said pneumatically-powered fluid mover moves said secondary cooling liquid from said thermal storage tank through said cold fluid side of said primary-to-secondary heat exchanger, through said secondary liquid loop, and back to said thermal storage tank; and
f. said primary-to-secondary heat exchanger transfers heat from said principal cooling equipment fluid loop to said secondary liquid loop.

81. The backup system according to claim 80, further comprising at least one additional pneumatically-powered fluid mover, wherein said additional pneumatically-powered fluid mover moves a primary cooling fluid through said hot fluid side of said primary-to-secondary heat exchanger and through all or through a portion of said principal cooling equipment fluid loop.

82. The backup system according to claim 67, further comprising at least one connection to a principal cooling equipment fluid loop, wherein said pneumatically-powered fluid mover moves said cooling fluid through all or through a portion of said principal cooling equipment fluid loop.

83. The backup system according to claim 1, wherein said pneumatically-powered fluid mover is mounted on, in, or adjacent to a piece of principal cooling equipment.

84. The backup system according to claim 1, wherein said pneumatically-powered fluid mover further comprises at least one pneumatic motor coupled to an electrically-driven piece of principal cooling equipment, wherein said pneumatic motor pneumatically-overrides the fan, pump, or compressor of said electrically-driven piece of principal cooling equipment.

85. The backup system according to claim 84, further comprising at least one clutch, wherein said clutch allows said pneumatically-powered fluid mover to engage and disengage with said fan, pump, or compressor of said electrically-driven piece of principal cooling equipment.

86. The backup system according to claim 1, further comprising at least one space pressure reliever selected from the group consisting of a relief damper, a backdraft damper, a counterbalanced backdraft damper, a pneumatic damper, a motorized damper, a check valve, a break-through seal, an intentional opening, and an intentional leakage opening.

87. A method for maintaining information technology equipment within an acceptable temperature range for a duration of thirty minutes or less, the method comprising:
a. releasing compressed air from a compressed air tank which stores compressed air by opening an automatic releasing valve in response to an indication of a non-standard operating condition, wherein said indication of a non-standard operating condition comprises an indication of a loss of normal utility power;
b. directing or delivering said compressed air from said compressed air tank to a pneumatically-powered fluid mover through a compressed air conduit;
c. moving a cooling fluid by utilizing said compressed air in said pneumatically-powered fluid mover, wherein said cooling fluid is moved at a mass flowrate which is at least three times larger than the mass flowrate of said compressed air entering said pneumatically-powered fluid mover; and
d. transferring heat which originates from said information technology equipment to said cooling fluid.

88. The method according to claim 87, wherein said releasing step is accomplished without requiring the assistance of digital controls, electronic controls, normal utility power, backup power, nor manual intervention.

89. The method according to claim 87, wherein said releasing step is accomplished without requiring the assistance of normal utility power, backup power, nor manual intervention.

90. The method according to claim 87, wherein said releasing step comprises expanding said compressed air for a minimum duration sufficient to drop the stagnation temperature of said compressed air by at least fifteen degrees Fahrenheit.

91. The method according to claim 87, further comprising holding said automatic releasing valve open after said releasing step initially opens said automatic releasing valve and continuing said holding of said automatic releasing valve open regardless of any changes to the state or status of said indication of a non-standard operating condition.

92. The method according to claim 87, wherein said releasing step comprises fully releasing said compressed air from said compressed air tank, such that the pressure inside said compressed air tank drops to atmospheric pressure or near atmospheric pressure.

93. The method according to claim 87, wherein said releasing step comprises releasing said compressed air from said compressed air tank for a minimum duration sufficient to drop the absolute pressure inside said compressed air tank to a value which is approximately 0.37 times the initial absolute pressure in said compressed air tank or lower.

94. The method according to claim 87, wherein said indication of a non-standard operating condition of said releasing step is at least one indication selected from the group consisting of a loss of normal utility power, a loss of at least one source of normal utility power, a principal cooling equipment alarm, a principal cooling equipment signal, a generator alarm, a generator signal, an emergency power alarm, an emergency power signal, a standby power alarm, a standby power signal, a transfer switch alarm, a transfer switch signal, a cooling fluid alarm, a cooling fluid signal, a cold aisle alarm, a cold aisle signal, a differential pressure alarm, a differential pressure signal, a leak alarm, a leak signal, a temperature sensor alarm, a temperature sensor signal, an information technology equipment alarm, an information technology equipment signal, an information technology equipment failure alarm, an information technology equipment failure signal, an information technology equipment high temperature alarm, an information technology equipment high temperature signal, a user-configurable alarm, a user-configurable signal, a building management system alarm, a building management system signal, a power management system alarm, a power management system signal, a state change of an electrical switch, a state change of a relay, an opening of a circuit, a closing of a circuit, an opening of a relay, a closing of a relay, a manual activation signal, a maintenance event alarm, and a maintenance event signal.

95. The method according to claim 87, wherein said moving step comprises moving said cooling fluid through a passive airside thermal storage heat exchanger and cooling said cooling fluid via passage through and contact with said passive airside thermal storage heat exchanger.

96. The method according to claim 87, wherein said moving step comprises moving said cooling fluid through an immersed heat exchanger immersed or submerged in thermal storage media inside a thermal storage tank.

97. The method according to claim 87, wherein said moving step comprises moving said cooling fluid through the hot fluid side of a primary-to-secondary heat exchanger and moving a secondary cooling liquid from a thermal storage tank through the cold fluid side of said primary-to-secondary heat exchanger.

98. The method according to claim 87, further comprising mixing said compressed air with said cooling fluid while simultaneously moving said cooling fluid, resulting in a discharge mass flowrate from said pneumatically-powered fluid mover which is larger and colder than the mass flowrate of said cooling fluid entering said pneumatically-powered fluid mover.
